(19) United States
(12) Patent Application Publication
(10) Pub. No.: US 2026/0090037 A1
(43) Pub. Date: Mar. 26, 2026

(54) SIC SEMICONDUCTOR DEVICE

(71) Applicant: ROHM CO., LTD., Kyoto-shi (JP)

(72) Inventors: Rogosu WAGURI, Kyoto-shi (JP); Yuki NAKANO, Kyoto-shi (JP); Seigo MORI, Kyoto-shi (JP)

(73) Assignee: ROHM CO., LTD., Kyoto-shi (JP)

(21) Appl. No.: 19/409,917

(22) Filed: Dec. 5, 2025

Related U.S. Application Data
(63) Continuation of application No. PCT/JP2024/019425, filed on May 27, 2024.

(30) Foreign Application Priority Data
Jun. 6, 2023 (JP) 2023-093514

(51) Int. Cl. H10D 62/10; H10D 30/01; H10D 30/66; H10D 62/00; H10D 62/832

(52) U.S. Cl. CPC H10D 62/111; H10D 30/0297; H10D 30/668; H10D 62/054; H10D 62/127; H10D 62/8325

(57) ABSTRACT

A semiconductor device includes chip having a main surface, a semiconductor region of a first conductivity type formed in a surface layer portion of the main surface, a gate structure of a trench type formed in the main surface and positioned in the semiconductor region, a body region of a second conductivity type formed in a region at a side of the main surface with respect to a depth position of a bottom wall of the gate structure in the surface layer portion of the main surface, and a high concentration region of the first conductivity type formed in a thickness range between the bottom wall of the gate structure and a bottom portion of the body region in the chip and having an impurity concentration higher than an impurity concentration of the semiconductor region.

### CROSS-REFERENCE TO RELATED APPLICATIONS

The present application is a bypass continuation of International Patent Application No. PCT/JP2024/019425 filed on May 27, 2024, which claims priority to Japanese Patent Application No. 2023-093514 filed on Jun. 6, 2023, and the entire contents of these applications are hereby incorporated herein by reference.

### BACKGROUND

### 1. Field of the Disclosure

The present disclosure relates to a semiconductor device.

### 2. Description of the Related Art

US2010/0224932A1 discloses a semiconductor device including a semiconductor substrate, a drift region, a body region, a gate trench, a gate insulating film, a gate electrode, and a diffusion region of a p-type. The drift region is formed on an upper surface side of the semiconductor substrate. The body region is formed on the upper surface side of the semiconductor substrate with respect to the drift region.

The gate trench is formed in an upper surface of the semiconductor substrate and passes through the body region. The gate insulating film covers a wall surface of the gate trench. The gate electrode is embedded in the gate trench via the gate insulating film. The p-type diffusion region is formed along a bottom wall of the gate trench in the drift region.

### BRIEF DESCRIPTION OF DRAWINGS

FIG. 1 is a plan view showing a semiconductor device according to a first embodiment.

FIG. 2 is a sectional view taken along line II-II shown in FIG. 1.

FIG. 3 is a plan view showing a layout example of a first main surface.

FIG. 4 is an enlarged plan view showing a layout example of one main portion of the first main surface.

FIG. 5 is a sectional view taken along line V-V shown in FIG. 4.

FIG. 6 is a sectional view taken along line VI-VI shown in FIG. 4.

FIG. 7 is an enlarged sectional view of a region including a gate structure shown in FIG. 5.

FIG. 8 is an enlarged sectional view of a region including the gate structure shown in FIG. 6.

FIG. 9 is a schematic view showing a wafer used in manufacture of the semiconductor device.

FIG. 10A to FIG. 10P are sectional views showing a manufacturing method example of the semiconductor device.

FIG. 11 is a sectional view showing one main portion of a semiconductor device according to a second embodiment.

FIG. 12 is a plan view showing one main portion of a semiconductor device according to a third embodiment.

FIG. 13 is a sectional view taken along line XIII-XIII shown in FIG. 12.

FIG. 14 is a sectional view taken along line XIV-XIV shown in FIG. 12.

FIG. 15 is an enlarged sectional view of a region including a source structure shown in FIG. 13.

FIG. 16 is an enlarged sectional view of a region including the source structure shown in FIG. 14.

FIG. 17 is a plan view showing one main portion of a semiconductor device according to a fourth embodiment.

FIG. 18 is a sectional view showing a semiconductor device according to a first modification example.

FIG. 19 is a sectional view showing a semiconductor device according to a second modification example.

FIG. 20 is a sectional view showing a semiconductor device according to a third modification example.

FIG. 21 is a sectional view showing a semiconductor device according to a fourth modification example.

FIG. 22 is a sectional view showing a semiconductor device according to a fifth modification example.

FIG. 23 is a sectional view showing a semiconductor device according to a sixth modification example.

FIG. 24 is a sectional view showing a semiconductor device according to a seventh modification example.

FIG. 25 is a sectional view showing a semiconductor device according to an eighth modification example.

### DETAILED DESCRIPTION OF THE PREFERRED EMBODIMENTS

Hereinafter, specific embodiments shall be described in detail with reference to attached drawings. The attached drawings are all schematic views and are not strictly illustrated, and relative positional relationships, scales, proportions, angles, and the like thereof do not always match. Identical reference signs are given to corresponding structures among the attached drawings, and duplicate descriptions thereof shall be omitted or simplified. For the structures whose description has been omitted or simplified, the description given before the omission or simplification shall apply.

When the wording “substantially equal” is used in this Description, the wording includes a numerical value (shape) equal to a numerical value (shape) of a comparison target and also includes numerical errors (shape errors) in a range of ±10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type,” the “p-type” may be referred to as a “first conductivity type,” and the “n-type” may be referred to as a “second conductivity type.” As a matter of course, the “n-type” may be referred to as the “first conductivity type,” and the “p-type” may be referred to as the “second conductivity type.”

The “p-type” is a conductivity type due to a trivalent element, and the “n-type” is a conductivity type due to a pentavalent element. The trivalent element is at least one type among boron, aluminum, gallium, and indium. The pentavalent element is at least one type among nitrogen, phosphorus, arsenic, antimony, and bismuth.

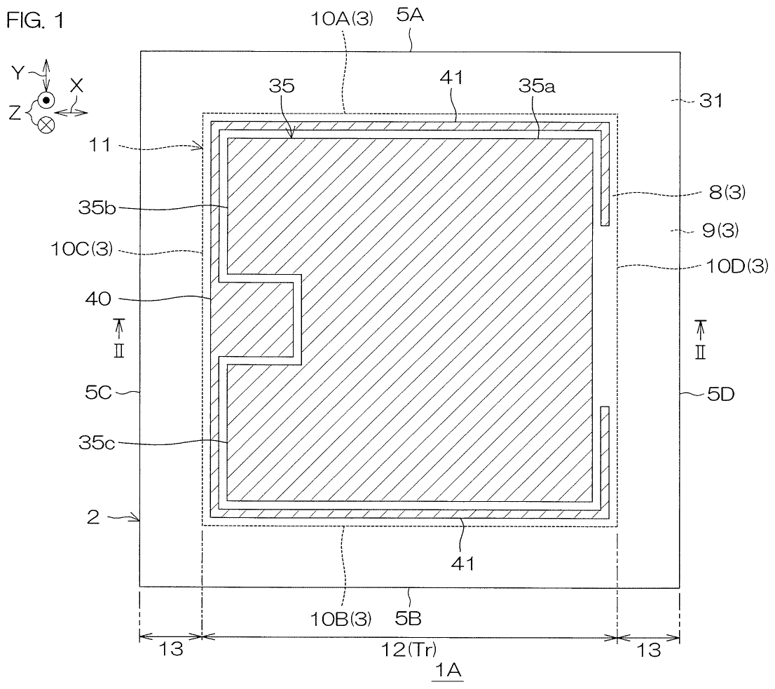

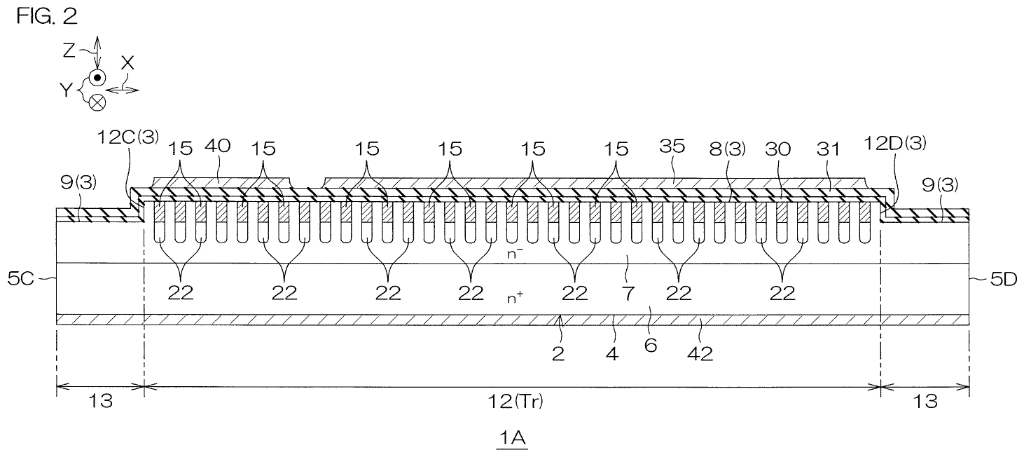

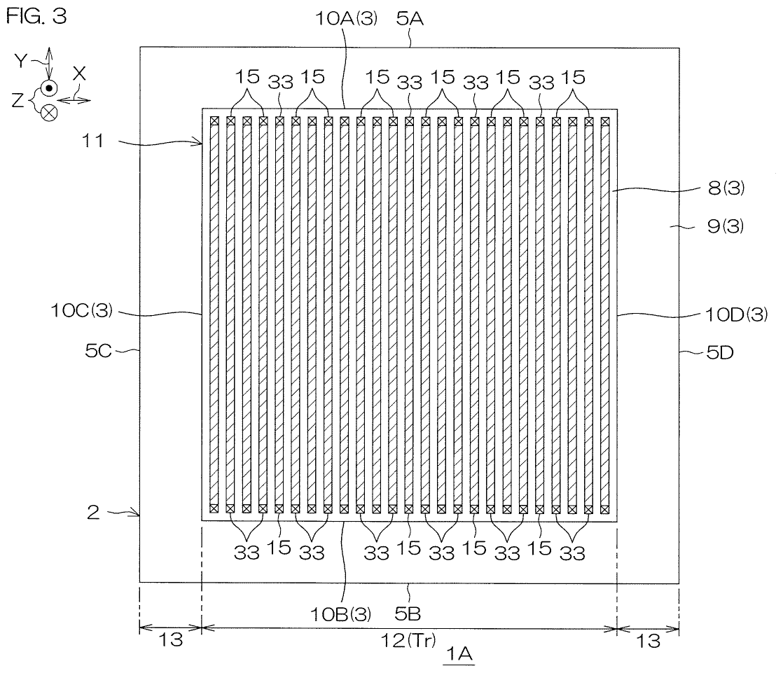

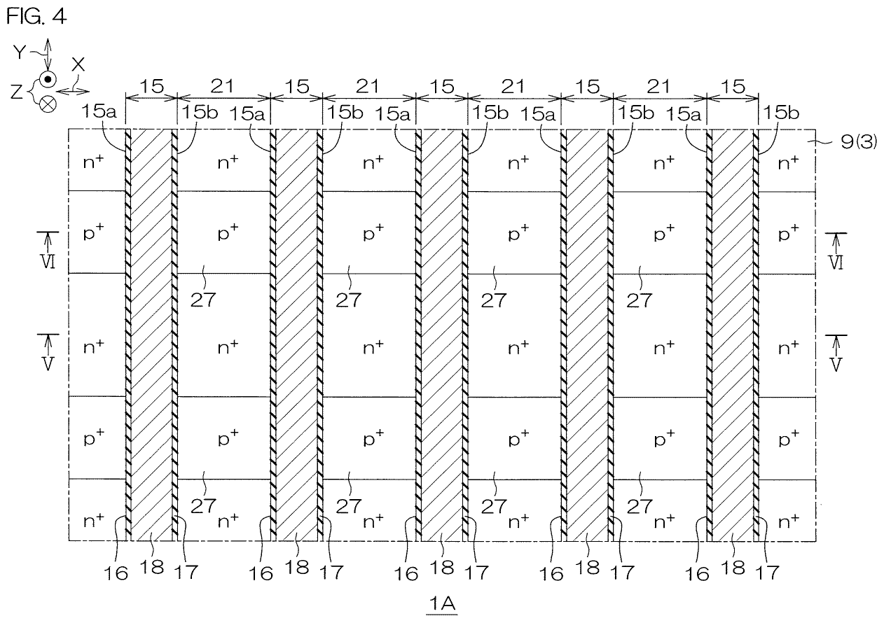

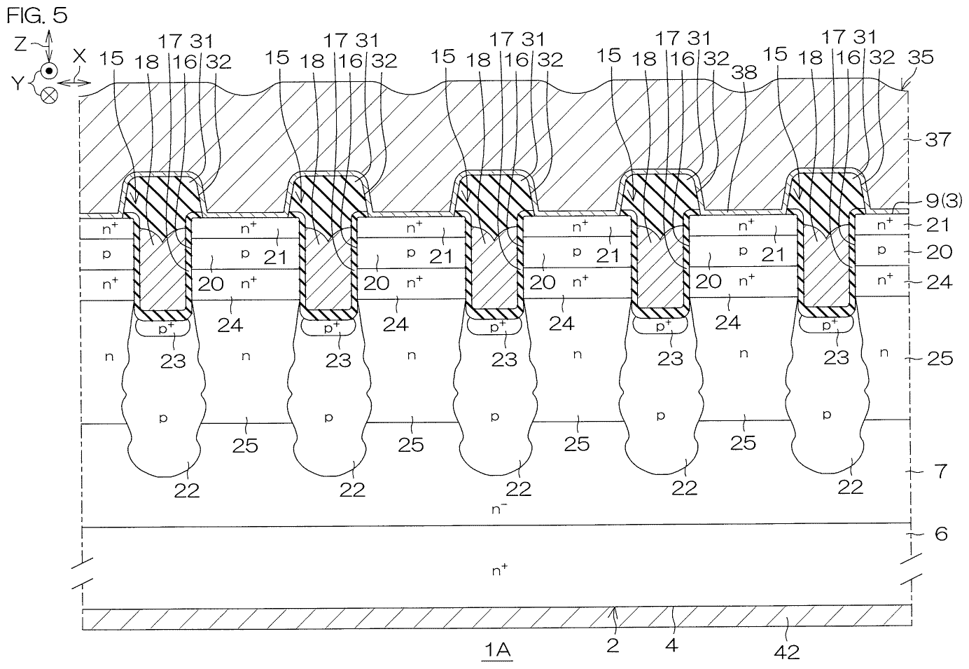

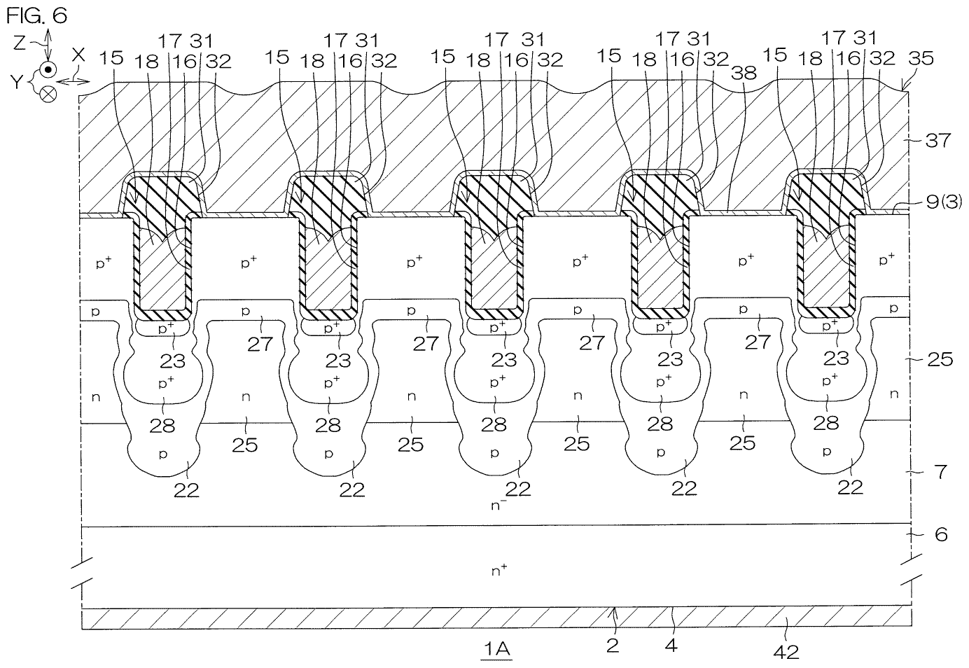

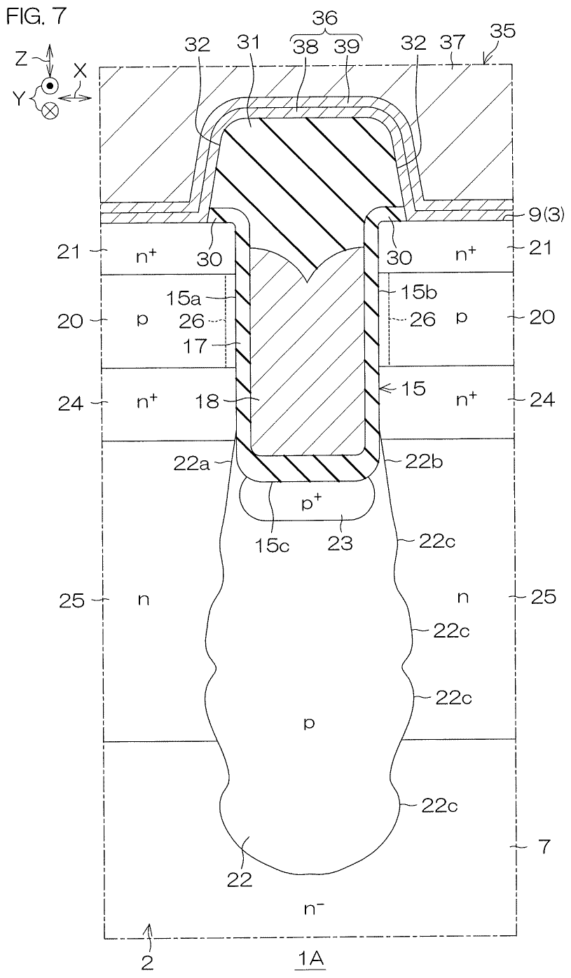

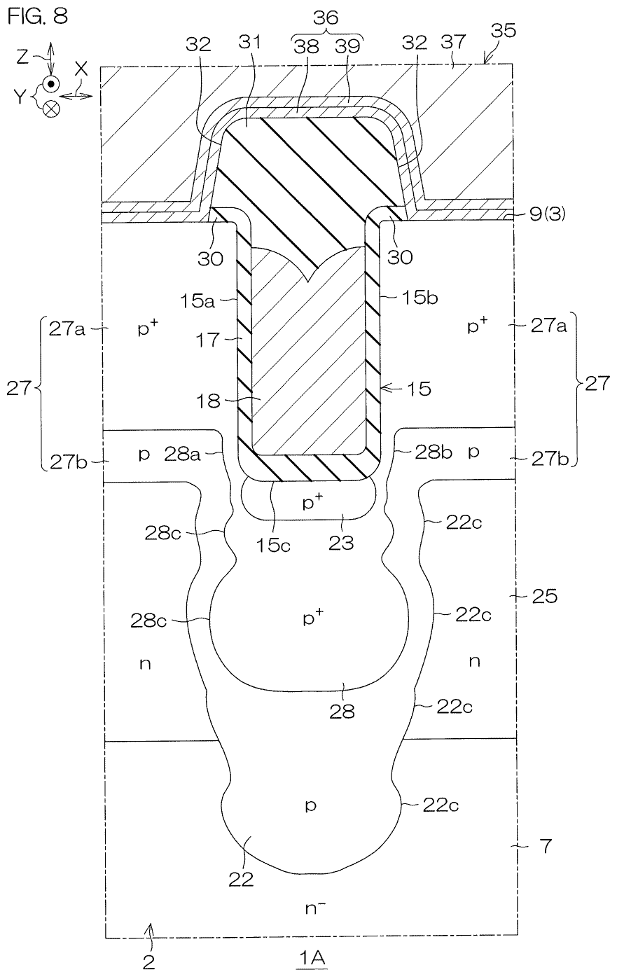

FIG. 1 is a plan view showing a semiconductor device 1A according to a first embodiment. FIG. 2 is a sectional view taken along line II-II shown in FIG. 1. FIG. 3 is a plan view showing a layout example of a first main surface 3. FIG. 4 is an enlarged plan view showing a layout example of one main portion of the first main surface 3. FIG. 5 is a sectional view taken along line V-V shown in FIG. 4. FIG. 6 is a sectional view taken along line VI-VI shown in FIG. 4. FIG. 7 is an enlarged sectional view of a region including a gate structure 15 shown in FIG. 5. FIG. 8 is an enlarged sectional view of a region including the gate structure 15 shown in FIG. 6.

Referring to FIGS. 1 to 8, the semiconductor device 1A is a semiconductor switching device that has a transistor structure Tr of an insulated gate type as an example of a device structure. The transistor structure Tr has a vertical structure. The semiconductor device 1A is an SiC semiconductor device having a chip 2 including an SiC monocrystal. The chip 2 may be referred to as a “SiC chip” or a “semiconductor chip.”

In this embodiment, the chip 2 is constituted of the SiC monocrystal, which is a hexagonal crystal, and is formed in a rectangular parallelepiped shape. The SiC monocrystal that is a hexagonal crystal has multiple polytypes including a 2H (hexagonal)-SiC monocrystal, a 4H—SiC monocrystal, a 6H—SiC monocrystal, etc. In this embodiment, an example in which the chip 2 is constituted of the 4H—SiC monocrystal is to be given, but the chip 2 may be constituted of another polytype instead.

The chip 2 has the first main surface 3 on one side, a second main surface 4 on the other side, and first to fourth side surfaces 5A to 5D connecting the first main surface 3 and the second main surface 4. In a plan view as viewed from a vertical direction Z (hereinafter referred to simply as “plan view”), the first main surface 3 and the second main surface 4 are formed in quadrangle shapes. The vertical direction Z is also a thickness direction of the chip 2 and a normal direction to the first main surface 3 (the second main surface 4). The first main surface 3 and the second main surface 4 may be formed in a square shape or a rectangular shape in plan view.

The first main surface 3 and the second main surface 4 are preferably formed by c-planes of the SiC monocrystal. In this case, preferably, the first main surface 3 is formed by a silicon plane (a (0001) plane) of the SiC monocrystal and the second main surface 4 is formed by a carbon plane (a (000-1) plane) of the SiC monocrystal.

The first side surface 5A and the second side surface 5B extend in a first direction X oriented along the first main surface 3 and are opposed in a second direction Y that intersects the first direction X along the first main surface 3. Specifically, the second direction Y is orthogonal to the first direction X. The third side surface 5C and the fourth side surface 5D extend in the second direction Y and are opposed in the first direction X.

In this embodiment, the first direction X is an m-axis direction (a [1-100] direction) of the SiC monocrystal and the second direction Y is an a-axis direction (a [11-20] direction) of the SiC monocrystal. As a matter of course, the first direction X may instead be the a-axis direction of the SiC monocrystal and the second direction Y may instead be the m-axis direction of the SiC monocrystal. In the following, directions extending along the first main surface 3 are expressed at times as “horizontal directions.” The horizontal directions are also an XY plane (horizontal plane) formed by the first direction X and the second direction Y and are orthogonal to the vertical direction Z.

The chip 2 (the first main surface 3 and the second main surface 4) has the off angle inclined at the predetermined angle in the predetermined off direction with respect to the c-plane of the SiC monocrystal. That is, a c-axis (a (0001) axis) of the SiC monocrystal is inclined by just the off angle toward the off direction from a vertical line. Also, the c-plane of the SiC monocrystal is inclined by just the off angle with respect to the horizontal plane.

The off direction is preferably the a-axis direction (that is, the second direction Y) of the SiC monocrystal. The off angle may exceed 0° but be not more than 10°. The off angle may have a value belonging to at least one range among exceeding 0° and not more than 1°, not less than 1° and not more than 2.5°, not less than 2.5° and not more than 5°, not less than 5° and not more than 7.5°, and not less than 7.5° and not more than 10°.

The off angle is preferably not more than 5°. The off angle is especially preferably not less than 2° and not more than 4.5°. The off angle is typically set in a range of 4°+0.1°. This Description does not exclude an embodiment in which the off angle is 0° (that is, an embodiment in which the first main surface 3 is a just surface with respect to the c-plane).

The semiconductor device 1A includes a first semiconductor region 6 of the n-type that is formed in a surface layer portion of the second main surface 4 of the chip 2. A drain potential is to be applied as a first potential (a high potential) to the first semiconductor region 6. The first semiconductor region 6 may be referred to as a “semiconductor layer,” a “first semiconductor layer,” a “drain region,” etc. The first semiconductor region 6 may have an n-type impurity concentration of not less than 1×10¹⁴ cm⁻³ and not more than 1×10²¹ cm⁻³.

The first semiconductor region 6 is formed in a layered shape extending along the second main surface 4 and is exposed from the second main surface 4 of the chip 2 and the first to fourth side surfaces 5A to 5D of the chip 2. In this embodiment, the first semiconductor region 6 is constituted of a semiconductor layer of the n-type. Specifically, the first semiconductor region 6 is constituted of a substrate (an SiC substrate) that includes an SiC monocrystal (a semiconductor monocrystal) and forms the second main surface 4 of the chip 2 and the first to fourth side surfaces 5A to 5D of the chip 2. The first semiconductor region 6 (the substrate) has the off direction and the off angle described above.

The first semiconductor region 6 may have a thickness of not less than 10 μm and not more than 500 μm. The thickness of the first semiconductor region 6 may have a value belonging to at least one range among not less than 10 μm and not more than 50 μm, not less than 50 μm and not more than 100 μm, not less than 100 μm and not more than 150 μm, not less than 150 μm and not more than 200 μm, not less than 200 μm and not more than 300 μm, not less than 300 μm and not more than 400 μm, and not less than 400 μm and not more than 500 μm.

The semiconductor device 1A includes a second semiconductor region 7 of the n-type that is formed in a surface layer portion of the first main surface 3 of the chip 2. The second semiconductor region 7 may be referred to as a “semiconductor layer,” a “second semiconductor layer,” a “drift region,” etc. The second semiconductor region 7 has an n-type impurity concentration that is less than an n-type impurity concentration of the first semiconductor region 6. The n-type impurity concentration of the second semiconductor region 7 may be not less than 1×10¹⁴ cm⁻³ and not more than 1×10¹⁸ cm⁻³.

The second semiconductor region 7 is formed in a layered shape extending along the first main surface 3 and is electrically connected to the first semiconductor region 6. The second semiconductor region 7 is exposed from the first main surface 3 of the chip 2 and the first to fourth side surfaces 5A to 5D of the chip 2. In this embodiment, the second semiconductor region 7 is constituted of a semiconductor layer of the n-type.

Specifically, the second semiconductor region 7 is constituted of an epitaxial layer (an SiC epitaxial layer) including an SiC monocrystal (a semiconductor monocrystal) and forms the first main surface 3 of the chip 2 and the first to fourth side surfaces 5A to 5D of the chip 2. The second semiconductor region 7 (the epitaxial layer) has the off direction and the off angle described above. The second semiconductor region 7 preferably has a thickness less than the thickness of the first semiconductor region 6. The thickness of the second semiconductor region 7 may be greater than the thickness of the first semiconductor region 6.

The thickness of the second semiconductor region 7 may be not less than 5 μm and not more than 50 μm. The thickness of the second semiconductor region 7 may have a value belonging to at least one range among not less than 5 μm and not more than 10 μm, not less than 10 μm and not more than 15 μm, not less than 15 μm and not more than 20 μm, not less than 20 μm and not more than 25 μm, not less than 25 μm and not more than 30 μm, not less than 30 μm and not more than 35 μm, not less than 35 μm and not more than 40 μm, not less than 40 μm and not more than 45 μm, and not less than 45 μm and not more than 50 μm.

The semiconductor device 1A includes a first surface portion 8, a second surface portion 9, and first to fourth connecting surface portions 10A to 10D that are formed in the first main surface 3. The first surface portion 8, the second surface portion 9, and the first to fourth connecting surface portions 10A to 10D demarcate a mesa 11 in the first main surface 3. The first surface portion 8, the second surface portion 9, and the first to fourth connecting surface portions 10A to 10D (that is, the mesa 11) may be regarded as constituent elements of the chip 2 (the first main surface 3).

The first surface portion 8 may be referred to as an “active surface,” the second surface portion 9 may be referred to as an “outer surface,” the first to fourth connecting surface portions 10A to 10D may be referred to as “connecting surfaces,” and the mesa 11 may be referred to as an “active mesa.”

The first surface portion 8 is formed at intervals inward from peripheral edge of the first main surface 3 (from the first to fourth side surfaces 5A to 5D). The first surface portion 8 has a flat surface extending in the horizontal directions and is formed by a c-plane (an Si plane). The first surface portion 8 is formed in a quadrilateral shape having four sides parallel to the first to fourth side surfaces 5A to 5D in plan view in this embodiment. A planar area of the first surface portion 8 is preferably not less than 50% and not more than 90% of a planar area of the first main surface 3.

The second surface portion 9 is positioned at a peripheral edge portion side of the first main surface 3 with respect to the first surface portion 8 and is recessed in the thickness direction (to the second main surface 4 side) of the chip 2 from a height position of the first surface portion 8. In plan view, the second surface portion 9 extends in a band shape along the first surface portion 8 and is formed in an annular shape (specifically, a quadrilateral annular shape) surrounding the first surface portion 8. The second surface portion 9 is continuous with the first to fourth side surfaces 5A to 5D.

The second surface portion 9 is formed substantially parallel to the first surface portion 8 and has a flat surface extending in the horizontal directions. In this embodiment, the second surface portion 9 is formed by a c-plane (an Si plane). The second surface portion 9 is formed in the second semiconductor region 7 at an interval from the first semiconductor region 6. That is, the second surface portion 9 is recessed to a depth less than the thickness of the second semiconductor region 7 and exposes the second semiconductor region 7.

The second surface portion 9 has a depth of not less than 0.1 μm and not more than 3 μm. The depth of the second surface portion 9 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the second surface portion 9 is preferably not less than 1.5 μm and not more than 2.5 μm.

The first to fourth connecting surface portions 10A to 10D extend in the vertical direction Z and are connected to the first surface portion 8 and the second surface portion 9. The first connecting surface portion 10A is positioned at the first side surface 5A side, the second connecting surface portion 10B is positioned at the second side surface 5B side, the third connecting surface portion 10C is positioned at the third side surface 5C side, and the fourth connecting surface portion 10D is positioned at the fourth side surface 5D side. The first connecting surface portion 10A and the second connecting surface portion 10B extend in the first direction X and are opposed in the second direction Y. The third connecting surface portion 10C and the fourth connecting surface portion 10D extend in the second direction Y and are opposed in the first direction X.

The first to fourth connecting surface portions 10A to 10D may extend substantially perpendicularly between the first surface portion 8 and the second surface portion 9 and demarcate the mesa 11 of a quadrilateral column shape. The first to fourth connecting surface portions 10A to 10D may be inclined obliquely downward from the first surface portion 8 toward the second surface portion 9 and demarcate the mesa 11 of a truncated quadrilateral prism shape. The first to fourth connecting surface portions 10A to 10D may be inclined at an angle of exceeding 90° and not more than 135° with respect to the first surface portion 8.

The mesa 11 is thus demarcated in a projecting shape on the second semiconductor region 7 in the first main surface 3. The mesa 11 is formed just in the second semiconductor region 7 and is not formed in the first semiconductor region 6.

The semiconductor device 1A includes an active region 12 that is set in the chip 2. The active region 12 includes the device structure (the transistor structure Tr) and is a region in which an output current (a drain current) is generated. The active region 12 is set in an inner portion of the chip 2. Specifically, the active region 12 is set in the first surface portion 8.

The semiconductor device 1A includes an outer peripheral region 13 that is set outside the active region 12 in the chip 2. The outer peripheral region 13 is a region not including the device structure (the transistor structure Tr). The outer peripheral region 13 is set in a peripheral edge portion of the chip 2. Specifically, the outer peripheral region 13 is set in the second surface portion 9. That is, the outer peripheral region 13 is set in a region between the peripheral edge of the first surface portion 8 and the peripheral edge of the second surface portion 9 in plan view. Hereinafter, the configuration of the active region 12 shall be described. The semiconductor device 1A includes a plurality of the gate structures 15 of a trench type (a trench electrode type) that are formed in the first main surface 3 (the first surface portion 8). The gate structures 15 may be referred to as “trench gate structures” or as “trench structures.” A gate potential is to be applied as a control potential to the plurality of gate structures 15.

The plurality of gate structures 15 are formed in the first surface portion 8 at intervals inward from the peripheral edge of the first surface portion 8 (from the first to fourth connecting surface portions 10A to 10D). The plurality of gate structures 15 are aligned at intervals in the first direction X in plan view and are each formed in a band shape extending in the second direction Y. That is, in plan view, the plurality of gate structures 15 are aligned in a stripe shape extending in the second direction Y.

The plurality of gate structures 15 may be aligned at intervals of not less than 0.25 μm and not more than 3 μm. The interval between the gate structures 15 may have a value belonging to at least one range among not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, not less than 2.25 μm and not more than 2.5 μm, not less than 2.5 μm and not more than 2.75 μm, and not less than 2.75 μm and not more than 3 μm. The interval between the gate structures 15 is preferably not less than 0.5 μm and not more than 1.5 μm.

The plurality of gate structures 15 are positioned in the second semiconductor region 7. The plurality of gate structures 15 are formed at intervals to the first main surface 3 side from the bottom portion of the second semiconductor region 7 and face the first semiconductor region 6 with a portion of the second semiconductor region 7 interposed therebetween. The plurality of gate structures 15 are formed substantially perpendicular to the first main surface 3 (the first surface portion 8).

The plurality of gate structures 15 each have a first side wall 15a on one side (the third side surface 5C side) in the first direction X, a second side wall 15b on the other side (the fourth side surface 5D side) in the first direction X, and a bottom wall 15c connecting the first side wall 15a and the second side wall 15b in sectional view.

The first side wall 15a and the second side wall 15b are each formed by an a-plane (a (11-20) plane) of the SiC monocrystal. As a matter of course, the first side wall 15a and the second side wall 15b may each be formed by an m-plane (a (1-100) plane) of the SiC monocrystal in accordance with an extension direction of the gate structures 15. The first side wall 15a and the second side wall 15b are formed substantially perpendicular to the first main surface 3.

An inclination angle (absolute value) of the first side wall 15a (the second side wall 15b) on a basis of a vertical line may be not less than 85° and not more than 95°. The inclination angle of the first side wall 15a (the second side wall 15b) may have a value belonging to at least one range among not less than 85° and not more than 87.5°, not less than 87.5° and not more than 90°, not less than 90° and not more than 92.5°, and not less than 92.5° and not more than 95°. The inclination angle of the first side wall 15a (the second side wall 15b) is preferably not less than 87° and not more than 93°.

The bottom wall 15c is formed by a c-plane (an Si plane) of the SiC monocrystal. The bottom wall 15c preferably extends substantially flat in the horizontal direction. As a matter of course, the bottom wall 15c may be curved in a circular arc shape toward the second main surface 4 side.

The gate structure 15 may have a width of not less than 0.1 μm and not more than 1.5 μm. The width of the gate structure 15 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, and not less than 1.25 μm and not more than 1.5 μm. The width of the gate structure 15 is preferably not less than 0.25 μm and not more than 0.75 μm.

The gate structure 15 may have a depth of not less than 0.1 μm and not more than 3 μm. The depth of the gate structure 15 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the gate structure 15 is preferably not less than 0.5 μm and not more than 1.5 μm. The depth of the gate structure 15 is preferably substantially equal to the depth of the second surface portion 9.

The plurality of gate structures 15 each include a trench 16, an insulating film 17, and an embedded electrode 18. The trench 16 is formed in the first main surface 3 (the first surface portion 8) and demarcates wall surfaces (the first side wall 15a, the second side wall 15b, and the bottom wall 15c) of the gate structure 15.

The insulating film 17 may include at least one among a silicon oxide film, a silicon nitride film, and a silicon oxynitride film. In this embodiment, the insulating film 17 has a single layer structure constituted of a silicon oxide film. The insulating film 17 particularly preferably includes a silicon oxide film constituted of an oxide of the chip 2.

The insulating film 17 covers a wall surface of the trench 16 in a film shape. The insulating film 17 includes a first film portion, a second film portion, and a third film portion. The first film portion covers the first side wall 15a in a film shape. The second film portion covers the second side wall 15b in a film shape. The third film portion covers the bottom wall 15c in a film shape and is continuous with the first film portion and the second film portion.

The second film portion has a thickness substantially equal to the thickness of the first film portion. The third film portion has a thickness greater than both the thickness of the first film portion and the thickness of the second film portion. As a matter of course, the thickness of the third film portion may be substantially equal to the thickness of the first film portion and the thickness of the second film portion.

The insulating film 17 may have the thickness of not less than 10 nm and not more than 150 nm. The thickness of the insulating film 17 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The embedded electrode 18 may contain any one or both of a conductive polysilicon of the p-type and a conductive polysilicon of the n-type. The embedded electrode 18 is embedded in the trench 16 with the insulating film 17 interposed therebetween.

The embedded electrode 18 has an electrode surface exposed from the trench 16. The electrode surface is positioned at the bottom wall 15c side with respect to a height position of the first main surface 3. The electrode surface has, in an inner portion, a recess that is recessed in a shape tapering toward the bottom wall 15c side. The bottom portion of the recess is preferably positioned at the first main surface 3 side with respect to a depth position of an intermediate portion of the trench 16.

The semiconductor device 1A includes a plurality of body regions 20 of the p-type that are formed in a surface layer portion of the first main surface 3 (the first surface portion 8). A source potential is to be applied as a second potential (a low potential) differing from the first potential (the high potential) to the plurality of body regions 20. The body region 20 may be referred to as a “channel region,” a “base region,” etc. The plurality of body regions 20 may have a p-type impurity concentration of not less than 1×10¹⁷ cm⁻³ and not more than 1×10¹⁹ cm⁻³.

The plurality of body regions 20 are each formed in regions oriented along the plurality of gate structures 15. Specifically, the plurality of body regions 20 are each formed in regions between the plurality of gate structures 15 and each extend in a band shape along the plurality of gate structures 15.

Hereinafter, the configuration of the single body region 20 shall be described. In this embodiment, the body region 20 is formed in a layered shape extending in the first direction X in sectional view and is connected to any one or both (in this embodiment, both) of the plurality of adjacent gate structures 15. The body region 20 faces the embedded electrodes 18 of the plurality of gate structures 15 with the insulating films 17 of the plurality of gate structures 15 interposed therebetween.

The body region 20 is formed at an interval to a region at the first surface portion 8 side from the depth position of the second surface portion 9. The body region 20 is formed at an interval to the first main surface 3 side from the depth position of the bottom wall 15c of the gate structure 15. The body region 20 has a bottom portion positioned at the bottom wall 15c side of the gate structure 15 with respect to a depth position of an intermediate portion of the gate structure 15.

That is, the bottom portion of the body region 20 is positioned in a region between the bottom wall 15c of the gate structure 15 and the intermediate portion of the gate structure 15. In other words, a distance between the bottom portion of the body region 20 and the bottom wall 15c of the gate structure 15 is less than a thickness (depth) of the body region 20. The bottom portion of the body region 20 is positioned at the bottom wall 15c side of the gate structure 15 with respect to the bottom portion of the recess of the embedded electrode 18. As a matter of course, the bottom portion of the body region 20 may be positioned at the first main surface 3 side with respect to the depth position of the intermediate portion of the gate structure 15.

The body region 20 may have the thickness of not less than 0.1 μm and not more than 1 μm. The thickness of the body region 20 may have a value belonging to at least one range among not less than 0.1 μm and not more than 0.2 μm, not less than 0.2 μm and not more than 0.4 μm, not less than 0.4 μm and not more than 0.6 μm, not less than 0.6 μm and not more than 0.8 μm, and not less than 0.8 μm and not more than 1 μm. The thickness of the body region 20 is preferably not less than 0.3 μm and not more than 0.7 μm.

The semiconductor device 1A includes a plurality of source regions 21 of the n-type that are formed in a region at the first main surface 3 side with respect to the plurality of the body regions 20. The plurality of source regions 21 have an n-type impurity concentration higher than the n-type impurity concentration of the second semiconductor region 7. The n-type impurity concentration of the plurality of source regions 21 may be not less than 1×10¹⁸ cm⁻³ and not more than 1×10²¹ cm⁻³.

The plurality of source regions 21 are each formed in regions oriented along the plurality of gate structures 15 in the surface layer portion of the plurality of body regions 20. Specifically, the plurality of source regions 21 are each formed in regions between the plurality of gate structures 15 and each extend in a band shape along the plurality of gate structures 15.

Hereinafter, the configuration of the single source region 21 shall be described. The source region 21 is formed at an interval to the first main surface 3 side from the bottom portion of the body region 20. In this embodiment, the source region 21 is formed in a layered shape extending in the first direction X in sectional view and is connected to any one or both (in this embodiment, both) of the plurality of adjacent gate structures 15. The source region 21 faces the embedded electrodes 18 of the plurality of gate structures 15 with the insulating films 17 of the plurality of gate structures 15 interposed therebetween.

The source region 21 has a bottom portion positioned at the bottom wall 15c side of the trench 16 with respect to a height position of the electrode surface of the embedded electrode 18 and a surface layer portion positioned at the first main surface 3 side with respect to the height position of the electrode surface of the embedded electrode 18. That is, the source region 21 has a portion (the bottom portion) facing the embedded electrode 18 with the insulating film 17 interposed therebetween and a portion (the surface layer portion) not facing the embedded electrode 18 with the insulating film 17 interposed therebetween.

The bottom portion of the source region 21 may be positioned at the first main surface 3 side with respect to the depth position of the bottom portion of the recess of the embedded electrode 18. As a matter of course, the bottom portion of the source region 21 may be positioned at the bottom portion side of the body region 20 with respect to the depth position of the bottom portion of the recess.

The semiconductor device 1A includes a plurality of well regions 22 of the p-type that are formed in the chip 2 (the second semiconductor region 7). The plurality of well regions 22 have a p-type impurity concentration higher than the p-type impurity concentration of the body region 20. As a matter of course, the p-type impurity concentration of the plurality of well regions 22 may be less than the p-type impurity concentration of the body region 20. The p-type impurity concentration of the plurality of well regions 22 may be not less than 1×10¹⁶ cm⁻³ and not more than 1×10²⁰ cm⁻³.

The plurality of well regions 22 are each formed in regions oriented along the bottom walls 15c of the plurality of gate structures 15 at intervals in the first direction X in the chip 2 (the second semiconductor region 7). In this embodiment, the plurality of well regions 22 are each formed in a one-to-one correspondence with respect to the plurality of gate structures 15. Each of the plurality of well regions 22 is formed in a band shape extending along the corresponding gate structure 15 in plan view and faces the corresponding embedded electrode 18 with the corresponding insulating film 17 interposed therebetween. As a matter of course, the plurality of well regions 22 may be formed in a multiple-to-one correspondence with respect to the single gate structure 15. In this case, the plurality of well regions 22 are formed at intervals in the second direction Y.

Hereinafter, the configuration of the single well region 22 shall be described. The well region 22 is formed to be wider than the gate structure 15 in plan view. The well region 22 is formed in a columnar shape extending in the thickness direction (the vertical direction Z) of the second semiconductor region 7 in sectional view.

The well region 22 may have a depth across an intermediate portion between the bottom portion of the second semiconductor region 7 and the bottom wall 15c of the gate structure 15. The well region 22 may be formed at an interval to the first main surface 3 side from the intermediate portion between the bottom portion of the second semiconductor region 7 and the bottom wall 15c of the gate structure 15.

The well region 22 is formed at an interval to the first surface portion 8 side from the bottom portion of the second semiconductor region 7 and faces the first semiconductor region 6 with a portion of the second semiconductor region 7 interposed therebetween. As a matter of course, the well region 22 may have a bottom portion that crosses the bottom portion of the second semiconductor region 7 and is located in the first semiconductor region 6. The well region 22 forms a pn junction portion with the second semiconductor region 7.

In this embodiment, the well region 22 has a thickness (depth) greater than the thickness (depth) of the body region 20. The thickness of the well region 22 is the thickness of the well region 22 in the vertical direction Z with reference to the bottom wall 15c of the gate structure 15. In this embodiment, the thickness of the well region 22 is greater than the depth of the gate structure 15. As a matter of course, the thickness of the well region 22 may be less than the depth of the gate structure 15. In this case, the thickness of the well region 22 may be less than the thickness of the body region 20.

The well region 22 has an upper end portion oriented along a corner portion of the bottom wall 15c of the gate structure 15. The well region 22 has a first extension portion 22a on the first side wall 15a side and a second extension portion 22b on the second side wall 15b side at the upper end portion (see FIG. 7).

The first extension portion 22a is led out from a region directly below the gate structure 15 to the lower end portion of the first side wall 15a. The first extension portion 22a is formed at an interval to the bottom wall 15c side of the gate structure 15 from the bottom portion of the body region 20. In this embodiment, the first extension portion 22a faces the embedded electrode 18 with the insulating film 17 interposed therebetween in the horizontal direction.

As a matter of course, the first extension portion 22a may be formed at the bottom wall 15c side of the trench 16 with respect to the depth position of the lower end portion of the embedded electrode 18 and face just the insulating film 17 (the third film portion) in the horizontal direction. The first extension portion 22a is formed in a tapered shape toward the first main surface 3 (the bottom portion side of the body region 20) in sectional view.

The second extension portion 22b is led out from a region directly below the gate structure 15 to the lower end portion of the second side wall 15b and faces the first extension portion 22a with the gate structure 15 interposed therebetween. The second extension portion 22b is formed at an interval to the bottom wall 15c side of the gate structure 15 from the bottom portion of the body region 20. In this embodiment, the second extension portion 22b faces the embedded electrode 18 with the insulating film 17 interposed therebetween in the horizontal direction.

As a matter of course, the second extension portion 22b may be formed at the bottom wall 15c side of the trench 16 with respect to the depth position of the lower end portion of the embedded electrode 18 and face just the insulating film 17 (the third film portion) in the horizontal direction. The second extension portion 22b is formed in a tapered shape toward the first main surface 3 (the bottom portion side of the body region 20) in sectional view.

The well region 22 has one or a plurality (in this embodiment, a plurality of) first bulging portions 22c. In the attached drawings, the well region 22 having four first bulging portions 22c is illustrated. The number of the first bulging portions 22c is appropriately adjusted by adjusting process conditions. Each of the plurality of first bulging portions 22c is formed by a portion where a width of the well region 22 in the horizontal direction (the first direction X) gradually increases or decreases in the thickness direction and is formed in multiple stages from the bottom wall 15c of the gate structure 15 toward the bottom portion of the second semiconductor region 7.

The plurality of first bulging portions 22c protrude in an arc shape (circular arc shape) from a region directly below the gate structure 15 to both sides of the gate structure 15. When the well region 22 has the single first bulging portion 22c, the single first bulging portion 22c may be formed such as to protrude in an arc shape (circular arc shape) to both sides of the gate structure 15 at the intermediate portion of the well region 22.

The semiconductor device 1A includes a plurality of high concentration well regions 23 of the p-type that are each formed in the plurality of well regions 22. The plurality of high concentration well regions 23 are regions in which the p-type impurity concentration of the well region 22 is increased and have a p-type impurity concentration higher than the p-type impurity concentration of the well region 22. The high concentration well region 23 may be regarded as a high concentration portion of the well region 22. The p-type impurity concentration of the plurality of high concentration well regions 23 may be not less than 1×10¹⁸ cm⁻³ and not more than 1×10²⁰ cm⁻³.

The plurality of high concentration well regions 23 are each formed in a one-to-one correspondence with respect to the plurality of well regions 22. Each of the plurality of high concentration well regions 23 is formed in a region oriented along the bottom wall 15c of the corresponding gate structure 15. Each of the plurality of high concentration well regions 23 is formed in a band shape extending along the corresponding gate structure 15 (the well region 22) in plan view and faces the corresponding embedded electrode 18 with the corresponding insulating film 17 interposed therebetween.

As a matter of course, the plurality of high concentration well regions 23 may be formed in a multiple-to-one correspondence with respect to the single well region 22. In this case, the plurality of high concentration well regions 23 are formed at intervals in the second direction Y in the single well region 22.

Hereinafter, the configuration of the single high concentration well region 23 shall be described. The high concentration well region 23 is formed at an interval to the bottom wall 15c side of the gate structure 15 from the bottom portion of the well region 22. The high concentration well region 23 preferably has a bottom portion positioned at the bottom wall 15c side of the gate structure 15 with respect to a depth position of the intermediate portion of the well region 22.

The bottom portion of the high concentration well region 23 is defined by a concentration transition portion where the p-type impurity concentration gradually decreases toward the bottom portion side of the well region 22. As a matter of course, the bottom portion of the high concentration well region 23 may be positioned at the bottom portion side of the well region 22 with respect to the depth position of the intermediate portion of the well region 22.

The high concentration well region 23 is formed to be narrower than the well region 22. In this embodiment, the high concentration well region 23 is formed to be narrower than the gate structure 15. As a matter of course, the high concentration well region 23 may be formed to be wider than the gate structure 15 and protrude to both sides of the gate structure 15.

The high concentration well region 23 has a thickness (depth) less than the depth of the gate structure 15. The thickness of the high concentration well region 23 is the thickness of the high concentration well region 23 in the vertical direction Z with reference to the bottom wall 15c of the gate structure 15. The thickness of the high concentration well region 23 is less than the thickness of the body region 20. As a matter of course, the thickness of the high concentration well region 23 may be greater than the thickness of the body region 20 or may be greater than the depth of the gate structure 15.

The semiconductor device 1A includes a plurality of high concentration regions 24 of the n-type that are each formed in regions below the plurality of body regions 20 in the chip 2 (the second semiconductor region 7). The plurality of high concentration regions 24 are regions (low-resistance regions) in which the n-type impurity concentration of the second semiconductor region 7 is increased and have an n-type impurity concentration higher than the n-type impurity concentration of the second semiconductor region 7. The plurality of high concentration regions 24 may be regarded as high concentration portions of the second semiconductor region 7.

The n-type impurity concentration of the plurality of high concentration regions 24 may be not less than 1×10¹⁶ cm⁻³ and not more than 1×10¹⁹ cm⁻³. For example, the n-type impurity concentration of the plurality of high concentration regions 24 can be appropriately compared by being compared with the n-type impurity concentration on the bottom portion side of the second semiconductor region 7. The high concentration region 24 may be referred to as a “high concentration drift region.”

The plurality of high concentration regions 24 are each formed in regions oriented along the plurality of gate structures 15 in regions below the plurality of body regions 20. Specifically, the plurality of high concentration regions 24 are each formed in regions between the plurality of gate structures 15 in a thickness range between the bottom walls 15c of the plurality of gate structures 15 and the bottom portions of the plurality of body regions 20. The plurality of high concentration regions 24 each extend in a band shape along the plurality of gate structures 15 in plan view.

Hereinafter, the configuration of the single high concentration region 24 shall be described. In this embodiment, the high concentration region 24 is formed in a layered shape extending in the first direction X in sectional view and is connected to any one or both (in this embodiment, both) of the plurality of adjacent gate structures 15. The high concentration region 24 faces the embedded electrodes 18 of the plurality of gate structures 15 with the insulating films 17 of the plurality of gate structures 15 interposed therebetween.

The high concentration region 24 faces the source region 21 with a portion of the body region 20 interposed therebetween in the thickness direction. In this embodiment, the high concentration regions 24 face the source regions 21 in a one-to-one correspondence in the thickness direction.

The high concentration region 24 is formed at an interval to the first main surface 3 side from the bottom portion of the second semiconductor region 7 and faces the first semiconductor region 6 with a portion of the second semiconductor region 7 interposed therebetween. The high concentration region 24 is preferably formed at an interval to the first main surface 3 side from an intermediate portion of the second semiconductor region 7.

In this embodiment, the high concentration region 24 has a bottom portion positioned at the first main surface 3 side with respect to the depth position of the bottom wall 15c of the gate structure 15. The bottom portion of the high concentration region 24 is defined by a concentration transition portion where the n-type impurity concentration gradually decreases toward the bottom portion side of the second semiconductor region 7. That is, the high concentration region 24 is formed at an interval to the first main surface 3 side from the depth position of the bottom wall 15c of the gate structure 15.

The high concentration region 24 is formed in a thickness range between the body region 20 and the well region 22 and separates the well region 22 from the body region 20. That is, the high concentration region 24 suppresses an increase in p-type impurity concentration in a portion oriented along the side walls (the first side wall 15a and the second side wall 15b) of the gate structure 15. The high concentration region 24 has a thickness (depth) less than the thickness (depth) of the body region 20 in the vertical direction Z.

The thickness of the high concentration region 24 may be not less than 0.1 μm and not more than 0.5 μm. The thickness of the high concentration region 24 may have a value belonging to at least one range among not less than 0.1 μm and not more than 0.15 μm, not less than 0.15 μm and not more than 0.2 μm, not less than 0.2 μm and not more than 0.25 μm, not less than 0.25 μm and not more than 0.3 μm, not less than 0.3 μm and not more than 0.35 μm, not less than 0.35 μm and not more than 0.4 μm, not less than 0.4 μm and not more than 0.45 μm, and not less than 0.45 μm and not more than 0.5 μm. The thickness of the high concentration region 24 is preferably not less than 0.1 μm and not more than 0.3 μm.

For example, a distance in the vertical direction Z between the bottom wall 15c of the gate structure 15 and the bottom portion of the high concentration region 24 may be not less than 0 μm and not more than 0.4 μm. The distance may have a value belonging to at least one range among not less than 0 μm and not more than 0.05 μm, not less than 0.05 μm and not more than 0.1 μm, not less than 0.1 μm and not more than 0.15 μm, not less than 0.15 μm and not more than 0.2 μm, not less than 0.2 μm and not more than 0.25 μm, not less than 0.25 μm and not more than 0.3 μm, not less than 0.3 μm and not more than 0.35 μm, and not less than 0.35 μm and not more than 0.4 μm. The distance is preferably not less than 0.05 μm and not more than 0.2 μm.

As a matter of course, the bottom portion of the high concentration region 24 may be positioned at the bottom portion side of the second semiconductor region 7 with respect to the bottom wall 15c of the gate structure 15. In this case, it must be borne in mind that the current density in the vicinity of the bottom wall 15c of the gate structure 15 is increased, as a result of which the concentration of electric field in the vicinity of the bottom wall 15c of the gate structure 15 (especially in the vicinity of the corner portion of the bottom wall 15c) is increased.

The plurality of high concentration regions 24 may have n-type impurity concentrations substantially equal to each other, or may have n-type impurity concentrations different from each other. For example, with respect to the one and the other high concentration regions 24 positioned on both sides of the single gate structure 15, the n-type impurity concentration of the other high concentration region 24 may be different from the n-type impurity concentration of the one high concentration region 24. That is, the n-type impurity concentration of the other high concentration region 24 may be higher than the n-type impurity concentration of the one high concentration region 24 or may be lower than the n-type impurity concentration of the one high concentration region 24.

The semiconductor device 1A includes a plurality of intermediate concentration regions 25 of the n-type that are each formed in regions below the plurality of high concentration regions 24 in the chip 2 (the second semiconductor region 7). The plurality of intermediate concentration regions 25 are regions (low-resistance regions) in which the n-type impurity concentration of the second semiconductor region 7 is increased and have an n-type impurity concentration higher than the n-type impurity concentration of the second semiconductor region 7 and lower than the n-type impurity concentration of the high concentration region 24. The plurality of intermediate concentration regions 25 may be regarded as high concentration portions of the second semiconductor region 7.

The n-type impurity concentration of the plurality of intermediate concentration regions 25 may be not less than 1×10¹⁵ cm⁻³ and not more than 1×10¹⁷ cm⁻³. For example, the n-type impurity concentration of the plurality of intermediate concentration regions 25 can be appropriately compared by being compared with the n-type impurity concentration on the bottom portion side of the second semiconductor region 7. The intermediate concentration region 25 may be referred to as an “intermediate concentration drift region.”

The plurality of intermediate concentration regions 25 are each formed in regions between the plurality of gate structures 15 in a thickness range between the bottom portion of the second semiconductor region 7 and the bottom portions of the plurality of high concentration regions 24. Each of the plurality of intermediate concentration regions 25 has a portion interposed in a region between the plurality of well regions 22. In this embodiment, each of the plurality of intermediate concentration regions 25 has a portion interposed in a region between the plurality of gate structures 15.

The plurality of intermediate concentration regions 25 each extend in a band shape along the plurality of gate structures 15 in plan view. In this embodiment, the plurality of intermediate concentration regions 25 are connected to one or both (in this embodiment, both) of the well regions 22 with respect to two adjacent well regions 22.

Hereinafter, the configuration of the single intermediate concentration region 25 shall be described. The intermediate concentration region 25 is formed at an interval to the first main surface 3 side from the bottom portion of the second semiconductor region 7 and faces the first semiconductor region 6 with a portion of the second semiconductor region 7 interposed therebetween.

The intermediate concentration region 25 has an upper end portion positioned on an upper side with respect to the depth position of the bottom wall 15c of the gate structure 15. The upper end portion of the intermediate concentration region 25 is positioned in a region between the plurality of gate structures 15 and faces the gate structure 15 with the upper end portion (the first extension portion 22a and the second extension portion 22b) of the well region 22 interposed therebetween. The upper end portion of the intermediate concentration region 25 may have a portion connected to the gate structure 15.

The intermediate concentration region 25 has a bottom portion positioned on a lower side with respect to the depth position of the bottom wall 15c of the gate structure 15. Specifically, the bottom portion of the intermediate concentration region 25 is formed at an interval to the first main surface 3 side from the bottom portion of the well region 22. The bottom portion of the intermediate concentration region 25 is preferably positioned further to the bottom portion side of the well region 22 than the bottom portion of the high concentration well region 23.

The bottom portion of the intermediate concentration region 25 may be positioned further to the bottom portion side of the second semiconductor region 7 than the intermediate portion of the well region 22. As a matter of course, the bottom portion of the intermediate concentration region 25 may be positioned further to the bottom wall 15c side of the gate structure 15 than the intermediate portion of the well region 22.

The semiconductor device 1A includes a plurality of channel regions 26 each formed between the plurality of source regions 21 and the plurality of high concentration regions 24 in the plurality of body regions 20. Inversion and non-inversion of the plurality of channel regions 26 are controlled by the gate structure 15. The plurality of channel regions 26 each form current paths connecting the plurality of source regions 21 and the plurality of high concentration regions 24 along the side walls (the first side wall 15a and the second side wall 15b) of the plurality of gate structures 15 in the plurality of body regions 20.

Referring to FIGS. 4, 6, and 8, the semiconductor device 1A includes a plurality of first contact regions 27 of the p-type that are formed in regions oriented along the plurality of gate structures 15 in the surface layer portion of the first main surface 3 (the first surface portion 8).

The plurality of first contact regions 27 have a p-type impurity concentration higher than the p-type impurity concentration of the plurality of body regions 20. The p-type impurity concentration of the plurality of first contact regions 27 is higher than the p-type impurity concentration of the plurality of well regions 22. The p-type impurity concentration of the plurality of first contact regions 27 may be not less than 1×10¹⁷ cm⁻³ and not more than 1×10¹⁹ cm⁻³.

The plurality of first contact regions 27 are each formed in regions between the plurality of gate structures 15. That is, the plurality of first contact regions 27 are each formed at both sides of the plurality of gate structures 15.

The plurality of first contact regions 27 are aligned at intervals in the second direction Y along the plurality of gate structures 15 and are each formed in a band shape extending in the second direction Y. The plurality of first contact regions 27 overlap the plurality of body regions 20 and increase the p-type impurity concentration of the plurality of body regions 20.

Regarding the one and the other first contact regions 27 positioned on both sides of the single gate structure 15, the other first contact region 27 faces the one first contact region 27 with the gate structure 15 interposed therebetween. That is, the plurality of first contact regions 27 are aligned, as a whole, in a matrix in plan view.

In the second direction Y, lengths of and intervals between the plurality of first contact regions 27 are appropriately adjusted in accordance with a channel area to be achieved. The channel area corresponds to the total area of the plurality of source regions 21. The length of the first contact region 27 in the second direction Y may be greater than the width of the gate structure 15 in the first direction X. As a matter of course, the length of the first contact region 27 may be less than the width of the gate structure 15.

A first ratio of the length of the first contact region 27 to the width of the gate structure 15 may be not less than 0.5 and not more than 10. The first ratio may have a value belonging to at least one range among not less than 0.5 and not more than 1, not less than 1 and not more than 2.5, not less than 2.5 and not more than 5, not less than 5 and not more than 7.5, and not less than 7.5 and not more than 10. The first ratio is preferably not less than 1 and not more than 5.

A second ratio of the interval between the first contact regions 27 to the length of the first contact region 27 may be not less than 1 and not more than 50. The second ratio may have a value belonging to at least one range among not less than 1 and not more than 5, not less than 5 and not more than 10, not less than 10 and not more than 15, not less than 15 and not more than 20, not less than 20 and not more than 25, not less than 25 and not more than 30, not less than 30 and not more than 35, not less than 35 and not more than 40, not less than 40 and not more than 45, and not less than 45 and not more than 50.

Hereinafter, the configuration of the single first contact region 27 shall be described. In this embodiment, the first contact region 27 is formed in a layered shape extending in the horizontal directions along the first main surface 3 and is connected to any one or both (in this embodiment, both) of the plurality of adjacent gate structures 15. The first contact region 27 faces the embedded electrodes 18 of the plurality of gate structures 15 with the insulating films 17 of the plurality of gate structures 15 interposed therebetween.

The first contact region 27 has a thickness greater than the thickness of the source region 21 and has a bottom portion positioned further to the bottom portion side of the second semiconductor region 7 than the bottom portion of the source region 21. The bottom portion of the first contact region 27 is positioned at the bottom portion side of the body region 20 with respect to the depth position of the bottom portion of the recess of the embedded electrode 18.

In this embodiment, the first contact region 27 has a thickness greater than the thickness of the body region 20 and has a bottom portion positioned further to the bottom portion side of the second semiconductor region 7 than the bottom portion of the body region 20. The bottom portion of the first contact region 27 is defined by a concentration transition portion where the p-type impurity concentration gradually decreases toward the bottom portion side of the second semiconductor region 7.

The bottom portion of the first contact region 27 may be positioned further to the first main surface 3 side than the depth position of the bottom wall 15c of the gate structure 15. In this case, the first contact region 27 may have a thickness less than the thickness of the body region 20 and have a bottom portion positioned further to the first main surface 3 side than the bottom portion of the body region 20. That is, the first contact region 27 may face the high concentration region 24 with a portion of the body region 20 interposed therebetween.

In this embodiment, the bottom portion of the first contact region 27 is positioned further to the bottom portion side of the second semiconductor region 7 than the depth position of the bottom wall 15c of the gate structure 15. In this embodiment, the first contact region 27 overlaps a portion or an entirety of the high concentration region 24 in sectional view. That is, in the first contact region 27, the n-type impurity concentration of a portion or an entirety of the high concentration region 24 is replaced with the p-type impurity concentration. Therefore, the p-type impurity concentration at the bottom portion (the lower end portion) of the first contact region 27 is reduced by the n-type impurity concentration of the high concentration region 24.

In this embodiment, the first contact region 27 has a bottom portion positioned in the intermediate concentration region 25 across the bottom portion of the high concentration region 24. Therefore, in the first contact region 27, the n-type impurity concentration of a portion of the intermediate concentration region 25 is also replaced with the p-type impurity concentration. The bottom portion of the first contact region 27 is preferably positioned further to the first main surface 3 side than the depth position of the intermediate portion of the well region 22.

The bottom portion of the first contact region 27 overlaps the upper end portion (the first extension portion 22a and the second extension portion 22b) of the well region 22 in a region further to the bottom portion side of the second semiconductor region 7 than the depth position of the bottom wall 15c of the gate structure 15. The first contact region 27 electrically thereby connects the well region 22 to the body region 20.

In this embodiment, the first contact region 27 has a high concentration portion 27a on the first main surface 3 side and a low concentration portion 27b on the bottom portion side of the second semiconductor region 7. The high concentration portion 27a is formed at least further to the first main surface 3 side than the depth position of the bottom wall 15c of the gate structure 15 and forms a main body portion of the first contact region 27. The high concentration portion 27a extends in a layered shape in the horizontal directions along the first main surface 3.

The low concentration portion 27b is formed at the bottom portion side of the second semiconductor region 7 with respect to the high concentration portion 27a and forms the bottom portion (the concentration transition portion) of the first contact region 27. The low concentration portion 27b is also a portion where the p-type impurity concentration is reduced by the n-type impurity concentration of the high concentration region 24. The low concentration portion 27b has a thickness less than the thickness of the high concentration portion 27a and extends in a layered shape in the horizontal directions along the high concentration portion 27a.

The low concentration portion 27b crosses the depth position of the bottom wall 15c of the gate structure 15 in the thickness direction. That is, the low concentration portion 27b has a portion positioned further to the first main surface 3 side than the depth position of the bottom wall 15c of the gate structure 15 and a portion positioned further to the bottom portion of the second semiconductor region 7 than the depth position of the bottom wall 15c of the gate structure 15. The low concentration portion 27b overlaps the upper end portions of the plurality of well regions 22 and is electrically connected to the plurality of well regions 22.

As a matter of course, the low concentration portion 27b may be positioned just at a position further to the first main surface 3 side with respect to the depth position of the bottom wall 15c of the gate structure 15 in accordance with the thickness of the high concentration portion 27a. The low concentration portion 27b may be positioned just at a position further to the bottom portion side of the second semiconductor region 7 with respect to the depth position of the bottom wall 15c of the gate structure 15 in accordance with the thickness of the high concentration portion 27a.

The semiconductor device 1A includes a plurality of second contact regions 28 of the p-type that are each formed in regions oriented along the bottom walls 15c of the plurality of gate structures 15 in the chip 2. The plurality of second contact regions 28 have a p-type impurity concentration higher than the p-type impurity concentration of the plurality of body regions 20. The p-type impurity concentration of the plurality of second contact regions 28 is higher than the p-type impurity concentration of the plurality of well regions 22.

The p-type impurity concentration of the plurality of second contact regions 28 may be not less than 1×10¹⁸ cm⁻³ and not more than 1×10²⁰ cm⁻³. The p-type impurity concentration of the plurality of second contact regions 28 is preferably substantially equal to the p-type impurity concentration of the plurality of first contact regions 27.

The plurality of second contact regions 28 are each formed in a one-to-multiple correspondence with respect to the bottom wall 15c of the plurality of gate structures 15. The plurality of second contact regions 28 are each interposed in regions between the plurality of first contact regions 27 adjacent in the first direction X in plan view. That is, the plurality of second contact regions 28 are positioned on the same straight line as the plurality of first contact regions 27 in the first direction X.

Each of the plurality of second contact regions 28 is formed in a band shape extending along the corresponding gate structure 15 in plan view and faces the embedded electrode 18 with the insulating film 17 interposed therebetween. In the second direction Y, the lengths of the plurality of second contact regions 28 are substantially equal to the lengths of the plurality of first contact regions 27. In the second direction Y, the interval between the plurality of second contact regions 28 is substantially equal to the interval between the plurality of first contact regions 27.

Hereinafter, the configuration of the single second contact region 28 shall be described. The second contact region 28 is formed in the single corresponding well region 22. The second contact region 28 overlaps the high concentration well region 23 and is electrically connected to the high concentration well region 23 in the well region 22. The second contact region 28 is formed at an interval inward from a peripheral edge portion of the well region 22.

The second contact region 28 is formed at an interval to the bottom wall 15c side of the gate structure 15 from the bottom portion of the well region 22 and faces the bottom portion of the second semiconductor region 7 with a portion of the well region 22 interposed therebetween. The second contact region 28 is formed in a columnar shape extending in the thickness direction (the vertical direction Z) of the second semiconductor region 7 in sectional view.

In this embodiment, the second contact region 28 has a bottom portion positioned further to the bottom portion side of the well region 22 than a thickness position of the intermediate portion of the well region 22. As a matter of course, the bottom portion of the second contact region 28 may be positioned further to the bottom wall 15c side of the gate structure 15 than the thickness position of the intermediate portion of the well region 22.

In this embodiment, the bottom portion of the second contact region 28 is positioned further to the bottom wall 15c side of the gate structure 15 than the bottom portion of the intermediate concentration region 25. As a matter of course, the bottom portion of the second contact region 28 may be positioned further to the bottom portion side of the second semiconductor region 7 than the bottom portion of the intermediate concentration region 25. In this case, the second contact region 28 may be formed such as to cross the bottom portion of the well region 22 and have a bottom portion positioned in the second semiconductor region 7.

The second contact region 28 has an upper end portion oriented along a corner portion of the bottom wall 15c of the gate structure 15. The second contact region 28 is electrically connected to the plurality of first contact regions 27 at the upper end portion. That is, the second contact region 28 electrically connects the well region 22 and the high concentration well region 23 to the body region 20 via the plurality of first contact regions 27.

The second contact region 28 has a first extension portion 28a on the first side wall 15a side and a second extension portion 28b on the second side wall 15b side. The first extension portion 28a is led out from a region directly below the gate structure 15 to the lower end portion of the first side wall 15a. The first extension portion 28a faces the embedded electrode 18 with the insulating film 17 interposed therebetween in the horizontal direction.

The first extension portion 28a is connected to the first contact region 27 in a region oriented along the first side wall 15a. Specifically, the first extension portion 28a is connected to both the high concentration portion 27a and the low concentration portion 27b of the first contact region 27.

The second extension portion 28b is led out from a region directly below the gate structure 15 to the lower end portion of the second side wall 15b and faces the first extension portion 28a with the gate structure 15 interposed therebetween. The second extension portion 28b faces the embedded electrode 18 with the insulating film 17 interposed therebetween in the horizontal direction. The second extension portion 28b is connected to the first contact region 27 in a region oriented along the second side wall 15b. Specifically, the second extension portion 28b is connected to both the high concentration portion 27a and the low concentration portion 27b of the first contact region 27.

The second contact region 28 has one or a plurality (in this embodiment, a plurality of) second bulging portions 28c. In the attached drawings, the second contact region 28 having two second bulging portions 28c is illustrated. The number of the second bulging portions 28c is appropriately adjusted by adjusting process conditions.

Each of the plurality of second bulging portions 28c is formed by a portion where a width of the second contact region 28 in the horizontal direction (the first direction X) gradually increases or decreases in the thickness direction, and is formed in multiple stages from the bottom wall 15c of the gate structure 15 toward the bottom portion of the second semiconductor region 7.

The plurality of second bulging portions 28c protrude in an arc shape (circular arc shape) from a region directly below the gate structure 15 to both sides of the gate structure 15. When the second contact region 28 has the single second bulging portion 28c, the single second bulging portion 28c may be formed such as to protrude in an arc shape (circular arc shape) to both sides of the gate structure 15 at an intermediate portion of the second contact region 28.

The semiconductor device 1A includes a main surface insulating film 30 that covers the first main surface 3. The main surface insulating film 30 selectively covers the first surface portion 8, the second surface portion 9, and the first to fourth connecting surface portions 10A to 10D. The main surface insulating film 30 is connected to the insulating films 17 of the plurality of gate structures 15 in the first surface portion 8 and exposes the embedded electrodes 18 of the plurality of gate structures 15.

The main surface insulating film 30 may include at least one among a silicon oxide film, a silicon nitride film, and a silicon oxynitride film. In this embodiment, the main surface insulating film 30 has a single layer structure constituted of a silicon oxide film. The main surface insulating film 30 particularly preferably includes a silicon oxide film constituted of the oxide of the chip 2.

The semiconductor device 1A includes an interlayer film 31 with an insulating property that covers the main surface insulating film 30. The interlayer film 31 may be referred to as an “insulating film,” an “interlayer insulating film,” an “intermediate insulating film,” etc. The interlayer film 31 selectively covers the first surface portion 8, the second surface portion 9, and the first to fourth connecting surface portions 10A to 10D with the main surface insulating film 30 interposed therebetween. The interlayer film 31 covers the plurality of gate structures 15 (the embedded electrodes 18) in the first surface portion 8.

In this embodiment, the interlayer film 31 is continuous with the first to fourth side surfaces 5A to 5D in the peripheral edge portion of the second surface portion 9. As a matter of course, the interlayer film 31 may be formed at an interval inward from the peripheral edge of the second surface portion 9 and expose the second semiconductor region 7 from the peripheral edge portion of the second surface portion 9. The interlayer film 31 may include at least one among a silicon oxide film, a silicon nitride film, and a silicon oxynitride film. The interlayer film 31 preferably includes a silicon oxide film.

The interlayer film 31 may have a thickness of not less than 0.5 μm and not more than 3 μm. The thickness of the interlayer film 31 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm.

The semiconductor device 1A includes a plurality of source openings 32 that are formed in the interlayer film 31. The plurality of source openings 32 are each formed in regions between the plurality of gate structures 15 and expose the plurality of source regions 21 and the plurality of first contact regions 27. The plurality of source openings 32 extend in a band shape in the second direction Y along the plurality of gate structures 15.

Each of the plurality of source openings 32 preferably has an opening end curved in a circular arc shape. In regions between the plurality of adjacent gate structures 15, the plurality of source openings 32 may be formed at intervals in the second direction Y. In this case, the plurality of source openings 32 may be formed in a quadrilateral shape, a rectangular shape (band shape), a circular shape, etc., in plan view.

The semiconductor device 1A includes a plurality of gate openings 33 that are formed in the interlayer film 31 (see FIG. 3). In this embodiment, each of the plurality of gate openings 33 selectively exposes both end portions of the single corresponding gate structure 15.

Specifically, each of the plurality of gate openings 33 selectively exposes both end portions of the embedded electrode 18 of the single corresponding gate structure 15. As with the source opening 32, each of the plurality of gate openings 33 preferably has an opening end curved in a circular arc shape. The plurality of gate openings 33 may be formed in a quadrilateral shape, a rectangular shape (band shape), a circular shape, etc., in plan view.

The semiconductor device 1A includes a source electrode 35 that is arranged on the first main surface 3. The source electrode 35 is a terminal electrode to which the source potential is to be applied from an exterior. The source electrode 35 may be referred to as a “source pad electrode,” a “first pad electrode,” a “first main surface electrode,” a “first terminal electrode,” etc. The source electrode 35 is arranged on a portion of the interlayer film 31 that covers the first surface portion 8.

In this embodiment, the source electrode 35 has a first pad portion 35a, a second pad portion 35b, and a third pad portion 35c. The first pad portion 35a has a comparatively large planar area and forms a main body of the source electrode 35. In this embodiment, the first pad portion 35a, in plan view, is formed in a polygonal shape (in this embodiment, a quadrilateral shape) having four sides parallel to the peripheral edge of the chip 2 and is shifted to the fourth side surface 5D side with respect to a central portion of the first surface portion 8.

The second pad portion 35b has a planar area less than a planar area of the first pad portion 35a and is led out in a band shape (quadrilateral shape) toward the third side surface 5C from one end portion (an end portion at the first side surface 5A side) in the second direction Y of the first pad portion 35a. The third pad portion 35c has a planar area less than the planar area of the first pad portion 35a, is led out in a band shape (quadrilateral shape) toward the third side surface 5C from the other end portion (an end portion at the second side surface 5B side) in the second direction Y of the first pad portion 35a, and faces the second pad portion 35b in the second direction Y.

The planar area of the third pad portion 35c may be substantially equal to the planar area of the second pad portion 35b. As a matter of course, the planar area of the third pad portion 35c may be greater than the planar area of the second pad portion 35b or may be less than the planar area of the second pad portion 35b. Any one or both of the second pad portion 35b and the third pad portion 35c may be used as a terminal portion for current monitoring.

The source electrode 35 does not necessarily have to have both the second pad portion 35b and the third pad portion 35c at the same time. The source electrode 35 may have just either of the second pad portion 35b and the third pad portion 35c. As a matter of course, the source electrode 35 may be constituted of just the first pad portion 35a and may not have both the second pad portion 35b and the third pad portion 35c.

The source electrode 35 enters the plurality of source openings 32 from above the interlayer film 31 and is connected to the first main surface 3 (the first surface portion 8) in the plurality of source openings 32. The source electrode 35 is electrically connected to the plurality of source regions 21 and the plurality of first contact regions 27 in the plurality of source openings 32.

In this embodiment, the source electrode 35 has a laminated structure that includes a lower electrode film 36 and a main electrode film 37 that are laminated in that order from the chip 2 side. In this embodiment, the lower electrode film 36 has a laminated structure that includes a first electrode film 38 and a second electrode film 39. In this embodiment, the first electrode film 38 includes a Ti film, and the second electrode film 39 includes a TiN film. The lower electrode film 36 does not necessarily have to have a laminated structure and may instead have a single layer structure constituted of one of either of the first electrode film 38 (a Ti film) and the second electrode film 39 (a TiN film).

The first electrode film 38 has a thickness less than the thickness of the interlayer film 31. The thickness of the first electrode film 38 may be not less than 10 nm and not more than 100 nm. The thickness of the first electrode film 38 may have a value belonging to at least one range among not less than 10 nm and not more than 25 nm, not less than 25 nm and not more than 50 nm, not less than 50 nm and not more than 75 nm, and not less than 75 nm and not more than 100 nm.

The second electrode film 39 has a thickness less than the thickness of the interlayer film 31. The thickness of the second electrode film 39 is preferably greater than the thickness of the first electrode film 38. The thickness of the second electrode film 39 may be not less than 50 nm and not more than 200 nm. The thickness of the second electrode film 39 may have a value belonging to at least one range among not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm.

The first electrode film 38 entirely covers, in a film shape, a region of the interlayer film 31 in which the plurality of source openings 32 are formed and enters the plurality of source openings 32 from above the interlayer film 31. The first electrode film 38 has a portion that covers an insulating main surface of the interlayer film 31 in a film shape, portions that cover wall surfaces of the plurality of source openings 32 in film shapes, and portions that cover the first main surface 3 in film shapes in the plurality of source openings 32.

Specifically, the first electrode film 38 directly covers the insulating main surface of the interlayer film 31 and faces the gate structures 15 with the interlayer film 31 interposed therebetween. The first electrode film 38 extends in a circular arc shape from above the insulating main surface of the interlayer film 31 in conformance to the opening end of the source opening 32 and covers the wall surface of the source opening 32 in a film shape. The first electrode film 38 covers the first main surface 3 (the first surface portion 8) in a film shape in the source opening 32 and is mechanically and electrically connected to the plurality of source regions 21 and the plurality of first contact regions 27 on the first main surface 3.

The second electrode film 39 directly covers the first electrode film 38. The second electrode film 39 entirely covers, in a film shape, a region of the interlayer film 31, in which the plurality of source openings 32 are formed, with the first electrode film 38 interposed therebetween and enters the plurality of source openings 32 from above the interlayer film 31.

The second electrode film 39 has a portion that covers the insulating main surface of the interlayer film 31 in a film shape with the first electrode film 38 interposed therebetween, portions that cover the wall surfaces of the plurality of source openings 32 in film shapes with the first electrode film 38 interposed therebetween, and portions that cover the first main surface 3 in film shapes with the first electrode film 38 interposed therebetween in the plurality of source openings 32.

Specifically, the second electrode film 39 covers the insulating main surface of the interlayer film 31 with the first electrode film 38 interposed therebetween and faces the gate structure 15 with the interlayer film 31 and the first electrode film 38 interposed therebetween. The second electrode film 39 covers the opening end of the source opening 32 in a circular arc shape with the first electrode film 38 interposed therebetween and covers the wall surface of the source opening 32 in a film shape with the first electrode film 38 interposed therebetween. The second electrode film 39 covers the first main surface 3 (the first surface portion 8) in a film shape with the first electrode film 38 interposed therebetween in the source opening 32 and is electrically connected to the plurality of source regions 21 and the plurality of first contact regions 27 via the first electrode film 38.

The main electrode film 37 includes a conductive material differing from the lower electrode film 36 (the first electrode film 38 and the second electrode film 39). The main electrode film 37 may include at least one among an Al film, an Al alloy film, a Cu film, and a Cu alloy film. The Al alloy film may include at least one among an AlSi alloy film, an AlCu alloy film, and an AlSiCu alloy film. The main electrode film 37 has a thickness greater than the thickness (the total thickness) of the lower electrode film 36. The thickness of the main electrode film 37 is preferably greater than the thickness of the interlayer film 31.

The thickness of the main electrode film 37 may be not less than 0.5 μm and not more than 5 μm. The thickness of the main electrode film 37 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The main electrode film 37 directly covers the lower electrode film 36 (the second electrode film 39). The main electrode film 37 refills the plurality of source openings 32, and entirely covers, in a film shape, a region of the interlayer film 31 in which the plurality of source openings 32 are formed. The main electrode film 37 has a portion that covers the insulating main surface of the interlayer film 31 with the lower electrode film 36 interposed therebetween, portions that cover the wall surfaces of the plurality of source openings 32 with the lower electrode film 36 interposed therebetween, and a portion that covers the first main surface 3 with the lower electrode film 36 interposed therebetween.

Specifically, the main electrode film 37 covers the insulating main surface of the interlayer film 31 with the lower electrode film 36 interposed therebetween and faces the gate structure 15 with the interlayer film 31 and the lower electrode film 36 interposed therebetween. The main electrode film 37 covers the opening end of the source opening 32 with the lower electrode film 36 interposed therebetween. The main electrode film 37 covers the first main surface 3 (the first surface portion 8) with the lower electrode film 36 interposed therebetween in the source opening 32 and is electrically connected to the plurality of source regions 21 and the plurality of first contact regions 27 via the lower electrode film 36.

The semiconductor device 1A includes a gate electrode 40 that is arranged on the first main surface 3. The gate electrode 40 is a terminal electrode to which the gate potential is to be applied from the exterior. The gate electrode 40 may be referred to as a “second pad electrode,” a “second main surface electrode,” a “second terminal electrode,” etc. Although not illustrated, as with the source electrode 35, the gate electrode 40 includes the lower electrode film 36 and the main electrode film 37 that are laminated in that order from the chip 2 side.

The gate electrode 40 is arranged on a portion of the interlayer film 31 that covers the first surface portion 8 at an interval from the source electrode 35. In this embodiment, the gate electrode 40 is arranged in a region at the third side surface 5C side with respect to the first pad portion 35a and faces the first pad portion 35a in the first direction X. Also, the gate electrode 40 is interposed in a region between the second pad portion 35b and the third pad portion 35c and faces both the second pad portion 35b and the third pad portion 35c in the second direction Y. The gate electrode 40, in plan view, is formed in a polygonal shape (in this embodiment, a quadrilateral shape) having four sides parallel to the peripheral edge of the chip 2. The gate electrode 40 has a planar area less than a planar area of the source electrode 35. The gate electrode 40 has a planar area less than the planar area of the first pad portion 35a. The gate electrode 40 may have a planar area less than the planar area of the second pad portion 35b (the third pad portion 35c).

The gate electrode 40 partially faces the plurality of gate structures 15 with the interlayer film 31 interposed therebetween. Specifically, the gate electrode 40 is arranged at an interval inward from both end portions of the plurality of gate structures 15 and faces an inner portion (in this embodiment, the intermediate portion) of the plurality of gate structures 15 with the interlayer film 31 interposed therebetween.

In this embodiment, the gate electrode 40 does not have a portion that is electrically connected directly to the plurality of gate structures 15. As a matter of course, the gate electrode 40 may be electrically connected to the plurality of gate structures 15 via the plurality of gate openings 33. Portions of the plurality of gate structures 15 positioned at the gate electrode 40 may be removed. In this case, the gate electrode 40 may face the body region 20 with the main surface insulating film 30 and the interlayer film 31 interposed therebetween.

The semiconductor device 1A includes a gate wiring 41 that is led out onto the first main surface 3 from the gate electrode 40. The gate wiring 41 may be referred to as a “gate finger,” a “gate finger electrode,” etc. The gate wiring 41 transmits the gate potential applied to the gate electrode 40 to another region. Although not illustrated, as with the source electrode 35 (the gate electrode 40), the gate wiring 41 includes the lower electrode film 36 and the main electrode film 37 that are laminated in that order from the chip 2 side.

The gate wiring 41 is led out onto a portion of the interlayer film 31 that covers the first surface portion 8 from the gate electrode 40. The gate wiring 41 is routed in a band shape at a region between the peripheral edge of the first surface portion 8 and the source electrode 35. The gate wiring 41 has a portion extending in a band shape in the first direction X and a portion extending in a band shape in the second direction Y in plan view. In this embodiment, the gate wiring 41 is formed in a band shape with ends having four sides parallel to the peripheral edge of the first main surface 3 and surrounds the source electrode 35.

The gate wiring 41 intersects with (specifically, is orthogonal to) the end portions (in this embodiment, both end portions) of the plurality of gate structures 15. The gate wiring 41 enters the plurality of gate openings 33 from above the interlayer film 31 and is mechanically and electrically connected to the end portions (both end portions) of the plurality of gate structures 15 (the embedded electrodes 18) in the plurality of gate openings 33. The gate potential applied to the gate electrode 40 is thereby applied to the plurality of gate structures 15 via the gate wiring 41.

The semiconductor device 1A includes a drain electrode 42 that covers the second main surface 4. The drain electrode 42 is a terminal electrode to which the drain potential is to be applied from the exterior. The drain electrode 42 may be referred to as a “third pad electrode,” a “third main surface electrode,” a “third terminal electrode,” etc.

The drain electrode 42 is electrically connected to the first semiconductor region 6. The drain electrode 42 may cover a whole region of the second main surface 4 such as to be continuous with the peripheral edge of the second main surface 4 (the first to fourth side surfaces 5A to 5D). The drain electrode 42 may partially cover the second main surface 4 such as to expose the peripheral edge portion of the second main surface 4.

A breakdown voltage applicable between the source electrode 35 and the drain electrode 42 (between the first main surface 3 and the second main surface 4) may be not less than 500 V and not more than 3000 V. The breakdown voltage may have a value belonging to at least one range among not less than 500 V and not more than 1000 V, not less than 1000 V and not more than 1500 V, not less than 1500 V and not more than 2000 V, not less than 2000 V and not more than 2500 V, and not less than 2500 V and not more than 3000 V.

As described above, the semiconductor device 1A includes the chip 2, the second semiconductor region 7 (the semiconductor layer) of the n-type, the gate structure 15 of the trench type, the body region 20 of the p-type, and the high concentration region 24 of the n-type. The chip 2 has the first main surface 3. The second semiconductor region 7 is formed in the surface layer portion of the first main surface 3. The gate structure 15 is formed in the first main surface 3 and is positioned in the second semiconductor region 7.

The body region 20 is formed in a region at the first main surface 3 side with respect to the depth position of the bottom wall 15c of the gate structure 15 in the surface layer portion of the first main surface 3. The high concentration region 24 is formed in a thickness range between the bottom wall 15c of the gate structure 15 and the bottom portion of the body region 20 in the chip 2. The high concentration region 24 has an impurity concentration higher than the impurity concentration of the second semiconductor region 7.

With this configuration, the semiconductor device 1A capable of improving electrical characteristics is provided. For example, the resistance value in the vicinity of the gate structure 15 is reduced by the high concentration region 24 formed below the body region 20. Such a configuration is effective in reducing the on-resistance and the JFET resistance. The high concentration region 24 cancels out the undesirable p-type impurity introduced to the lateral side of the gate structure 15 due to a process error, etc. Fluctuations of the gate threshold voltage due to the undesirable p-type impurity are thereby suppressed.

The chip 2 preferably contains SiC. With this configuration, the semiconductor device 1A as an SiC semiconductor device capable of improving electrical characteristics is provided. The high concentration region 24 may have a bottom portion positioned at the first main surface 3 side with respect to the depth position of the bottom wall 15c of the gate structure 15. With this configuration, an increase in current density in the vicinity of the bottom wall 15c of the gate structure 15 is suppressed. Thereby, the electric field with respect to the bottom wall 15c of the gate structure 15 is relaxed, and a decrease in the withstand voltage due to the concentration of the electric field is suppressed.

The high concentration region 24 may be connected to the gate structure 15. With this configuration, the undesirable p-type impurity introduced to the lateral side of the gate structure 15 is appropriately canceled out by the high concentration region 24. The fluctuations of the gate threshold voltage are thereby appropriately suppressed.

The high concentration region 24 may have a thickness less than the thickness of the body region 20. With this configuration, a decrease in the cross-sectional area of the body region 20 due to the high concentration region 24 is suppressed. Therefore, in the configuration in which the high concentration region 24 is present, the function of the body region 20 is appropriately secured.

The gate structure 15 may have the side walls (the first side wall 15a and the second side wall 15b) having an inclination angle of not less than 87° and not more than 93°. For example, when the gate structure 15 has the side walls (the first side wall 15a and the second side wall 15b) inclined at an inclination angle of less than 87°, depending on process conditions, the p-type impurity is easily introduced to the lateral side of the gate structure 15 via the side walls (the first side wall 15a and the second side wall 15b) of the trench 16 of the gate structure 15.

Therefore, with the gate structure 15 having the side walls (the first side wall 15a and the second side wall 15b) substantially perpendicular to the first main surface 3, undesirable introduction of the p-type impurity via the side walls (the first side wall 15a and the second side wall 15b) is suppressed. Also, even when the p-type impurity is introduced, the p-type impurity is canceled out by the high concentration region 24. Therefore, the fluctuations of the gate threshold voltage are appropriately suppressed.

The plurality of gate structures 15 may be formed at an interval in the first main surface 3. In this case, the body region 20 may be formed in a region between the plurality of gate structures 15. Also, the high concentration region 24 may be formed in a region between the plurality of gate structures 15 in a thickness range between the bottom wall 15c of each of the plurality of gate structures 15 and the bottom portion of the body region 20.

With this configuration, the effect of reducing the resistance value by the high concentration region 24 can be obtained in a region between the plurality of gate structures 15. Also, the effect of suppressing the fluctuations of the gate threshold voltage can be obtained for the plurality of gate structures 15. In this configuration, the high concentration region 24 may be connected to the plurality of gate structures 15.

The semiconductor device 1A may include the source region 21 of the n-type (an impurity region) and the channel region 26. In this case, the source region 21 may be formed in a region at the first main surface 3 side with respect to the body region 20 such as to be oriented along the gate structure 15.

The high concentration region 24 may face the source region 21 with a portion of the body region 20 interposed therebetween. The channel region 26 may be formed between the source region 21 and the high concentration region 24 in the body region 20. The high concentration region 24 may have an n-type impurity concentration less than the n-type impurity concentration of the source regions 21.

The semiconductor device 1A may include the well region 22 of the p-type that is formed in a region oriented along the bottom wall 15c of the gate structure 15 in the chip 2. With this configuration, a depletion layer extends from a pn junction portion between the well region 22 and the second semiconductor region 7 when a reverse bias voltage is applied.

Also, with this configuration, the undesirable p-type impurity that may be introduced to the lateral side of the gate structure 15 in accompaniment with a forming step of the well region 22 is canceled out by the high concentration region 24. Thereby, the withstand voltage is improved by the well region 22, and at the same time, the fluctuations of the gate threshold voltage are appropriately suppressed.

The well region 22 may have the upper end portion oriented along the corner portion of the bottom wall 15c of the gate structure 15. In this case, the high concentration region 24 may be formed in a thickness range between the bottom portion of the body region 20 and the upper end portion of the well region 22. With this configuration, the fluctuations of the gate threshold voltage due to the p-type impurity constituting the upper end portion of the well region 22 are appropriately suppressed by the high concentration region 24. The well region 22 may have a thickness greater than the thickness of the body region 20.

The semiconductor device 1A may include the high concentration well region 23 of the p-type that is formed in the well region 22 at an interval to the bottom wall 15c side of the gate structure 15 from the bottom portion of the well region 22. The high concentration well region 23 may have a p-type impurity concentration higher than the p-type impurity concentration of the well region 22.

With this configuration, the electrical responsiveness of the well region 22 is improved by the high concentration well region 23. Also, with this configuration, the fluctuations of the gate threshold voltage due to the p-type impurity constituting the high concentration well region 23 are suppressed by the high concentration region 24. The high concentration well region 23 may have a bottom portion positioned at the bottom wall 15c side of the gate structure 15 with respect to the depth position of the intermediate portion of the well region 22.

The semiconductor device 1A may include the first contact region 27 of the p-type that is formed in a region oriented along the side wall of the gate structure 15 in the chip 2. The first contact region 27 may have an impurity concentration higher than the impurity concentration of the body region 20. With this configuration, the electrical responsiveness of the body region 20 is improved by the first contact region 27.

The semiconductor device 1A may include the first contact region 27 of the p-type that is formed in a region oriented along the bottom wall 15c of the gate structure 15 in the chip 2. The first contact region 27 may have an impurity concentration higher than the impurity concentration of the body region 20. With this configuration, the electrical responsiveness of the body region 20 is improved by the first contact region 27.

The semiconductor device 1A may include the second contact region 28 of the p-type that is formed in a region oriented along the bottom wall 15c of the gate structure 15 in the chip 2. The second contact region 28 may have an impurity concentration higher than the impurity concentration of the body region 20.

The second contact region 28 may be electrically connected to the first contact region 27. With this configuration, the electrical responsiveness of the second contact region 28 is improved by the first contact region 27. The second contact region 28 may electrically connect the well region 22 to the first contact region 27. With this configuration, the electrical responsiveness of the well region 22 is improved by the second contact region 28.

The semiconductor device 1A may include the intermediate concentration region 25 of the n-type that is formed in a region below the high concentration region 24 in the chip 2. The intermediate concentration region 25 may have an impurity concentration higher than the impurity concentration of the second semiconductor region 7 and lower than the impurity concentration of the high concentration region 24.

With this configuration, the resistance value in a region below the high concentration region 24 is reduced by the intermediate concentration region 25. Such a configuration is effective in reducing the on-resistance and the JFET resistance. Since the intermediate concentration region 25 has an impurity concentration lower than that of the high concentration region 24, an increase in current density in the vicinity of the bottom wall 15c of the gate structure 15 is suppressed. Therefore, a decrease in the withstand voltage due to the concentration of the electric field is suppressed.

In the semiconductor device 1A, the intermediate concentration region 25 may have a region positioned on an upper side with respect to the depth position of the bottom wall 15c of the gate structure 15 and a region positioned on a lower side with respect to the depth position of the bottom wall 15c of the gate structure 15.

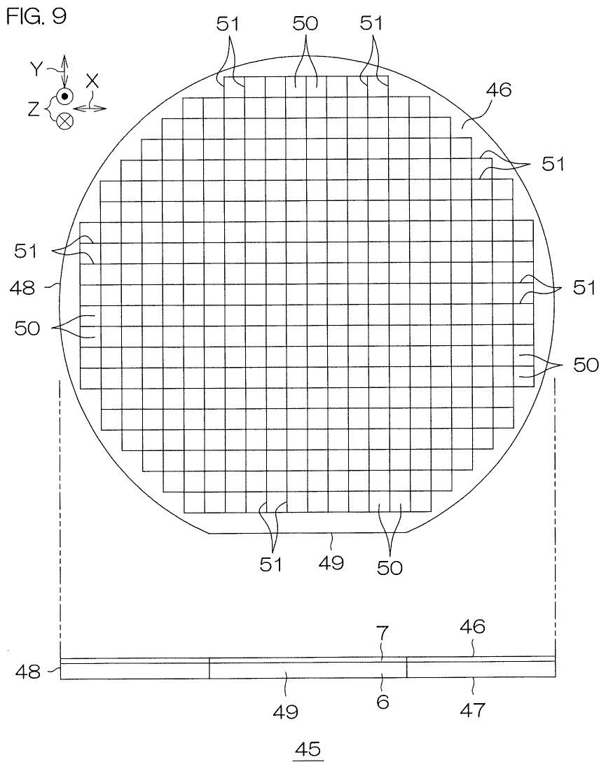

FIG. 9 is a schematic view showing a wafer 45 used in manufacture of the semiconductor device 1A. The wafer 45 is a base material of the chip 2 and includes the SiC monocrystal. The wafer 45 is formed in a flat disk shape. As a matter of course, the wafer 45 may be formed in a flat rectangular parallelepiped shape. The wafer 45 has a first wafer main surface 46 at one side, a second wafer main surface 47 at the other side, and a wafer side surface 48 that connects the first wafer main surface 46 and the second wafer main surface 47.

The first wafer main surface 46 corresponds to the first main surface 3 of the chip 2, and the second wafer main surface 47 corresponds to the second main surface 4 of the chip 2. The first wafer main surface 46 and the second wafer main surface 47 are formed by c-planes of the SiC monocrystal. The first wafer main surface 46 is formed by the silicon plane of the SiC monocrystal, and the second wafer main surface 47 is formed by the carbon plane of the SiC monocrystal. The wafer 45 (the first wafer main surface 46 and the second wafer main surface 47) has the off direction and the off angle described above.

The wafer 45 has a mark 49 that indicates a crystal orientation of the SiC monocrystal at the wafer side surface 48. The mark 49 may include any one or both of an orientation flat and an orientation notch. The orientation flat is constituted of a notched portion that is notched rectilinearly in plan view. The orientation notch is constituted of a notched portion that is notched in a recessed shape (for example, a tapered shape) toward a central portion of the first wafer main surface 46 in plan view.

The mark 49 may include any one or both of a first orientation flat that extends in the a-axis direction and a second orientation flat that extends in the m-axis direction. The mark 49 may include any one or both of an orientation notch that is recessed in the a-axis direction and an orientation notch flat that is recessed in the m-axis direction.

The wafer 45 includes the first semiconductor region 6 of the n-type that is formed in a surface layer portion of the second wafer main surface 47. The first semiconductor region 6 is formed in a layered shape extending along the second wafer main surface 47 and is exposed from the second wafer main surface 47 and the wafer side surface 48. In this embodiment, the first semiconductor region 6 is constituted of a semiconductor wafer (an SiC wafer) of the n-type that contains an SiC monocrystal (a semiconductor monocrystal) and has the off direction and off angle described above.

The wafer 45 includes the second semiconductor region 7 of the n-type that is formed in a surface layer portion of the first wafer main surface 46. The second semiconductor region 7 is formed in a layered shape extending along the first wafer main surface 46 and is exposed from the first wafer main surface 46 and the wafer side surface 48.

The second semiconductor region 7 is constituted of an epitaxial layer (an SiC epitaxial layer) of the n-type that includes an SiC monocrystal (a semiconductor monocrystal) and is laminated on the first semiconductor region 6. The second semiconductor region 7 has the off direction and the off angle described above. That is, in this embodiment, the wafer 45 is constituted of an epitaxial wafer (a so-called epi-wafer) having a laminated structure that includes a semiconductor wafer and an epitaxial layer.

The wafer 45 includes a plurality of device regions 50 and a plurality of intended cutting lines 51. For example, the plurality of device regions 50 and the plurality of intended cutting lines 51 are demarcated by alignment marks, etc., formed at the first wafer main surface 46 side. Each of the device regions 50 is a region corresponding to the semiconductor device 1A. The plurality of device regions 50 are each set in a quadrilateral shape in plan view.

In this embodiment, the plurality of device regions 50 are set in a matrix along the first direction X and the second direction Y in plan view. The plurality of device regions 50 are each set at intervals inward from a peripheral edge of the first wafer main surface 46 in plan view. The plurality of intended cutting lines 51 are set in a lattice extending in the first direction X and the second direction Y such as to demarcate the plurality of device regions 50.

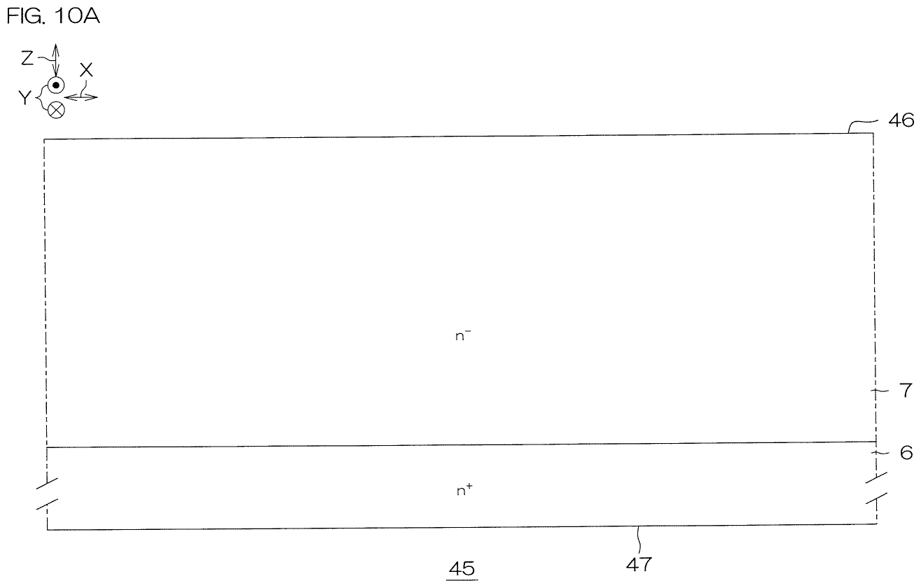

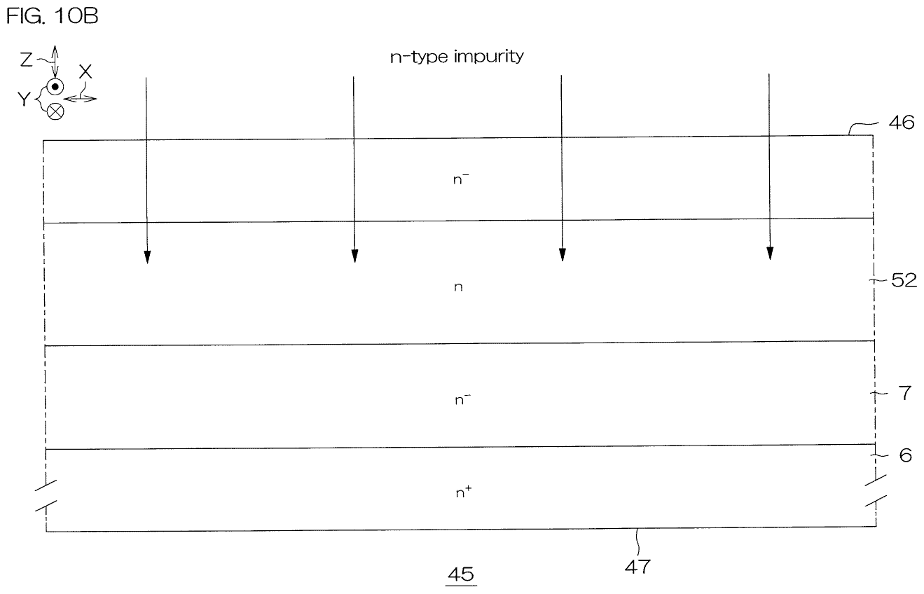

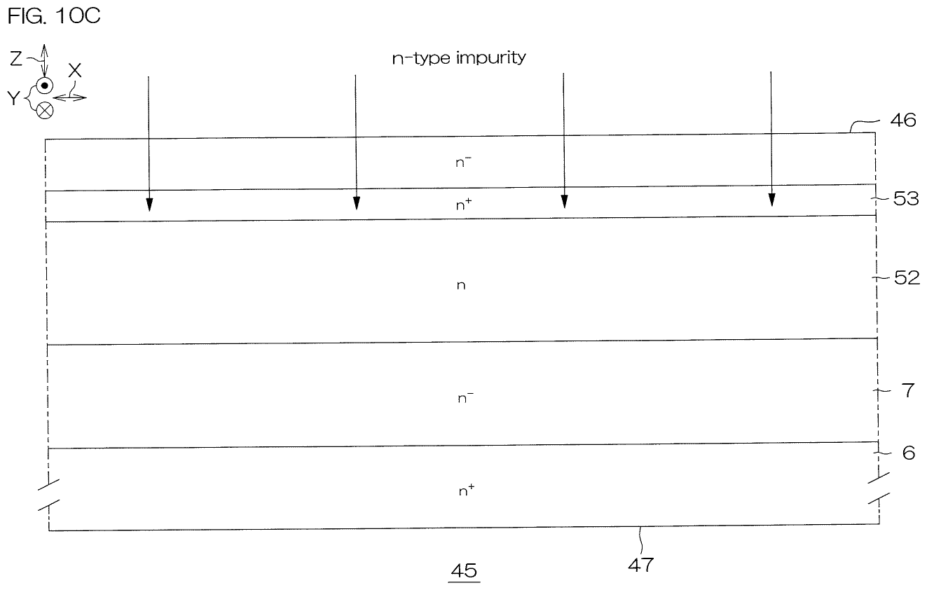

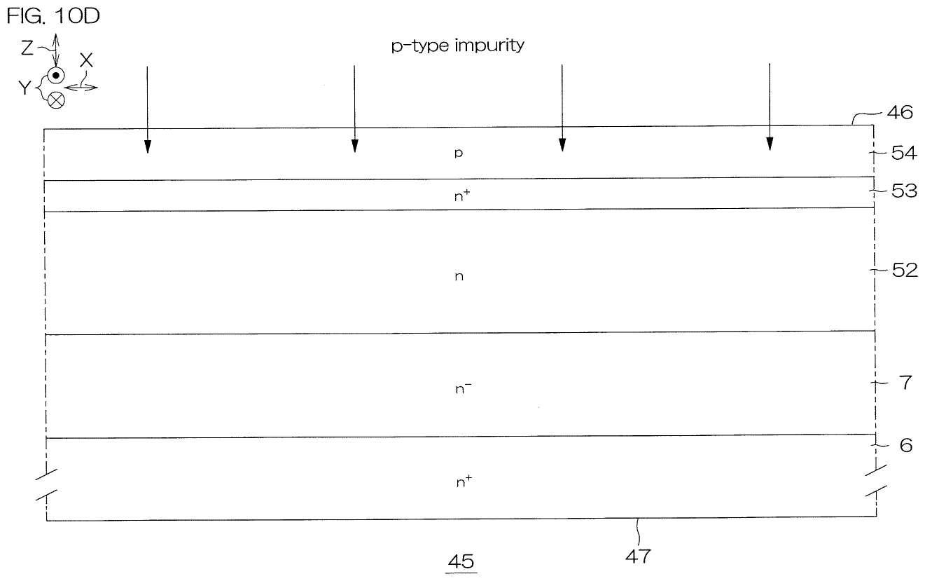

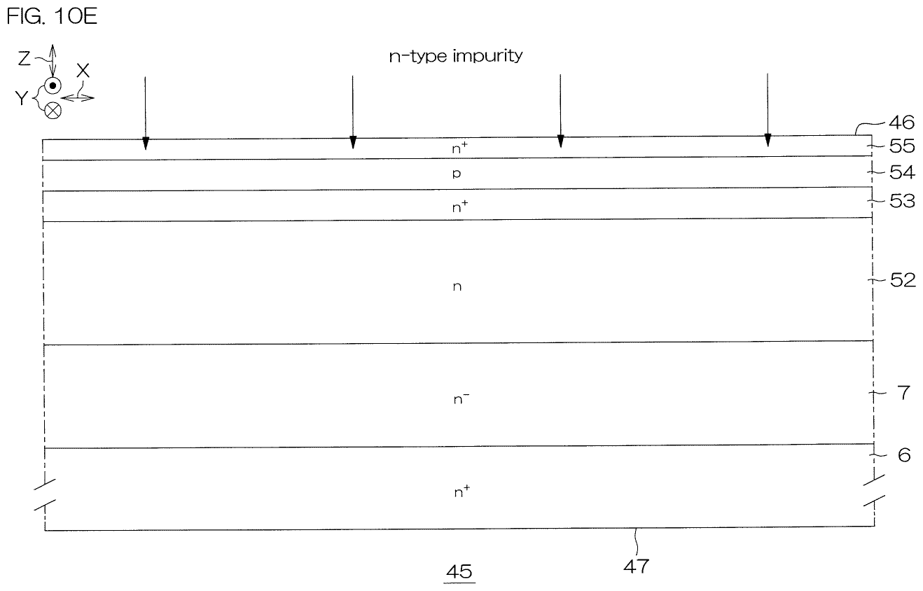

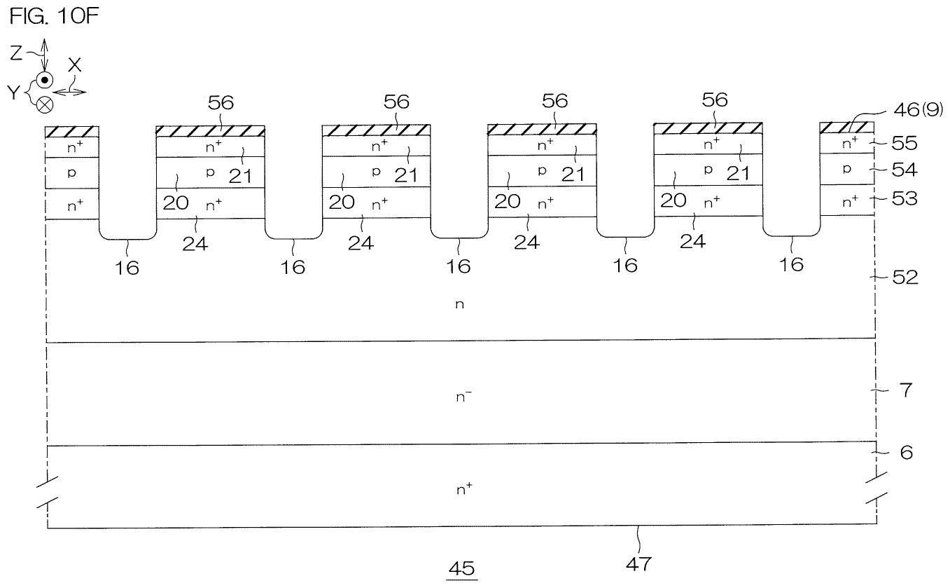

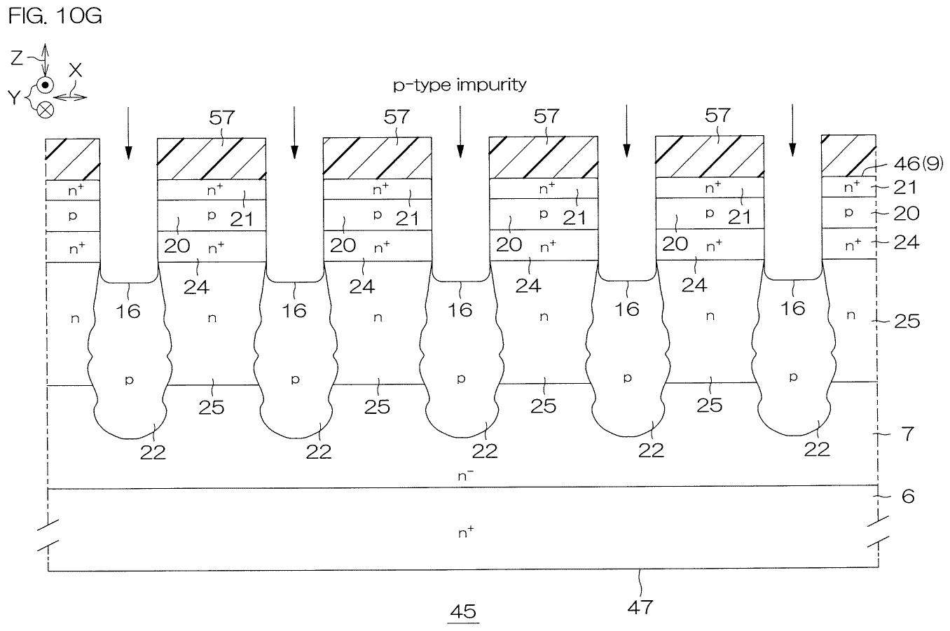

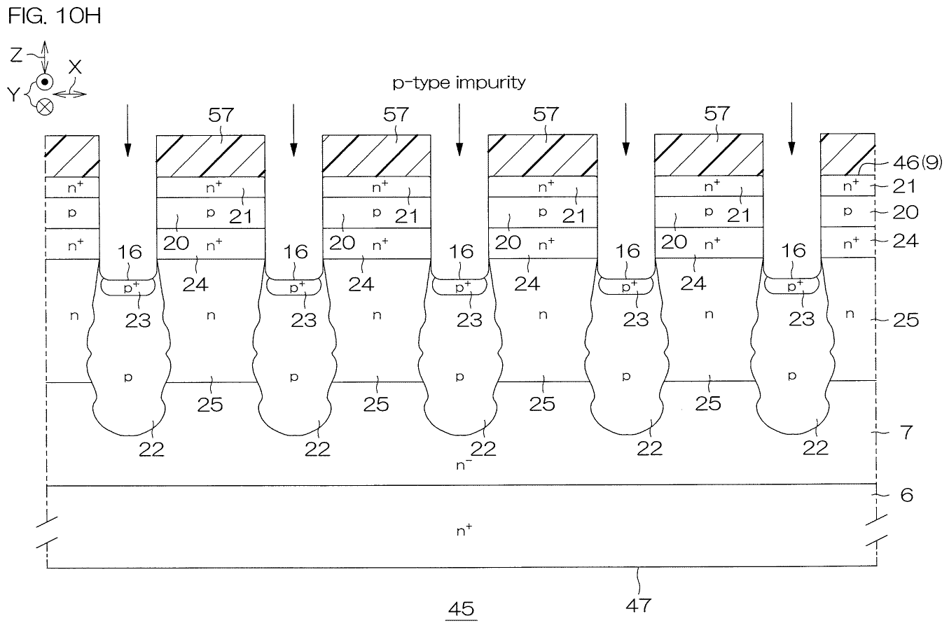

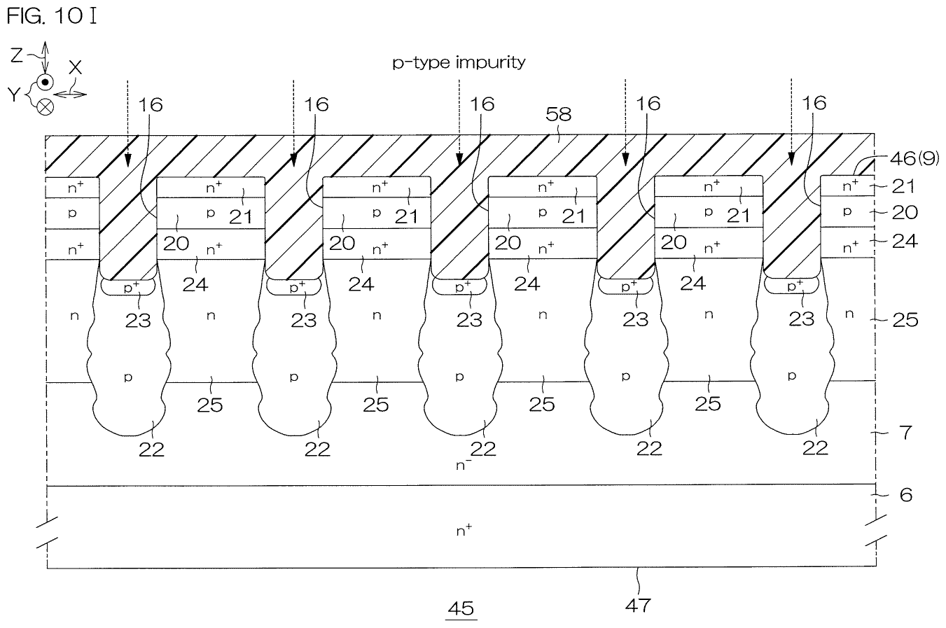

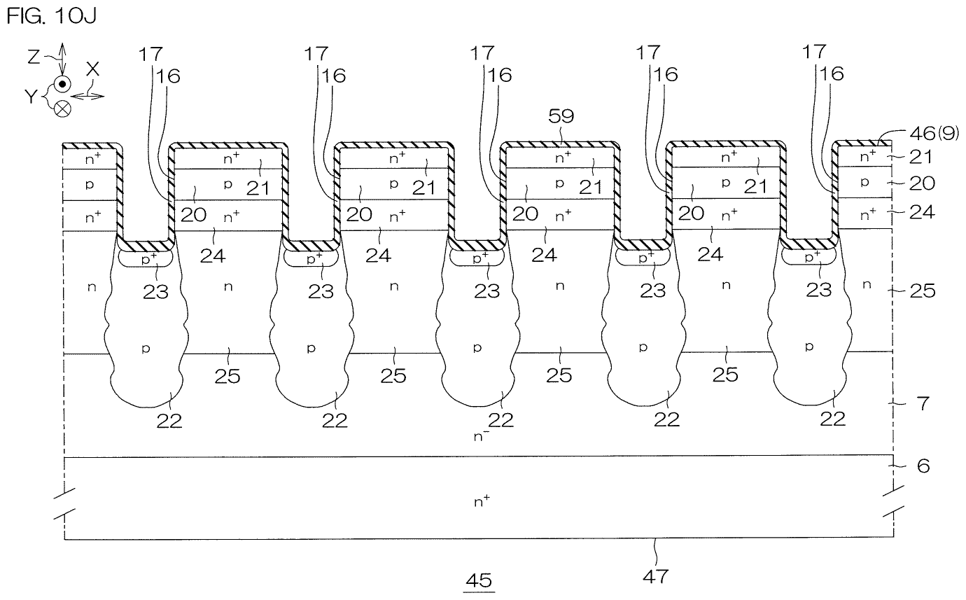

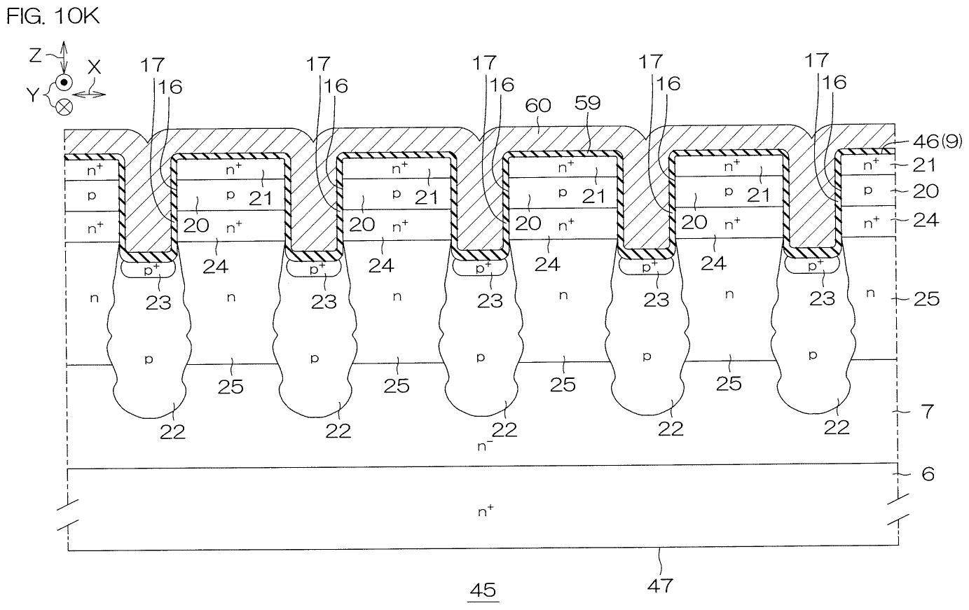

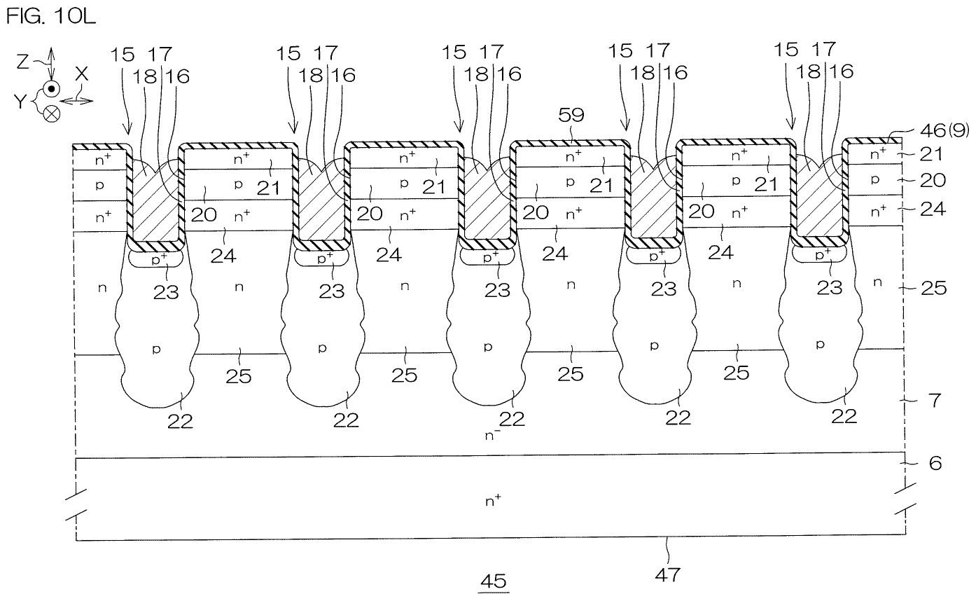

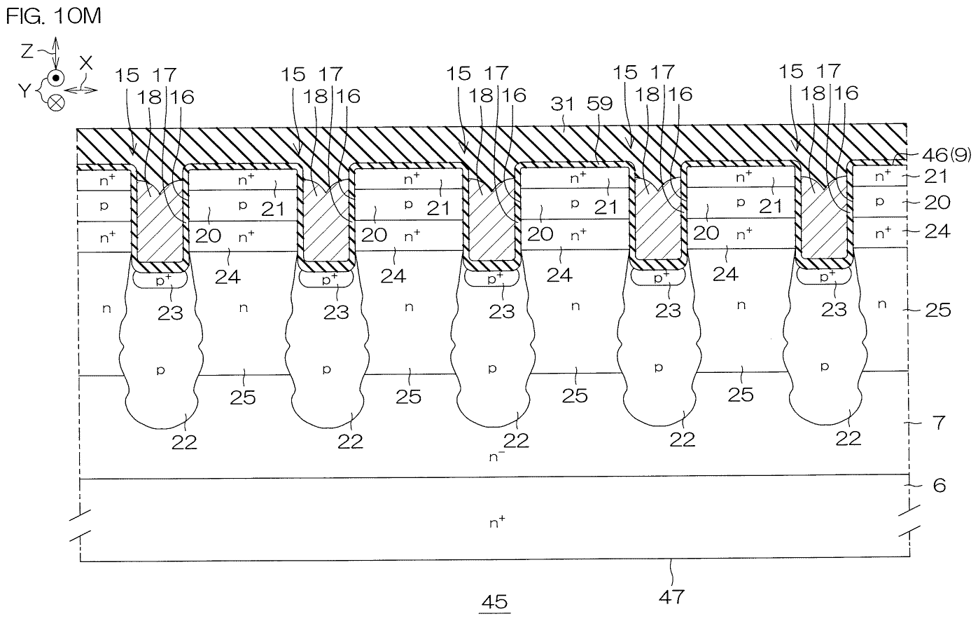

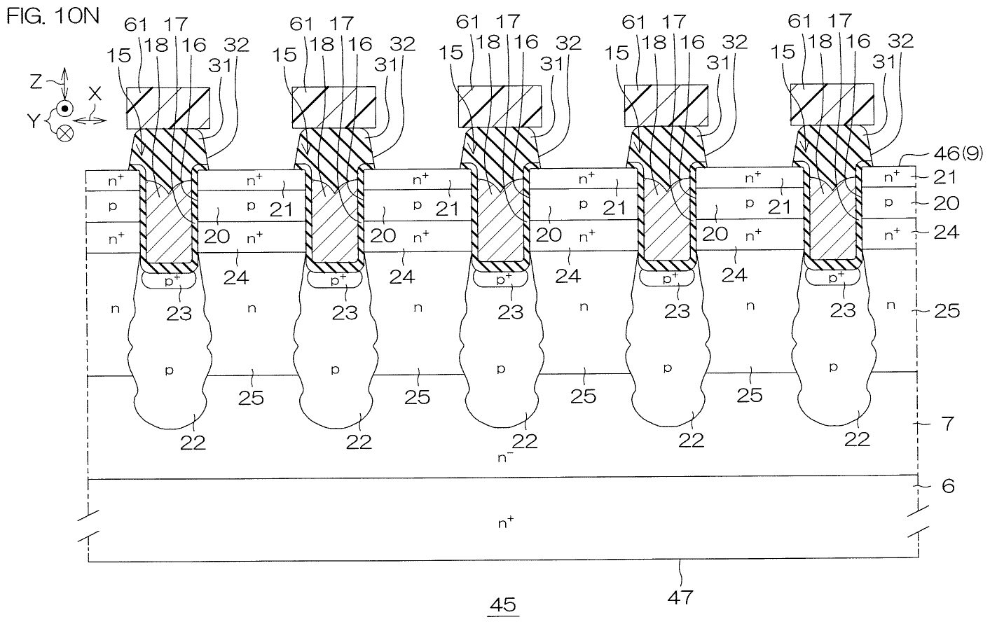

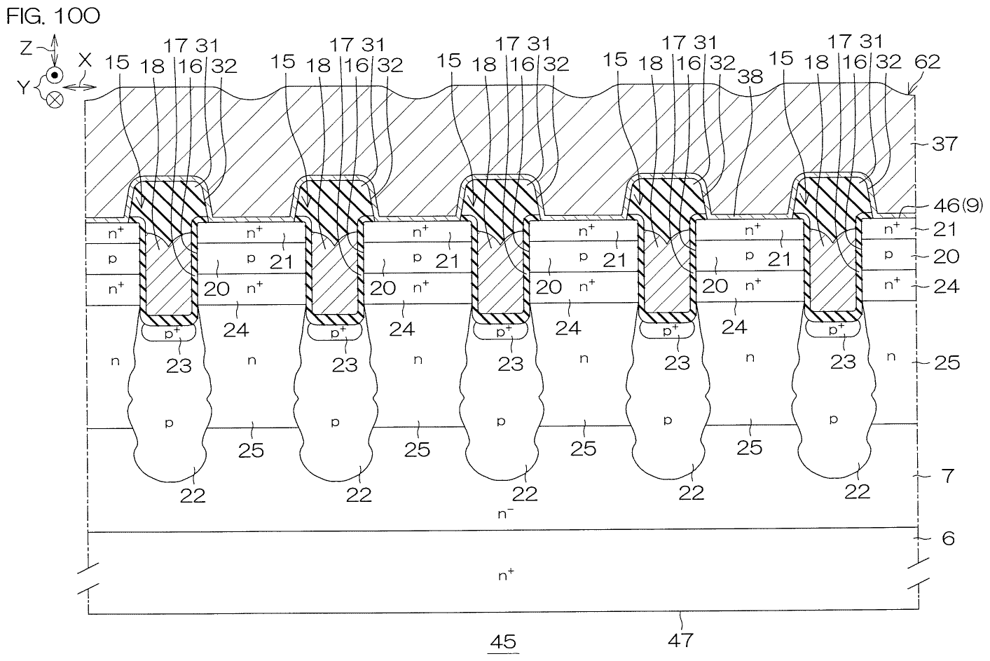

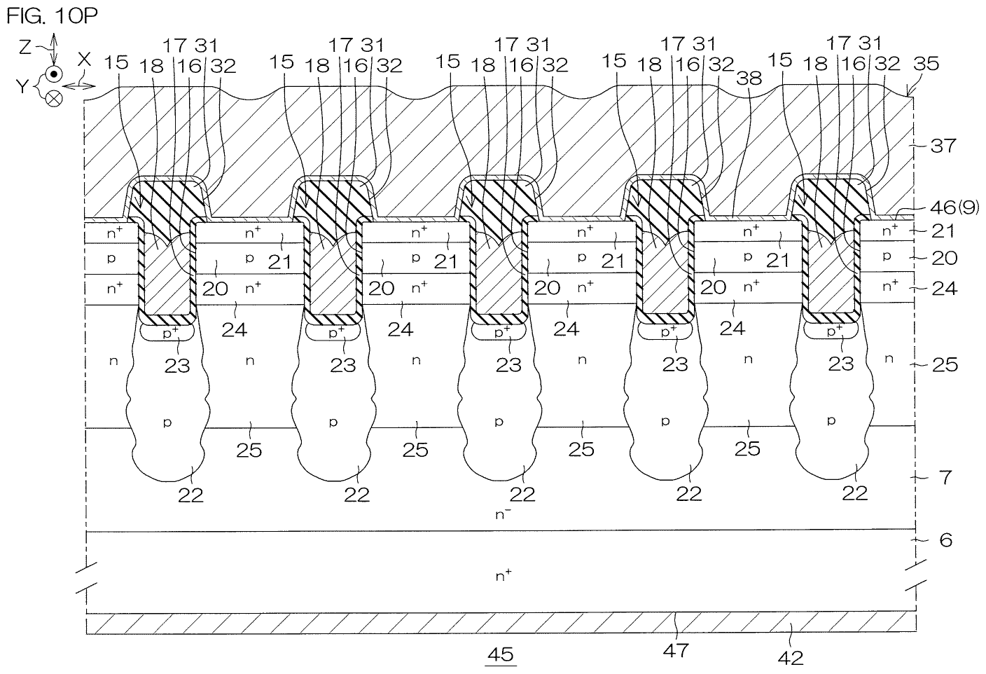

FIG. 10A to FIG. 10P are sectional views showing an example of a manufacturing method of the semiconductor device 1A. In FIGS. 10A to 10P, a cross section of a region corresponding to FIG. 5 is illustrated. First, referring to FIG. 10A, the above-described wafer 45 (see FIG. 9) is prepared.

Next, referring to FIG. 10B, a base intermediate concentration region 52 is formed in the surface layer portion of the first wafer main surface 46 in the wafer 45 (the second semiconductor region 7). The base intermediate concentration region 52 is a base of the plurality of intermediate concentration regions 25. In a forming step of the base intermediate concentration region 52, the n-type impurity is introduced into the second semiconductor region 7 by an ion implantation method.

The ion implantation method may be any one or both of a channeling ion implantation method and a random ion implantation method. In a channeling ion implantation step, the n-type impurity is introduced into the second semiconductor region 7 along an axis channel of the second semiconductor region 7. The axis channel is constituted of regions (channels) that are of comparatively wide interatomic distance (atomic interval) in the SiC monocrystal constituting the second semiconductor region 7 and are surrounded by atomic rows constituting a crystal axis extending in a lamination direction (crystal growth direction).

That is, the axis channel is constituted of regions that are sparse in atomic rows and extend in the lamination direction and are regions in which atomic rows (interatomic distance/atomic density) in the horizontal directions are sparse in plan view. The axis channel is preferably constituted of regions surrounded by atomic rows oriented along a low index crystal axis among crystal axes. A low index crystal axis is, in terms of Miller indices (a1, a2, a3, and c), a crystal axis expressed by absolute values of “a1,” “a2,” “a3,” and “c” all being not more than 2 (preferably not more than 1).

In this embodiment, the axis channel is constituted of regions surrounded by atomic rows oriented along the c-axis (the (0001) axis) of the SiC monocrystal. That is, the axis channel extends along the c-axis and has the off direction and the off angle described above. In other words, the axis channel is inclined by just the off angle toward the off direction from the vertical axis.

In the channeling ion implantation step, the n-type impurity is implanted into a deep region of the second semiconductor region 7 while repeating small angle scattering due to a channeling effect. That is, in the case of the channeling implantation method, a collision probability of the n-type impurity with respect to the atomic rows of the SiC monocrystal is reduced. Therefore, the channeling ion implantation step is effective when forming the base intermediate concentration region 52 that is relatively deep.

On the other hand, in a random ion implantation step, the n-type impurity is introduced into the second semiconductor region 7 in a random direction. The random direction is a direction other than the axis channel of the second semiconductor region 7 (that is, a direction intersecting with the axis channel).

For example, the random direction is the vertical direction Z. In the case of the random ion implantation step, since the collision probability of the n-type impurity with respect to the atomic row of the SiC monocrystal is high, the base intermediate concentration region 52 is formed in a relatively shallow region. Therefore, the random ion implantation step is effective when forming the base intermediate concentration region 52 that is relatively shallow.

In the forming step of the base intermediate concentration region 52, the base intermediate concentration region 52 extending in a layered shape in the horizontal directions along the first wafer main surface 46 is formed. The base intermediate concentration region 52 may be formed in the second semiconductor region 7 at an interval to the bottom portion side of the second semiconductor region 7 from the first wafer main surface 46. As a matter of course, the base intermediate concentration region 52 may be exposed from the first wafer main surface 46. In consideration of cancelation of the p-type impurity and the n-type impurity in a subsequent step, etc., a base high concentration region 53 is preferably formed at an interval from the first wafer main surface 46.

Next, referring to FIG. 10C, the base high concentration region 53 is formed in the surface layer portion of the first wafer main surface 46 in the wafer 45 (the second semiconductor region 7). The base high concentration region 53 is a base of the plurality of high concentration regions 24.

In a forming step of the base high concentration region 53, the n-type impurity is introduced into the second semiconductor region 7 by an ion implantation method. The ion implantation method may be any one or both of a channeling ion implantation method and a random ion implantation method. Since the n-type impurity is introduced into a region shallower than the base intermediate concentration region 52, the ion implantation method is preferably a random ion implantation method.

The n-type impurity is introduced into a thickness range of the first wafer main surface 46 and the base intermediate concentration region 52. Thereby, the base high concentration region 53 extending in a layered shape in the horizontal directions along the first wafer main surface 46 is formed. The base high concentration region 53 may be formed in the second semiconductor region 7 at an interval to the bottom portion side of the second semiconductor region 7 from the first wafer main surface 46.

As a matter of course, the base high concentration region 53 may be exposed from the first wafer main surface 46. In consideration of cancelation of the p-type impurity and the n-type impurity in a subsequent step, etc., the base high concentration region 53 is preferably formed at an interval to the bottom portion side of the second semiconductor region 7 from the first wafer main surface 46.

Next, referring to FIG. 10D, a base body region 54 is formed in the surface layer portion of the first wafer main surface 46 in the wafer 45 (the second semiconductor region 7). The base body region 54 is a base of the plurality of body regions 20. In the forming step of the base body region 54, the p-type impurity is introduced into the second semiconductor region 7 by an ion implantation method.

The ion implantation method may be any one or both of a channeling ion implantation method and a random ion implantation method. Since the p-type impurity is introduced into a region shallower than the base high concentration region 53, the ion implantation method is preferably a random ion implantation method. In this embodiment, the p-type impurity is introduced into a thickness range of the first wafer main surface 46 and the base high concentration region 53. The base body region 54 extending in a layered shape in the horizontal directions along the first wafer main surface 46 is thereby formed.

Next, referring to FIG. 10E, a base source region 55 is formed in the surface layer portion of the first wafer main surface 46 in the wafer 45 (the base body region 54). The base source region 55 is a base of the plurality of source regions 21. In a forming step of the base source region 55, the n-type impurity is introduced into the base body region 54 by an ion implantation method.

The ion implantation method may be any one or both of a channeling ion implantation method and a random ion implantation method. Since the n-type impurity is introduced into a region shallower than the base body region 54, the ion implantation method is preferably a random ion implantation method. The base source region 55 extending in a layered shape in the horizontal directions along the first wafer main surface 46 is thereby formed.

A step order of the forming step of the base intermediate concentration region 52, the forming step of the base high concentration region 53, the forming step of the body region 20, and the forming step of the base source region 55 is arbitrary and may be appropriately replaced and performed.

Next, referring to FIG. 10F, the mesa 11 and the plurality of trenches 16 are formed in the first wafer main surface 46. In this step, first, a first mask 56 having a predetermined layout is formed on the first wafer main surface 46. The first mask 56 may be an inorganic mask (for example, a silicon oxide film) or may be an organic mask (resist mask). The first mask 56 exposes regions in which the second surface portion 9 and the plurality of trenches 16 are to be formed and covers regions other than these.

Next, unnecessary portions of the wafer 45 are removed by an etching method via the first mask 56. The etching method may be any one or both of a wet etching method and a dry etching method.

The first surface portion 8, the second surface portion 9, the first to fourth connecting surface portions 10A to 10D, and the plurality of trenches 16 are thereby formed. Also, the base high concentration region 53, the base body region 54, and the base source region 55 are separated by the plurality of trenches 16, and the plurality of body regions 20, the plurality of source regions 21, and the plurality of high concentration regions 24 are formed.

In this step, the plurality of trenches 16 is formed substantially perpendicular to the first wafer main surface 46. That is, the first side wall 15a and the second side wall 15b of the plurality of trenches 16 have an inclination angle of not less than 87° and not more than 93°. Also, the bottom walls 15c of the plurality of trenches 16 are formed flat in the horizontal direction. With the trench 16 constituted of the bottom wall 15c formed of a flat surface, the accuracy of introduction of the impurity via the bottom wall 15c is improved. The first mask 56 is removed after this step.

Next, referring to FIG. 10G, the plurality of well regions 22 are formed in regions oriented along the bottom walls 15c of the plurality of trenches 16 in the wafer 45 (the second semiconductor region 7). In this step, first, a second mask 57 having a predetermined layout is formed on the first wafer main surface 46. The second mask 57 may be an inorganic mask (for example, a silicon oxide film) or may be an organic mask (resist mask).

The second mask 57 exposes regions in which the plurality of well regions 22 are to be formed (that is, the plurality of trenches 16) and covers regions other than these. Next, the p-type impurity is introduced into the second semiconductor region 7 via the bottom walls 15c of the plurality of trenches 16 by an ion implantation method via the second mask 57. The ion implantation method may be any one or both of a channeling ion implantation method and a random ion implantation method.

Preferably, the ion implantation method is a random ion implantation method, and the p-type impurity is introduced into the wafer 45 at an implantation angle substantially perpendicular to the first wafer main surface 46. Preferably, the ion implantation method is a vertical ion implantation method and is not an oblique ion implantation method. With this step, introduction of the p-type impurity into the wafer 45 via the first side wall 15a and the second side wall 15b of the trench 16 is suppressed.

In the random ion implantation step, the p-type impurity may be implanted in a single stage at a target depth position of the second semiconductor region 7 (the base intermediate concentration region 52). The p-type impurity may be implanted in multiple stages at different target depth positions of the second semiconductor region 7 (base intermediate concentration region 52) with different implantation energies. The implantation step of the p-type impurity may include a step of implanting the p-type impurity a plurality of times into the same target depth position of the second semiconductor region 7 (the base intermediate concentration region 52) in either case of a single-stage implantation step and a multi-stage implantation step.

The number of p-type impurity implantation stages (the number of target depth positions) in the multi-stage implantation step is appropriately adjusted in accordance with the thickness of the well region 22. The number of implantation stages may be 2 stages, 3 stages, 4 stages, 5 stages, 6 stages, 7 stages, 8 stages, 9 stages, or 10 stages. The number of implantation stages is preferably not less than 2 stages and not more than 5 stages. In the case of the multi-stage implantation step, the p-type impurity is implanted at different target depth positions such that the implantation locations of the p-type impurity overlap.

In the multi-stage implantation step, the dose amount (the impurity concentration) of the p-type impurity with respect to the second semiconductor region 7 (the base intermediate concentration region 52) may be adjusted such that the dose amount increases as the implantation location becomes deeper. Also, in the multi-stage implantation step, the implantation energy of the p-type impurity with respect to the second semiconductor region 7 (the base intermediate concentration region 52) may be adjusted such that the implantation energy increases as the implantation location becomes deeper.

The plurality of well regions 22 having the plurality of first bulging portions 22c that gradually increase and decrease in multiple stages in the thickness direction are thereby each formed in regions oriented along the bottom walls 15c of the plurality of trenches 16. Also, the base intermediate concentration region 52 is separated by the plurality of well regions 22, and a plurality of intermediate concentration regions 25 are formed.

Next, referring to FIG. 10H, the plurality of high concentration well regions 23 are formed in regions oriented along the bottom walls 15c of the plurality of trenches 16 in the plurality of well regions 22. In this step, the p-type impurity is introduced into the wafer 45 via the bottom walls 15c of the plurality of trenches 16 by the ion implantation method via the second mask 57 described above. The ion implantation method may be any one or both of a channeling ion implantation method and a random ion implantation method.

Preferably, the ion implantation method is a random ion implantation method, and the p-type impurity is introduced into the wafer 45 at an implantation angle substantially perpendicular to the first wafer main surface 46. Preferably, the ion implantation method is a vertical ion implantation method and is not an oblique ion implantation method. According to this step, introduction of the p-type impurity into the second semiconductor region 7 via the first side wall 15a and the second side wall 15b of the trench 16 is suppressed.

The plurality of high concentration well regions 23 are thereby each formed in the plurality of well regions 22. In this step, the second mask 57 related to the forming step of the well region 22 is used. As a matter of course, the plurality of high concentration well regions 23 may be formed using a mask different from the second mask 57. Thereafter, the second mask 57 is removed.

Next, referring to FIG. 10I, the plurality of first contact regions 27 and the plurality of second contact regions 28 are formed in regions oriented along the plurality of trenches 16 in the wafer 45 (the second semiconductor region 7). In this step, first, a third mask 58 having a predetermined layout is formed on the first wafer main surface 46.

The third mask 58 may be an inorganic mask (for example, a silicon oxide film) or may be an organic mask (resist mask). The third mask 58 exposes regions in which the plurality of first contact regions 27 and the plurality of second contact regions 28 are to be formed and covers regions other than these. That is, the third mask 58 selectively exposes a portion of the first wafer main surface 46 and a portion of the plurality of trenches 16.

Next, the p-type impurity is introduced into the wafer 45 via the first wafer main surface 46 and the plurality of trenches 16 by the ion implantation method via the third mask 58. The ion implantation method may be any one or both of a channeling ion implantation method and a random ion implantation method.

In this embodiment, the ion implantation method is a random ion implantation method. The random ion implantation method may be a vertical ion implantation method. In this case, the p-type impurity is introduced into the wafer 45 at an implantation angle substantially perpendicular to the first wafer main surface 46.

The random ion implantation method may be an oblique ion implantation method. In this case, the p-type impurity is introduced into the wafer 45 at an implantation angle obliquely inclined with respect to the first wafer main surface 46. The implantation angle may be greater than 0° and not more than 10°. The plurality of first contact regions 27 and the plurality of second contact regions 28 are thereby each formed in the second semiconductor region 7. Thereafter, the third mask 58 is removed.

Next, referring to FIG. 10J, a base insulating film 59 is formed on the first wafer main surface 46. The base insulating film 59 serves as a base of the plurality of insulating films 17 and the main surface insulating film 30. The base insulating film 59 is formed in a film shape along the first wafer main surface 46 and the wall surfaces of the plurality of trenches 16. The base insulating film 59 may be formed by any one or both of a CVD method and an oxidation treatment method (for example, a thermal oxidation treatment method).

Next, referring to FIG. 10K, a first base electrode film 60 is formed on the base insulating film 59. The first base electrode film 60 serves as a base of the plurality of embedded electrodes 18. The first base electrode film 60 has a portion that covers the first wafer main surface 46 with the base insulating film 59 interposed therebetween and portions that are embedded in the plurality of trenches 16 with the base insulating film 59 interposed therebetween. The base insulating film 59 may be formed by a CVD method.

Next, referring to FIG. 10L, unnecessary portions of the first base electrode film 60 are removed by an etching method until the base insulating film 59 is exposed. The etching method may be any one or both of a wet etching method and a dry etching method. The plurality of embedded electrodes 18 are thereby formed. Also, the plurality of gate structures 15 are formed.

Next, referring to FIG. 10M, the interlayer film 31 is formed on the first wafer main surface 46. The interlayer film 31 entirely covers the first surface portion 8, the second surface portion 9, the first to fourth connecting surface portions 10A to 10D, and the plurality of gate structures 15 in a film shape. The interlayer film 31 may be formed by a CVD method.

Next, referring to FIG. 10N, a fourth mask 61 having a predetermined layout is formed on the interlayer film 31. The fourth mask 61 may be an organic mask (resist mask). The fourth mask 61 exposes regions in which the plurality of source openings 32 and the plurality of gate openings 33 are to be formed and covers regions other than these.

Next, unnecessary portions of the interlayer film 31 are removed by an etching method via the fourth mask 61. The etching method may be any one or both of a wet etching method and a dry etching method.

Next, unnecessary portions of the base insulating film 59 are removed by an etching method via the fourth mask 61. The etching method may be any one or both of a wet etching method and a dry etching method.

The unnecessary portions of the base insulating film 59 may be removed simultaneously with the interlayer film 31. The plurality of source openings 32 and the plurality of gate openings 33 are thereby formed in the interlayer film 31. Also, the base insulating film 59 is divided into the insulating film 17 and the main surface insulating film 30. Thereafter, the fourth mask 61 is removed.

Next, referring to FIG. 10O, a second base electrode film 62 is formed on the interlayer film 31. The second base electrode film 62 is a base of the source electrode 35, the gate electrode 40, and the gate wiring 41. The second base electrode film 62 has a laminated structure that includes the lower electrode film 36 and the main electrode film 37. The lower electrode film 36 has the laminated structure that includes the first electrode film 38 and the second electrode film 39.

The first electrode film 38 may be formed by any one or both of a sputtering method and a vapor deposition method. The first electrode film 38 is formed in a film shape along the first wafer main surface 46, the interlayer film 31, the wall surfaces of the plurality of source openings 32, and the wall surfaces of the plurality of gate openings 33.

The second electrode film 39 may be formed by any one or both of a sputtering method and a vapor deposition method. The second electrode film 39 is laminated on the first electrode film 38 and is formed in a film shape along the first wafer main surface 46, the interlayer film 31, the wall surfaces of the plurality of source openings 32, and the wall surfaces of the plurality of gate openings 33.

The main electrode film 37 is formed on the lower electrode film 36. The main electrode film 37 may be formed by any one or both of a sputtering method and a vapor deposition method. The main electrode film 37 is laminated on the lower electrode film 36 and is formed in a film shape along the first wafer main surface 46, the interlayer film 31, the wall surfaces of the plurality of source openings 32, and the wall surfaces of the plurality of gate openings 33.

Next, the second base electrode film 62 is divided into the source electrode 35, the gate electrode 40, and the gate wiring 41. In this step, a mask (not shown) having a predetermined layout is formed on the main electrode film 37. The mask (not shown) covers regions in which the source electrode 35, the gate electrode 40, and the gate wiring 41 are to be formed and exposes regions other than these.

Next, unnecessary portions of the main electrode film 37 are removed by an etching method via the mask (not shown). The unnecessary portions of the main electrode film 37 are removed until the lower electrode film 36 is exposed. The etching method may be any one or both of a wet etching method and a dry etching method. The mask (not shown) is removed after the etching step of the main electrode film 37.

Next, unnecessary portions of the lower electrode film 36 are removed by an etching method using the main electrode film 37 as a mask. The unnecessary portions of the lower electrode film 36 are removed until the interlayer film 31 is exposed. A removing step of the lower electrode film 36 includes a step of removing the second electrode film 39 by an etching method and a step of removing a first electrode film 38 by an etching method. The etching method may be any one or both of a wet etching method and a dry etching method.

The source electrode 35, the gate electrode 40, and the gate wiring 41 are thereby formed. As a matter of course, the unnecessary portions of the lower electrode film 36 may be removed by an etching method via a mask (not shown) related to the etching step of the main electrode film 37.

Next, referring to FIG. 10P, the drain electrode 42 is formed on the second wafer main surface 47. The drain electrode 42 may be formed by any one or both of a sputtering method and a vapor deposition method. Thereafter, the wafer 45 is cut along the intended cutting line 51 (see FIG. 9), and a plurality of semiconductor devices 1A are cut out. The semiconductor device 1A is manufactured through the steps including the above.

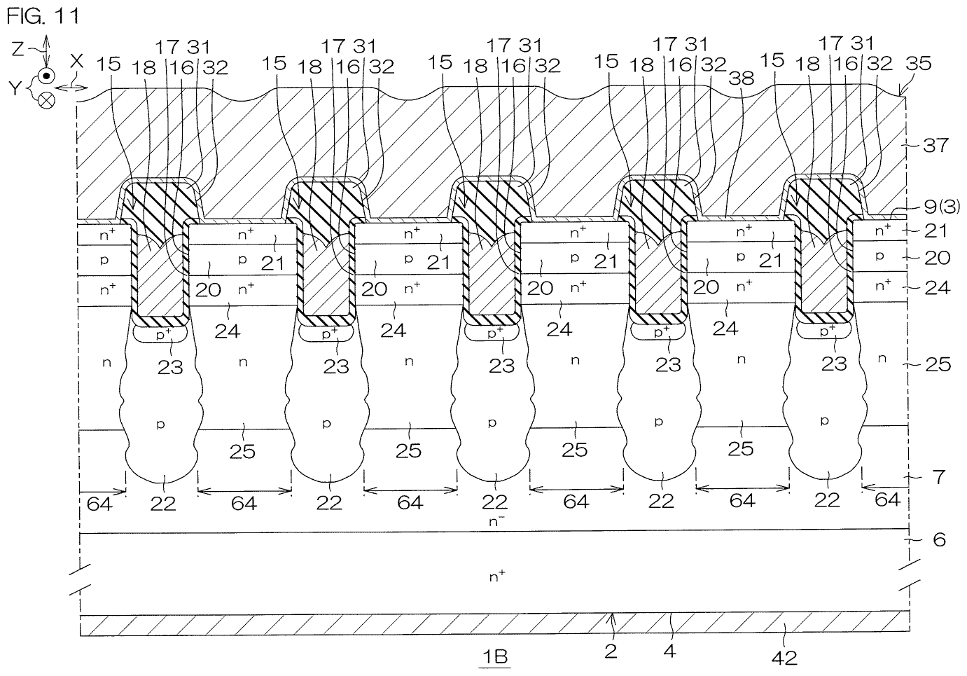

FIG. 11 is a sectional view showing one main portion of a semiconductor device 1B according to a second embodiment. Referring to FIG. 11, the semiconductor device 1B includes the plurality of well regions 22 each formed as a column region forming a super junction structure. As in the case of the semiconductor device 1A, the plurality of well regions 22 are formed in a columnar shape extending in the thickness direction in sectional view.

The semiconductor device 1B includes a plurality of intermediate drift regions 64 of the n-type that are formed in the chip 2 (the second semiconductor region 7). Each of the plurality of intermediate drift regions 64 includes a region demarcated between the plurality of well regions 22 in the second semiconductor region 7. That is, in this embodiment, each of the plurality of intermediate drift regions 64 includes a portion of the second semiconductor region 7, the high concentration region 24, and the intermediate concentration region 25.

The plurality of intermediate drift regions 64 are alternately aligned with the plurality of well regions 22 in the first direction X and each formed in a band shape extending in the second direction Y. That is, the plurality of intermediate drift regions 64 are formed in a stripe shape extending in the second direction Y along the plurality of well regions 22. Also, an extension direction of the plurality of intermediate drift regions 64 coincides with the off direction of the SiC monocrystal. The plurality of intermediate drift regions 64 are formed in a columnar shape extending in the thickness direction in sectional view and face the plurality of body regions 20 in a one-to-one correspondence.

The plurality of intermediate drift regions 64 form a plurality of pn junction portions having a charge balance together with the plurality of well regions 22 in a thickness range below the plurality of gate structures 15. A state of having the charge balance means a state where, for the plurality of well regions 22 that are mutually adjacent, depletion layers spreading from the pn junction portions at one side and depletion layers spreading from the pn junction portions at another side are connected inside the plurality of intermediate drift regions 64.

As described above, the semiconductor device 1B includes the intermediate drift regions 64 of the n-type that are demarcated between the plurality of well regions 22 in the chip 2 (the second semiconductor region 7). The intermediate drift regions 64 are demarcated into regions between the plurality of well regions 22 in the second semiconductor region 7.

The intermediate drift regions 64 form a super junction structure with the plurality of well regions 22. With this configuration, the semiconductor device 1B of a super junction type is provided. When the chip 2 contains SiC, the SiC semiconductor device of the super junction type is provided.

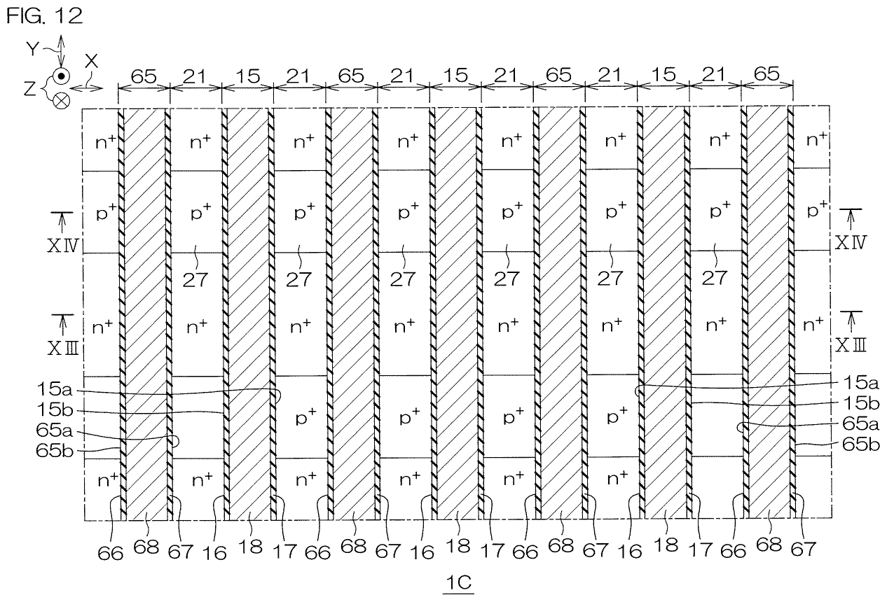

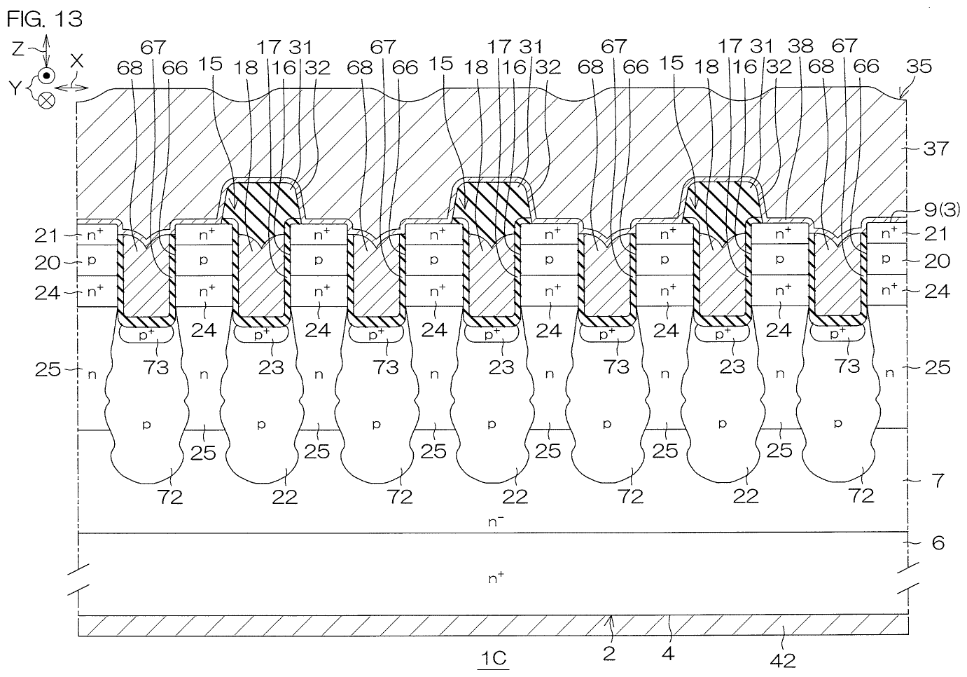

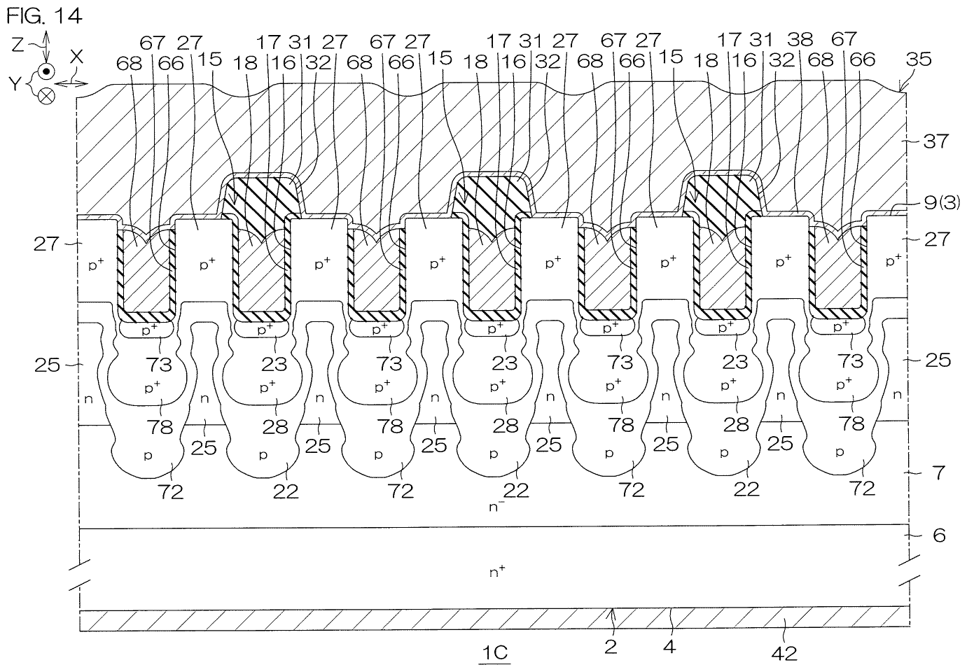

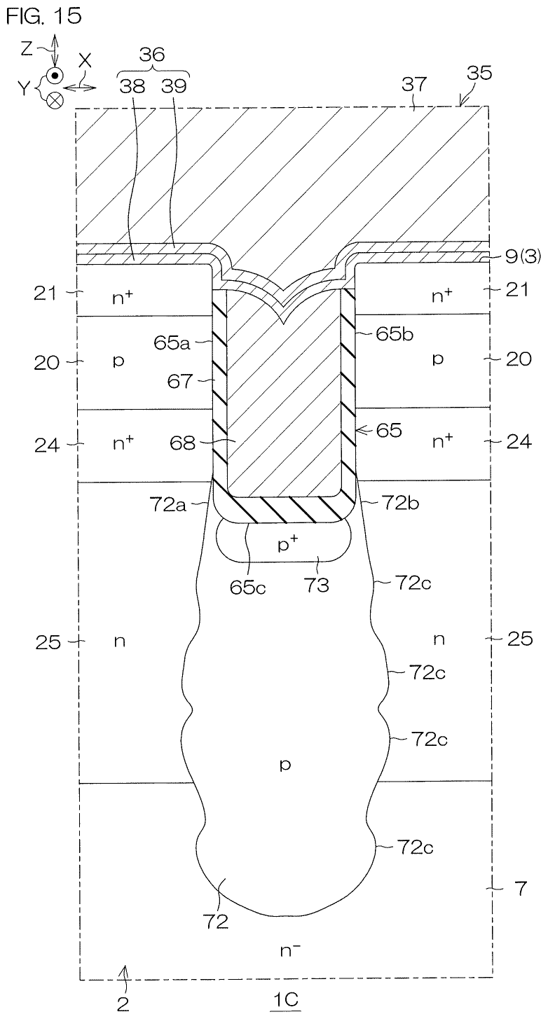

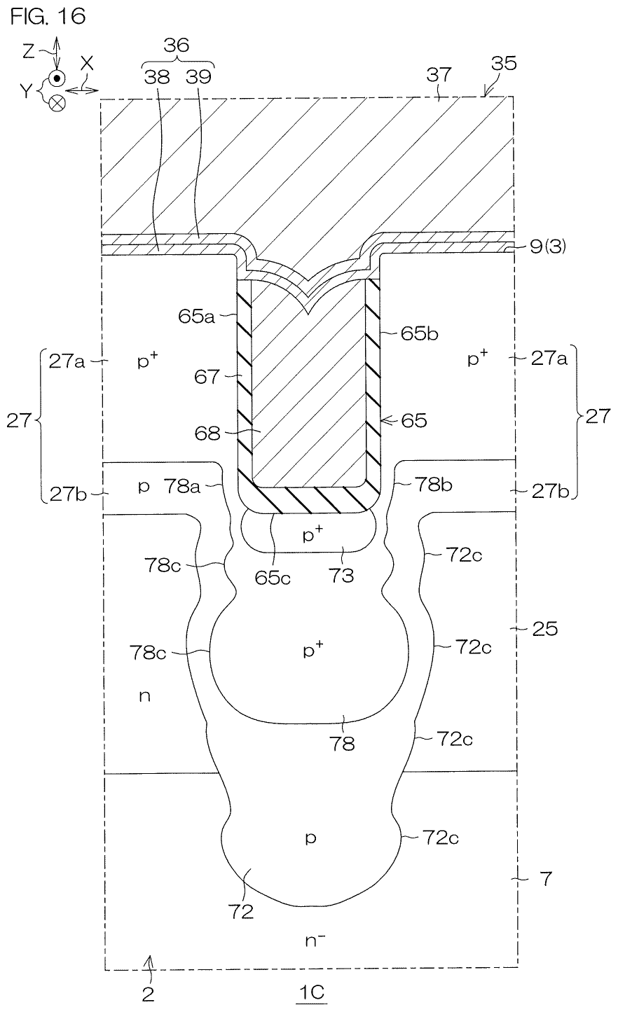

FIG. 12 is a plan view showing one main portion of a semiconductor device 1C according to a third embodiment. FIG. 13 is a sectional view taken along line XIII-XIII shown in FIG. 12. FIG. 14 is a sectional view taken along line XIV-XIV shown in FIG. 12. FIG. 15 is an enlarged sectional view of a region including a source structure 65 shown in FIG. 13. FIG. 16 is an enlarged sectional view of a region including the source structure 65 shown in FIG. 14.

The configuration of the semiconductor device 1C is different from that of the semiconductor device 1A in that the semiconductor device 1C includes a plurality of source structures 65 of a trench type (a trench electrode type) that are formed in the first main surface 3 (the first surface portion 8). The source structures 65 may be referred to as “trench source structures,” “second trench structures,” etc. The source potential is to be applied to the plurality of source structures 65.

In the semiconductor device 1C, since the layout of other constituent elements with respect to the gate structure 15 is the same as in the case of the semiconductor device 1A, embodiments of other constituent elements with respect to the source structure 65 shall be mainly described below. Description of other constituent elements with respect to the gate structure 15 shall be omitted unless otherwise specified. For the omitted description, the description given in the semiconductor device 1A shall apply.

Referring to FIGS. 12 to 16, the plurality of source structures 65 are formed such as to be adjacent to the plurality of gate structures 15 in the first direction X. Specifically, the plurality of source structures 65 are each arranged in regions between the plurality of adjacent gate structures 15 and face the plurality of gate structures 15 in the first direction X. The plurality of source structures 65 are alternately aligned with the plurality of gate structures 15 in the first direction X.

The plurality of source structures 65 may be formed in the first surface portion 8 at intervals inward from the peripheral edge of the first surface portion 8 (from the first to fourth connecting surface portions 10A to 10D). The plurality of source structures 65 may pass through the peripheral edge of the first surface portion 8 and be exposed from the first to fourth connecting surface portions 10A to 10D.

The plurality of source structures 65 are formed at intervals to the first main surface 3 side from the bottom portion of the second semiconductor region 7 and face the first semiconductor region 6 with a portion of the second semiconductor region 7 interposed therebetween. The plurality of source structures 65 are formed substantially perpendicular to the first main surface 3 (the first surface portion 8).

The plurality of source structures 65 each have a first side wall 65a on one side (the third side surface 5C side) in the first direction X, a second side wall 65b on the other side (the fourth side surface 5D side) in the first direction X, and a bottom wall 65c connecting the first side wall 65a and the second side wall 65b in sectional view.

The first side wall 65a and the second side wall 65b are each formed by an a-plane (a (11-20) plane) of the SiC monocrystal. As a matter of course, the first side wall 65a and the second side wall 65b may each be formed by an m-plane (a (1-100) plane) of the SiC monocrystal in accordance with an extension direction of the source structures 65. The first side wall 65a and the second side wall 65b are formed substantially perpendicular to the first main surface 3.

An inclination angle (absolute value) of the first side wall 65a (the second side wall 65b) on a basis of a vertical line may be not less than 85° and not more than 95°. The inclination angle of the first side wall 65a (the second side wall 65b) may have a value belonging to at least one range among not less than 85° and not more than 87.5°, not less than 87.5° and not more than 90°, not less than 90° and not more than 92.5°, and not less than 92.5° and not more than 95°. The inclination angle of the first side wall 65a (the second side wall 65b) is preferably not less than 87° and not more than 93°.

The bottom wall 65c is formed by a c-plane (an Si plane) of the SiC monocrystal. The bottom wall 65c preferably extends substantially flat in the horizontal directions. As a matter of course, the bottom wall 65c may be curved in a circular arc shape toward the second main surface 4 side.

A width of the source structure 65 may be substantially equal to the width of the gate structure 15. The width of the source structure 65 may be greater than the width of the gate structure 15 or may be less than the width of the gate structure 15. The source structure 65 may have a width of not less than 0.1 μm and not more than 1.5 μm.

The width of the source structure 65 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, and not less than 1.25 μm and not more than 1.5 μm. The width of the source structure 65 is preferably not less than 0.25 μm and not more than 0.75 μm.

The depth of the source structure 65 may be substantially equal to the depth of the second surface portion 9. The depth of the source structure 65 may be greater than the depth of the second surface portion 9 or may be less than the depth of the second surface portion 9. The depth of the source structure 65 may be substantially equal to the depth of the gate structure 15. The depth of the source structure 65 may be greater than the depth of the gate structure 15 or may be less than the depth of the gate structure 15.

The depth of the source structure 65 may be not less than 0.1 μm and not more than 3 μm. The depth of the source structure 65 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the source structure 65 is preferably not less than 0.5 μm and not more than 1.5 μm.

The plurality of source structure 65 each include a second trench 66, a second insulating film 67, and a second embedded electrode 68. The second trench 66 is formed in the first main surface 3 and demarcates wall surfaces (the first side wall 65a, the second side wall 65b, and the bottom wall 65c) of the source structure 65.

The second insulating film 67 may include at least one among a silicon oxide film, a silicon nitride film, and a silicon oxynitride film. The second insulating film 67 preferably includes the same type of insulating material as that of the insulating film 17. In this embodiment, the second insulating film 67 has a single layer structure constituted of a silicon oxide film. The second insulating film 67 particularly preferably includes a silicon oxide film constituted of the oxide of the chip 2.

The second insulating film 67 covers a wall surface of the second trench 66 in a film shape. The second insulating film 67 covers the first side wall 65a and the second side wall 65b at an interval to the bottom wall 65c side from the first main surface 3. That is, the second insulating film 67 exposes a portion of the first side wall 65a and a portion of the second side wall 65b from an opening end of the second trench 66.

The second insulating film 67 includes a first film portion, a second film portion, and a third film portion. The first film portion covers the first side wall 65a of the second trench 66 in a film shape. The second film portion covers the second side wall 65b of the second trench 66 in a film shape. The third film portion covers the bottom wall 65c of the second trench 66 in a film shape and is continuous with the first film portion and the second film portion.

The second film portion has a thickness substantially equal to the thickness of the first film portion. The third film portion has a thickness greater than the thickness of the first film portion and the thickness of the second film portion. The thickness of the third film portion may be substantially equal to the thickness of the first film portion and the thickness of the second film portion.

The first film portion of the second insulating film 67 may have a thickness substantially equal to the thickness of the first film portion of the insulating film 17. The second film portion of the second insulating film 67 may have a thickness substantially equal to the thickness of the second film portion of the insulating film 17. The third film portion of the second insulating film 67 may have a thickness substantially equal to the thickness of the third film portion of the insulating film 17.

The second insulating film 67 may have a thickness of not less than 10 nm and not more than 150 nm. The thickness of the second insulating film 67 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The second embedded electrode 68 may contain any one or both of a conductive polysilicon of the p-type and a conductive polysilicon of the n-type. The second embedded electrode 68 is embedded in the second trench 66 with the second insulating film 67 interposed therebetween. The second embedded electrode 68 has an electrode surface exposed from the second trench 66.

The electrode surface of the second embedded electrode 68 is positioned at the bottom wall 65c side of the second trench 66 with respect to the height position of the first main surface 3. The electrode surface of the second embedded electrode 68 may be positioned further to the bottom wall 65c side than the electrode surface of the embedded electrode 18 in height position.

As a matter of course, the height position of the electrode surface of the second embedded electrode 68 may be substantially equal to the height position of the electrode surface of the embedded electrode 18. The electrode surface of the second embedded electrode 68 has, in an inner portion, a recess that is recessed in a shape tapering toward the bottom wall 65c side. The bottom portion of the recess is preferably positioned at the first main surface 3 side with respect to a depth position of an intermediate portion of the second trench 66.

As in the case of the semiconductor device 1A, the semiconductor device 1C includes the plurality of body regions 20 formed in regions oriented along the plurality of gate structures 15 in the surface layer portion of the first main surface 3 (the first surface portion 8). In this embodiment, the plurality of body regions 20 are each formed in regions between the plurality of gate structures 15 and the plurality of source structures 65 and each extend in a band shape along the plurality of gate structures 15 and the plurality of source structures 65.

Hereinafter, the configuration of the single body region 20 shall be described. In this embodiment, the body region 20 is formed in a layered shape extending in the first direction X in sectional view and is connected to the gate structure 15 and the source structure 65. The body region 20 faces the second embedded electrode 68 with the second insulating film 67 interposed therebetween at the source structure 65 side.

The body region 20 is formed in a region at the first main surface 3 side with respect to a depth position of the bottom wall 65c of the source structure 65. The body region 20 has a bottom portion positioned at the bottom wall 65c side of the source structure 65 with respect to a depth position of an intermediate portion of the source structure 65.

That is, the bottom portion of the body region 20 is positioned in a region between the bottom wall 65c of the source structure 65 and the intermediate portion of the source structure 65. In other words, a distance between the bottom portion of the body region 20 and the bottom wall 65c of the source structure 65 is less than the thickness (depth) of the body region 20. The bottom portion of the body region 20 is positioned at the bottom wall 65c side with respect to the bottom portion of the recess of the second embedded electrode 68.

As in the case of the semiconductor device 1A, the semiconductor device 1C includes the plurality of source regions 21 formed in a region at the first main surface 3 side with respect to the plurality of the body regions 20. In this embodiment, the plurality of source regions 21 are each formed in regions between the plurality of gate structures 15 and the plurality of source structures 65 and each extend in a band shape along the plurality of gate structures 15 and the plurality of source structures 65.

Hereinafter, the configuration of the single source region 21 shall be described. The source region 21 is formed at an interval to the first main surface 3 side from the bottom portion of the body region 20. In this embodiment, the source region 21 is formed in a layered shape extending in the first direction X in sectional view and is connected to the gate structure 15 and the source structure 65. Each of the plurality of source regions 21 faces the second embedded electrode 68 with the second insulating film 67 interposed therebetween at the source structure 65 side.

The source region 21 has a bottom portion positioned at the bottom wall 65c side of the second trench 66 with respect to a height position of the electrode surface of the second embedded electrode 68 and a surface layer portion positioned at the first main surface 3 side with respect to the height position of the electrode surface of the second embedded electrode 68. That is, the source region 21 has a portion (the bottom portion) facing the second embedded electrode 68 with the second insulating film 67 interposed therebetween and a portion (the surface layer portion) not facing the second embedded electrode 68 with the second insulating film 67 interposed therebetween.

The bottom portion of the source region 21 is preferably positioned at the bottom portion side of the body region 20 with respect to the depth position of the bottom portion of the recess of the second embedded electrode 68. As a matter of course, the bottom portion of the source region 21 may be positioned at the first main surface 3 side with respect to the depth position of the bottom portion of the recess. The surface layer portion of the source region 21 is exposed from an upper end portion of the first side wall 65a or an upper end portion of the second side wall 65b of the source structure 65.

As in the case of the semiconductor device 1A, the semiconductor device 1C includes the plurality of well regions 22 formed in the chip 2 (the second semiconductor region 7). The description regarding the plurality of well regions 22 is the same as in the case of the semiconductor device 1A and shall thus be omitted.

The semiconductor device 1C includes a plurality of second well regions 72 of the p-type that are each formed in regions oriented along the bottom walls 65c of the plurality of source structures 65 in the chip 2 (the second semiconductor region 7). The plurality of second well regions 72 are formed in the same manner as the plurality of well regions 22 and have the p-type impurity concentration substantially equal to the p-type impurity concentration of the plurality of well regions 22.

The plurality of second well regions 72 are each formed in regions oriented along the bottom walls 65c of the plurality of source structures 65 at intervals in the first direction X from the plurality of well regions 22. The plurality of second well regions 72 are each formed in a one-to-one correspondence with respect to the plurality of source structures 65.

Each of the plurality of second well regions 72 is formed in a band shape extending along the plurality of source structures 65 in plan view and faces the corresponding second embedded electrode 68 with the corresponding second insulating film 67 interposed therebetween. As a matter of course, the plurality of second well regions 72 may be formed in a multiple-to-one correspondence with respect to the single source structure 65. In this case, the plurality of second well regions 72 are formed at intervals in the second direction Y.

Hereinafter, the configuration of the single second well region 72 shall be described. The second well region 72 is formed to be wider than the source structure 65 in plan view. The second well region 72 is formed in a columnar shape extending in the thickness direction (the vertical direction Z) of the second semiconductor region 7 in sectional view.

The second well region 72 is formed at an interval to the first surface portion 8 side from the bottom portion of the second semiconductor region 7 and faces the first semiconductor region 6 with a portion of the second semiconductor region 7 interposed therebetween. As a matter of course, the second well region 72 may be formed such as to cross the bottom portion of the second semiconductor region 7 and have a bottom portion positioned in the first semiconductor region 6. The second well region 72 forms a pn junction portion with the second semiconductor region 7.

In this embodiment, the second well region 72 has a thickness (depth) greater than the thickness (depth) of the body region 20. The thickness of the second well region 72 is the thickness of the second well region 72 in the vertical direction Z with reference to the bottom wall 65c of the source structure 65. In this embodiment, the thickness of the second well region 72 is greater than the depth of the source structure 65.

As a matter of course, the thickness of the second well region 72 may be less than the depth of the source structure 65. In this case, the thickness of the second well region 72 may be less than the thickness of the body region 20. The thickness of the second well region 72 is preferably substantially equal to the thickness of the well region 22. As a matter of course, the thickness of the second well region 72 may be greater than the thickness of the well region 22 or may be less than the thickness of the well region 22.

The second well region 72 has an upper end portion oriented along a corner portion of the bottom wall 65c of the source structure 65. The second well region 72 has a first extension portion 72a on the first side wall 65a side and a second extension portion 72b on the second side wall 65b side at the upper end portion (see FIG. 15).

The first extension portion 72a is led out from a region directly below the source structure 65 to the lower end portion of the first side wall 65a. The first extension portion 72a is formed at an interval to the bottom wall 65c side of the source structure 65 from the bottom portion of the body region 20. In this embodiment, the first extension portion 72a faces the second embedded electrode 68 with the second insulating film 67 interposed therebetween in the horizontal direction.

As a matter of course, the first extension portion 72a may be formed at the bottom wall 65c side of the second trench 66 with respect to the depth position of the lower end portion of the second embedded electrode 68 and face just the second insulating film 67 (the third film portion) in the horizontal direction. The first extension portion 72a is formed in a tapered shape toward the first main surface 3 (the bottom portion side of the body region 20) in sectional view.

The second extension portion 72b is led out from a region directly below the source structure 65 to the lower end portion of the second side wall 65b and faces the first extension portion 72a with the source structure 65 interposed therebetween. The second extension portion 72b is formed at an interval to the bottom wall 65c side of the source structure 65 from the bottom portion of the body region 20. In this embodiment, the second extension portion 72b faces the second embedded electrode 68 with the second insulating film 67 interposed therebetween in the horizontal direction.

As a matter of course, the second extension portion 72b may be formed at the bottom wall 65c side of the second trench 66 with respect to the depth position of the lower end portion of the second embedded electrode 68 and face just the second insulating film 67 (the third film portion) in the horizontal direction. The second extension portion 72b is formed in a tapered shape toward the first main surface 3 (the bottom portion side of the body region 20) in sectional view.

The second well region 72 has one or a plurality (in this embodiment, a plurality of) third bulging portions 72c. In the attached drawings, the second well region 72 having four third bulging portions 72c is illustrated. Each of the plurality of third bulging portions 72c is formed by a portion where a width of the second well region 72 in the horizontal direction (the first direction X) gradually increases or decreases in the thickness direction and is formed in multiple stages from the bottom wall 65c of the source structure 65 toward the bottom portion of the second semiconductor region 7.

The plurality of third bulging portions 72c protrude in an arc shape (circular arc shape) from a region directly below the source structure 65 to both sides of the source structure 65. When the second well region 72 has the single third bulging portion 72c, the single third bulging portion 72c may be formed such as to protrude in an arc shape (circular arc shape) to both sides of the source structure 65 at the intermediate portion of the second well region 72.

As in the case of the semiconductor device 1A, the semiconductor device 1C includes the plurality of high concentration well regions 23 each formed in the plurality of well regions 22. The description regarding the plurality of high concentration well regions 23 is the same as in the case of the semiconductor device 1A and shall thus be omitted.

The semiconductor device 1C includes a plurality of second high concentration well regions 73 of the p-type that are each formed in the plurality of second well regions 72. The plurality of second high concentration well regions 73 are formed in the same manner as the plurality of high concentration well regions 23 and have the p-type impurity concentration substantially equal to the p-type impurity concentration of the plurality of high concentration well regions 23.

The plurality of second high concentration well regions 73 are each formed in a one-to-one correspondence with respect to the corresponding second well regions 72. Each of the plurality of second high concentration well regions 73 is formed in a region oriented along the bottom wall 65c of the corresponding source structure 65. Each of the plurality of second high concentration well regions 73 is formed in a band shape extending along the corresponding source structures 65 (the second well regions 72) in plan view and faces the corresponding second embedded electrode 68 with the corresponding second insulating film 67 interposed therebetween.

As a matter of course, the plurality of second high concentration well regions 73 may be formed in a multiple-to-one correspondence with respect to the single second well region 72. In this case, the plurality of second high concentration well regions 73 are formed at intervals in the second direction Y in the single second well region 72.

Hereinafter, the configuration of the single second high concentration well region 73 shall be described. The second high concentration well region 73 is formed at an interval to the bottom wall 65c side of the source structure 65 from the bottom portion of the second well region 72. The second high concentration well region 73 preferably has a bottom portion positioned at the bottom wall 65c side of the source structure 65 with respect to a depth position of the intermediate portion of the second well region 72.

The bottom portion of the second high concentration well region 73 is defined by a concentration transition portion where the p-type impurity concentration gradually decreases toward the bottom portion side of the second well region 72. As a matter of course, the bottom portion of the second high concentration well region 73 may be positioned at the bottom portion side of the second well region 72 with respect to the depth position of the intermediate portion of the second well region 72. In this embodiment, the bottom portion of the second high concentration well region 73 is formed at a depth position substantially equal to the depth position of the bottom portion of the high concentration well region 23.

The second high concentration well region 73 is formed to be narrower than the second well region 72. In this embodiment, the second high concentration well region 73 is formed to be narrower than the source structure 65. As a matter of course, the second high concentration well region 73 may be formed to be wider than the source structure 65 and protrude to both sides of the source structure 65.

In this embodiment, a width of the second high concentration well region 73 is substantially equal to the width of the high concentration well region 23. As a matter of course, the width of the second high concentration well region 73 may be greater than the width of the high concentration well region 23 or may be smaller than the width of the high concentration well region 23.

The second high concentration well region 73 has a thickness (depth) less than the depth of the source structure 65. The thickness of the second high concentration well region 73 is the thickness of the second high concentration well region 73 in the vertical direction Z with reference to the bottom wall 65c of the source structure 65. The thickness of the second high concentration well region 73 is less than the thickness of the body region 20. As a matter of course, the thickness of the second high concentration well region 73 may be greater than the thickness of the body region 20 or may be greater than the depth of the source structure 65.

The thickness of the second high concentration well region 73 is preferably substantially equal to the thickness of the high concentration well region 23. As a matter of course, the thickness of the second well region 72 may be greater than the thickness of the high concentration well region 23 or may be less than the thickness of the high concentration well region 23.

As in the case of the semiconductor device 1A, the semiconductor device 1C includes the plurality of high concentration regions 24 each formed in regions below the plurality of body regions 20 in the chip 2 (the second semiconductor region 7). In this embodiment, the plurality of high concentration regions 24 are each formed in regions between the plurality of gate structures 15 and the plurality of source structures 65.

The plurality of high concentration regions 24 are each formed in a thickness range between the bottom walls 65c of the plurality of source structures 65 and the bottom portions of the plurality of body regions 20 for the plurality of source structures 65. The plurality of high concentration regions 24 each extend in a band shape along the plurality of gate structures 15 and the plurality of source structures 65 in plan view.

Hereinafter, the configuration of the single high concentration region 24 shall be described. In this embodiment, the high concentration region 24 is formed in a layered shape extending in the first direction X in sectional view and is connected to both the gate structure 15 and the source structure 65. The high concentration region 24 faces the second embedded electrode 68 with the second insulating film 67 interposed therebetween at the source structure 65 side.

The high concentration region 24 has a bottom portion positioned at the first main surface 3 side with respect to the depth position of the bottom wall 65c of the source structure 65. That is, the high concentration region 24 is formed at an interval to the first main surface 3 side from the depth position of the bottom wall 65c of the source structure 65.

The high concentration region 24 is formed in a thickness range between the body region 20 and the second well region 72 and separates the second well region 72 from the body region 20. That is, the high concentration region 24 suppresses an increase in p-type impurity concentration in a portion oriented along the side wall (the first side wall 65a or the second side wall 65b) of the source structure 65. As a matter of course, the bottom portion of the high concentration region 24 may be positioned at the bottom portion side of the second semiconductor region 7 with respect to the bottom wall 65c of the source structure 65.

As in the case of the semiconductor device 1A, the semiconductor device 1C includes the plurality of intermediate concentration regions 25 of the n-type that are each formed in regions below the plurality of high concentration regions 24 in the chip 2 (the second semiconductor region 7). In this embodiment, the plurality of intermediate concentration regions 25 are each formed in regions between the plurality of gate structures 15 and the plurality of source structures 65.

The plurality of intermediate concentration regions 25 are each formed in a thickness range between the bottom portion of the second semiconductor region 7 and the bottom portions of the plurality of high concentration regions 24. Each of the plurality of intermediate concentration regions 25 has a portion interposed in one of the regions between the plurality of well regions 22 and the plurality of second well regions 72. In this embodiment, each of the plurality of intermediate concentration regions 25 has a portion interposed in one of the regions between the plurality of gate structures 15 and the plurality of source structures 65.

The plurality of intermediate concentration regions 25 each extend in a band shape along the plurality of gate structures 15 and the plurality of source structures 65 in plan view. The plurality of intermediate concentration regions 25 are connected to any one or both (both in this embodiment) of the adjacent well region 22 and second well region 72.

Hereinafter, the configuration of the single intermediate concentration region 25 shall be described. The intermediate concentration region 25 is formed at an interval to the first main surface 3 side from the bottom portion of the second semiconductor region 7 and faces the first semiconductor region 6 with a portion of the second semiconductor region 7 interposed therebetween.

The intermediate concentration region 25 has an upper end portion positioned on an upper side with respect to the depth position of the bottom wall 65c of the source structure 65. The upper end portion of the intermediate concentration region 25 is positioned in a region between the gate structure 15 and the source structure 65. The upper end portion of the intermediate concentration region 25 faces the source structure 65 with the upper end portion (the first extension portion 72a or the second extension portion 72b) of the second well region 72 interposed therebetween. The upper end portion of the intermediate concentration region 25 may have a portion connected to the source structure 65.

The intermediate concentration region 25 has a bottom portion positioned on a lower side with respect to the depth position of the bottom wall 65c of the source structure 65. Specifically, the bottom portion of the intermediate concentration region 25 is formed at an interval to the first main surface 3 side from the bottom portion of the second well region 72. The bottom portion of the intermediate concentration region 25 is preferably positioned further to the bottom portion side of the second well region 72 than the bottom portion of the second high concentration well region 73.

The bottom portion of the intermediate concentration region 25 may be positioned further to the bottom portion side of the second semiconductor region 7 than the intermediate portion of the second well region 72. As a matter of course, the bottom portion of the intermediate concentration region 25 may be positioned further to the bottom wall 65c side of the source structure 65 than the intermediate portion of the second well region 72.

As in the case of the semiconductor device 1A, the semiconductor device 1C includes the plurality of channel regions 26 formed between the plurality of source regions 21 and the plurality of high concentration regions 24 in the body regions 20. The description regarding the plurality of channel regions 26 is the same as in the case of the semiconductor device 1A and shall thus be omitted.

As in the case of the semiconductor device 1A, the semiconductor device 1C includes the plurality of first contact regions 27 each formed in regions oriented along the plurality of gate structures 15 in the surface layer portion of the first main surface 3. In this embodiment, the plurality of first contact regions 27 are each formed in the body regions 20 in regions between the plurality of gate structures 15 and the plurality of source structures 65.

That is, the plurality of first contact regions 27 are each formed at both sides of the plurality of gate structures 15 and both sides of the plurality of source structures 65. The plurality of first contact regions 27 are aligned at intervals in the second direction Y along the plurality of gate structures 15 and the plurality of source structures 65 and are each formed in a band shape extending in the second direction Y. The plurality of first contact regions 27 are formed such as to overlap the body regions 20 and increase the p-type impurity concentration of the body regions 20.

In regard to the one and the other first contact regions 27 positioned on both sides of the single source structure 65 (the gate structure 15), the other first contact region 27 faces the one first contact region 27 with the source structure 65 (the gate structure 15) interposed therebetween. That is, the plurality of first contact regions 27 are aligned, as a whole, in a matrix in plan view.

Hereinafter, the configuration of the single first contact region 27 shall be described. In this embodiment, the first contact region 27 is formed in a layered shape extending in the horizontal directions along the first main surface 3 and is connected to any one or both (in this embodiment, both) of the gate structure 15 and the source structure 65. The first contact region 27 faces the second embedded electrode 68 of the source structure 65 with the second insulating film 67 of the source structure 65 interposed therebetween.

The bottom portion of the first contact region 27 is positioned at the bottom portion side of the body region 20 with respect to the depth position of the bottom portion of the recess of the second embedded electrode 68. In this embodiment, the bottom portion of the first contact region 27 is positioned further to the bottom portion side of the second semiconductor region 7 than the depth position of the bottom wall 65c of the source structure 65. As a matter of course, the bottom portion of the first contact region 27 may be positioned further to the first main surface 3 side than the depth position of the bottom wall 65c of the source structure 65.

As in the case of the semiconductor device 1A, the first contact region 27 overlaps a portion or an entirety (in this embodiment, an entirety) of the high concentration region 24 in sectional view. Also, the first contact region 27 has a bottom portion positioned in the intermediate concentration region 25 across the bottom portion of the high concentration region 24. Also, the bottom portion of the first contact region 27 overlaps the upper end portion (the first extension portion 72a and the second extension portion 72b) of the well region 22.

As in the case of the semiconductor device 1A, the first contact region 27 has the high concentration portion 27a and the low concentration portion 27b. The high concentration portion 27a is formed at least further to the first main surface 3 side than the depth position of the bottom wall 65c of the source structure 65 and extends in a layer shape in the horizontal directions along the first main surface 3. The high concentration portion 27a is connected to the gate structure 15 and the source structure 65.

The low concentration portion 27b crosses the depth position of the bottom wall 65c of the source structure 65 in the thickness direction. That is, the low concentration portion 27b has a portion positioned further to the first main surface 3 side than the depth position of the bottom wall 65c of the source structure 65 and a portion positioned further to the bottom portion side of the second semiconductor region 7 than the depth position of the bottom wall 65c of the source structure 65. The low concentration portion 27b overlaps the upper end portions of the plurality of second well regions 72 and is electrically connected to the plurality of second well regions 72.

As a matter of course, the low concentration portion 27b may be positioned just at a position further to the first main surface 3 side with respect to the depth position of the bottom wall 65c of the source structure 65 in accordance with the thickness of the high concentration portion 27a. The low concentration portion 27b may be positioned just at a position further to the bottom portion side of the second semiconductor region 7 with respect to the depth position of the bottom wall 65c of the source structure 65 in accordance with the thickness of the high concentration portion 27a.

As in the case of the semiconductor device 1A, the semiconductor device 1C includes the plurality of second contact regions 28 each formed in regions oriented along the bottom walls 15c of the plurality of gate structures 15 in the chip 2. The description regarding the plurality of second contact regions 28 is the same as in the case of the semiconductor device 1A and shall thus be omitted.

The semiconductor device 1C includes a plurality of third contact regions 78 each formed in regions oriented along the bottom walls 65c of the plurality of source structures 65 in the chip 2. The plurality of third contact regions 78 are formed in the same manner as the plurality of second contact regions 28 and have the p-type impurity concentration substantially equal to the p-type impurity concentration of the plurality of second contact regions 28.

The plurality of third contact regions 78 are each formed in a multiple-to-one correspondence with respect to the bottom wall 65c of the plurality of source structures 65. The plurality of third contact regions 78 are each interposed in regions between the plurality of first contact regions 27 adjacent in the first direction X in plan view. That is, the plurality of third contact regions 78 are positioned on the same straight line as the plurality of first contact regions 27 in the first direction X.

The plurality of third contact regions 78 are each formed at intervals in the first direction X from the plurality of well regions 22 (the second contact regions 28) in regions between the plurality of well regions 22 (the second contact regions 28). Each of the plurality of third contact regions 78 is formed in a band shape extending along the bottom wall 65c of the corresponding source structure 65 in plan view and faces the second embedded electrode 68 with the second insulating film 67 interposed therebetween.

In the second direction Y, the lengths of the plurality of third contact regions 78 are substantially equal to the lengths of the plurality of first contact regions 27. The lengths of the plurality of third contact regions 78 are substantially equal to the lengths of the plurality of second contact regions 28. In the second direction Y, the interval between the plurality of third contact regions 78 is substantially equal to the interval between the plurality of first contact regions 27. The interval between the plurality of third contact regions 78 is substantially equal to the interval between the plurality of second contact regions 28.

Hereinafter, the configuration of the single third contact region 78 shall be described. The third contact region 78 is formed in the single corresponding second well region 72. The third contact region 78 overlaps the second high concentration well region 73 and is electrically connected to the second high concentration well region 73 in the second well region 72. The third contact region 78 is formed at an interval inward from a peripheral edge portion of the second well region 72.

The third contact region 78 is formed at an interval to the bottom wall 65c side of the source structure 65 from the bottom portion of the second well region 72 and faces the bottom portion of the second semiconductor region 7 with a portion of the second well region 72 interposed therebetween. The third contact region 78 is formed in a columnar shape extending in the thickness direction (the vertical direction Z) of the second semiconductor region 7 in sectional view.

In this embodiment, the third contact region 78 has a bottom portion positioned further to the bottom portion side of the second well region 72 than a thickness position of the intermediate portion of the second well region 72. As a matter of course, the bottom portion of the third contact region 78 may be positioned further to the bottom wall 65c side of the source structure 65 than the thickness position of the intermediate portion of the second well region 72.

In this embodiment, the bottom portion of the third contact region 78 is positioned further to the bottom wall 65c side of the source structure 65 than the bottom portion of the intermediate concentration region 25. As a matter of course, the bottom portion of the third contact region 78 may be positioned further to the bottom portion side of the second semiconductor region 7 than the bottom portion of the intermediate concentration region 25. In this case, the third contact region 78 may be formed such as to cross the bottom portion of the second well region 72 and have a bottom portion positioned in the second semiconductor region 7.

The thickness of the third contact region 78 is preferably substantially equal to the thickness of the second contact region 28. As a matter of course, the thickness of the third contact region 78 may be greater than the thickness of the second contact region 28 or may be less than the thickness of the second contact region 28.

The third contact region 78 has an upper end portion oriented along a corner portion of the bottom wall 65c of the source structure 65. The third contact region 78 is electrically connected to the plurality of first contact regions 27 at the upper end portion. That is, the third contact region 78 electrically connects the second well region 72 and the second high concentration well region 73 to the body region 20 via the plurality of first contact regions 27.

The third contact region 78 has a first extension portion 78a on the first side wall 65a side and a second extension portion 78b on the second side wall 65b side. The first extension portion 78a is led out from a region directly below the source structure 65 to the lower end portion of the first side wall 65a.

The first extension portion 78a faces the second embedded electrode 68 with the second insulating film 67 interposed therebetween in the horizontal direction. The first extension portion 78a is connected to the first contact region 27 in a region oriented along the first side wall 65a. Specifically, the first extension portion 78a is connected to both the high concentration portion 27a and the low concentration portion 27b of the first contact region 27.

The second extension portion 78b is led out from a region directly below the source structure 65 to the lower end portion of the second side wall 65b and faces the first extension portion 78a with the source structure 65 interposed therebetween. The second extension portion 78b faces the second embedded electrode 68 with the second insulating film 67 interposed therebetween in the horizontal direction. The second extension portion 78b is connected to the first contact region 27 in a region oriented along the second side wall 65b. Specifically, the second extension portion 78b is connected to both the high concentration portion 27a and the low concentration portion 27b of the first contact region 27.

The third contact region 78 has one or a plurality (in this embodiment, a plurality of) fourth bulging portions 78c. In the attached drawings, the third contact region 78 having two fourth bulging portions 78c is illustrated. The number of the fourth bulging portions 78c is appropriately adjusted by adjusting process conditions.

Each of the plurality of fourth bulging portions 78c is formed by a portion where a width of the third contact region 78 in the horizontal direction (the first direction X) gradually increases or decreases in the thickness direction and is formed in multiple stages from the bottom wall 65c of the source structure 65 toward the bottom portion of the second semiconductor region 7.

The plurality of fourth bulging portions 78c protrude in an arc shape (circular arc shape) from a region directly below the source structure 65 to both sides of the source structure 65. When the third contact region 78 has the single third bulging portion 72c, the single third bulging portion 72c may be formed such as to protrude in an arc shape (circular arc shape) to both sides of the source structure 65 at an intermediate portion of the third contact region 78.

As in the case of the semiconductor device 1A, the semiconductor device 1C includes the main surface insulating film 30 that covers the first main surface 3. In this embodiment, the main surface insulating film 30 is connected to the insulating film 17 in the first surface portion 8 and exposes the embedded electrode 18. Although not specifically illustrated, the main surface insulating film 30 is connected to the second insulating film 67 in the peripheral edge portion of the first surface portion 8 and exposes the second embedded electrode 68.

As in the case of the semiconductor device 1A, the semiconductor device 1C includes the interlayer film 31 that covers the main surface insulating film 30. The interlayer film 31 covers the plurality of gate structures 15 (the embedded electrodes 18) in the first surface portion 8. The interlayer film 31 covers the plurality of source structures 65 (the second embedded electrodes 68) in the peripheral edge portion of the first surface portion 8.

As in the case of the semiconductor device 1A, the semiconductor device 1C includes the plurality of source openings 32 and the plurality of gate openings 33 (see FIG. 3) formed in the interlayer film 31. The plurality of source openings 32 are each formed in a one-to-one correspondence with respect to the plurality of source structures 65. The plurality of source openings 32 each expose the single corresponding source structure 65, the plurality of source regions 21, and the plurality of first contact regions 27. Each of the plurality of source openings 32 preferably has an opening end curved in a circular arc shape.

The plurality of source openings 32 are formed in a band shape extending in the second direction Y along the corresponding source structures 65. The plurality of source openings 32 may be formed in a multiple-to-one correspondence with respect to the single corresponding first source structure 65. In this case, the plurality of source openings 32 may be formed at intervals along the single corresponding source structure 65. Also, in this case, the plurality of source openings 32 may be formed in a quadrilateral shape, a rectangular shape (band shape), a circular shape, etc., in plan view.

As in the case of the semiconductor device 1A, the semiconductor device 1C includes the source electrode 35, the gate electrode 40, the gate wiring 41, and the drain electrode 42 arranged on the first main surface 3. The descriptions regarding the gate electrode 40, the gate wiring 41, and the drain electrode 42 are the same as in the case of the semiconductor device 1A and shall thus be omitted.

The source electrode 35 enters the plurality of source openings 32 from above the interlayer film 31 and is electrically connected to the plurality of source structures 65, the plurality of source regions 21, and the plurality of first contact regions 27 in the plurality of source openings 32. Specifically, the source electrode 35 covers the first main surface 3 (the first surface portion 8) in the plurality of source openings 32 and is mechanically and electrically connected to the plurality of source structures 65, the plurality of source regions 21, and the plurality of first contact regions 27 on the first main surface 3.

The source electrode 35 further enters a plurality of the second trenches 66 from above the first main surface 3 and is mechanically and electrically connected to the second embedded electrode 68, the plurality of source regions 21, and the plurality of first contact regions 27 in the plurality of second trenches 66.

As in the case of the semiconductor device 1A, the source electrode 35 has a laminated structure that includes the lower electrode film 36 and the main electrode film 37 that are laminated in that order from the chip 2 side. The lower electrode film 36 has the laminated structure that includes the first electrode film 38 and the second electrode film 39.

The first electrode film 38 entirely covers, in a film shape, a region of the interlayer film 31 in which the plurality of source openings 32 are formed and enters the plurality of source openings 32 from above the interlayer film 31. The first electrode film 38 has a portion that covers an insulating main surface of the interlayer film 31 in a film shape, portions that cover the wall surfaces of the plurality of source openings 32 in film shapes, portions that cover the first main surface 3 in film shapes in the plurality of source openings 32, and portions that cover the plurality of source structures 65 in film shapes.

Specifically, the first electrode film 38 directly covers the insulating main surface of the interlayer film 31 and faces the gate structures 15 with the interlayer film 31 interposed therebetween. The first electrode film 38 extends in a circular arc shape from above the insulating main surface of the interlayer film 31 in conformance to the opening end of the source opening 32 and covers the wall surface of the source opening 32 in a film shape.

The first electrode film 38 covers the first main surface 3 in a film shape in the source opening 32 and is mechanically and electrically connected to the plurality of source regions 21 and the plurality of first contact regions 27 on the first main surface 3.

The first electrode film 38 enters the second trench 66 from above the first main surface 3 and covers the first side wall 65a, second side wall 65b, the second insulating film 67, and the second embedded electrode 68 in a film shape in the second trench 66. The first electrode film 38 is mechanically and electrically connected to the second embedded electrode 68, the plurality of source regions 21, and the plurality of first contact regions 27.

The second electrode film 39 directly covers the first electrode film 38. The second electrode film 39 entirely covers, in a film shape, a region of the interlayer film 31, in which the plurality of source openings 32 are formed, with the first electrode film 38 interposed therebetween and enters the plurality of source openings 32 from above the interlayer film 31.

The second electrode film 39 has a portion that covers the insulating main surface of the interlayer film 31 in a film shape with the first electrode film 38 interposed therebetween, portions that cover the wall surfaces of the plurality of source openings 32 in film shapes with the first electrode film 38 interposed therebetween, portions that cover the first main surface 3 in film shapes with the first electrode film 38 interposed therebetween in the plurality of source openings 32, and portions that cover the plurality of source structures 65 in film shapes with the first electrode film 38 interposed therebetween.

Specifically, the second electrode film 39 covers the insulating main surface of the interlayer film 31 with the first electrode film 38 interposed therebetween and faces the gate structure 15 with the interlayer film 31 and the first electrode film 38 interposed therebetween. The second electrode film 39 covers the opening end of the source opening 32 in a circular arc shape with the first electrode film 38 interposed therebetween and covers the wall surface of the source opening 32 in a film shape with the first electrode film 38 interposed therebetween.

The second electrode film 39 covers the first main surface 3 in a film shape with the first electrode film 38 interposed therebetween in the source opening 32 and is electrically connected to the plurality of source regions 21 and the plurality of first contact regions 27 via the first electrode film 38.

The second electrode film 39 enters the second trench 66 from above the first main surface 3 and covers the first side wall 65a and the second side wall 65b, the second insulating film 67, and the second embedded electrode 68 in a film shape with the first electrode film 38 interposed therebetween in the second trench 66. The second electrode film 39 is electrically connected to the second embedded electrode 68, the plurality of source regions 21, and the plurality of first contact regions 27 via the first electrode film 38.

The main electrode film 37 directly covers the lower electrode film 36 (the second electrode film 39). The main electrode film 37 refills the plurality of second trenches 66 and the plurality of source openings 32 with the lower electrode film 36 interposed therebetween and entirely covers, in a film shape, a region of the interlayer film 31, in which the plurality of source openings 32 are formed, with the lower electrode film 36 interposed therebetween.

The main electrode film 37 has a portion that covers the insulating main surface of the interlayer film 31 with the lower electrode film 36 interposed therebetween, portions that cover the wall surfaces of the plurality of source openings 32 with the lower electrode film 36 interposed therebetween, a portion that covers the first main surface 3 with the lower electrode film 36 interposed therebetween, and a portion that covers the second trench 66 with the lower electrode film 36 interposed therebetween.

Specifically, the main electrode film 37 covers the insulating main surface of the interlayer film 31 with the lower electrode film 36 interposed therebetween and faces the gate structure 15 with the interlayer film 31 and the lower electrode film 36 interposed therebetween. The main electrode film 37 covers the opening end of the source opening 32 with the lower electrode film 36 interposed therebetween. The main electrode film 37 covers the first main surface 3 with the lower electrode film 36 interposed therebetween in the source opening 32 and is electrically connected to the plurality of source regions 21 and the plurality of first contact regions 27 via the lower electrode film 36.

The main electrode film 37 enters the second trench 66 from above the first main surface 3 and covers the first side wall 65a, the second side wall 65b, the second insulating film 67, and the second embedded electrode 68 with the lower electrode film 36 interposed therebetween in the second trench 66. The main electrode film 37 is electrically connected to the second embedded electrode 68, the source region 21, and the first contact region 27 via the lower electrode film 36 in the second trench 66.

The semiconductor device 1C is manufactured by changing a layout of various masks in the manufacturing method of the semiconductor device 1A. For example, the source structure 65 is formed simultaneously with the gate structure 15 using a forming step of the gate structure 15. For example, the second well region 72 is formed simultaneously with the well region 22 using a forming step of the well region 22.

For example, the second high concentration well region 73 is formed simultaneously with the high concentration well region 23 using a forming step of the high concentration well region 23. For example, the third contact region 78 is formed simultaneously with the first contact region 27 (the second contact region 28) using a forming step of the first contact region 27 (the second contact region 28).

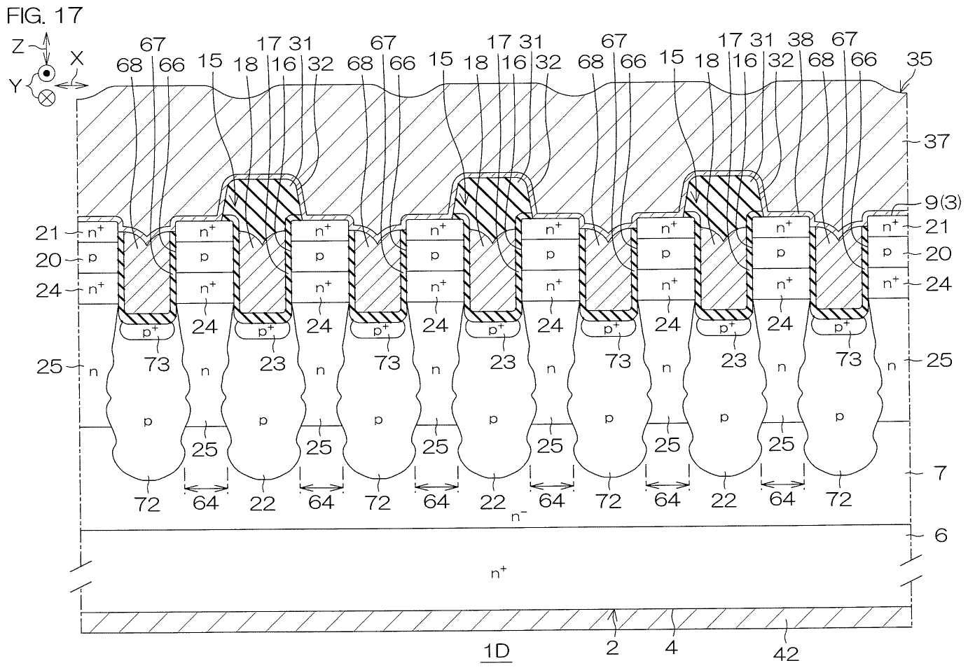

FIG. 17 is a sectional view showing one main portion of a semiconductor device 1D according to a fourth embodiment. Referring to FIG. 17, the semiconductor device 1D includes the plurality of well regions 22 formed as column regions forming a super junction structure and the plurality of second well regions 72 formed as column regions forming a super junction structure. As in the case of the semiconductor device 1C, the plurality of well regions 22 and the plurality of second well regions 72 are each formed in a columnar shape extending in the thickness direction in sectional view.

The semiconductor device 1D includes the plurality of intermediate drift regions 64 of the n-type that are formed in the second semiconductor region 7. Each of the plurality of intermediate drift regions 64 includes one of regions demarcated between the plurality of well regions 22 and the plurality of second well regions 72 in the second semiconductor region 7. That is, in this embodiment, each of the plurality of intermediate drift regions 64 includes a portion of the second semiconductor region 7, the high concentration region 24, and the intermediate concentration region 25.

The plurality of intermediate drift regions 64 are alternately aligned with the plurality of well regions 22 and the plurality of second well regions 72 in the first direction X and each formed in a band shape extending in the second direction Y. That is, the plurality of intermediate drift regions 64 are formed in a stripe shape extending in the second direction Y along the plurality of well regions 22 and the plurality of second well regions 72.

Also, an extension direction of the plurality of intermediate drift regions 64 coincides with the off direction of the SiC monocrystal. The plurality of intermediate drift regions 64 are formed in a columnar shape extending in the thickness direction in sectional view and face the plurality of body regions 20 in a one-to-one correspondence.

The plurality of intermediate drift regions 64 form a plurality of pn junction portions having a charge balance together with the plurality of well regions 22 and the plurality of second well regions 72 in a thickness range below the plurality of gate structures 15. A state of having the charge balance means a state where, for the well regions 22 and the second well regions 72 that are mutually adjacent, depletion layers spreading from the pn junction portions at one side and depletion layers spreading from the pn junction portions at another side are connected inside the intermediate drift regions 64.

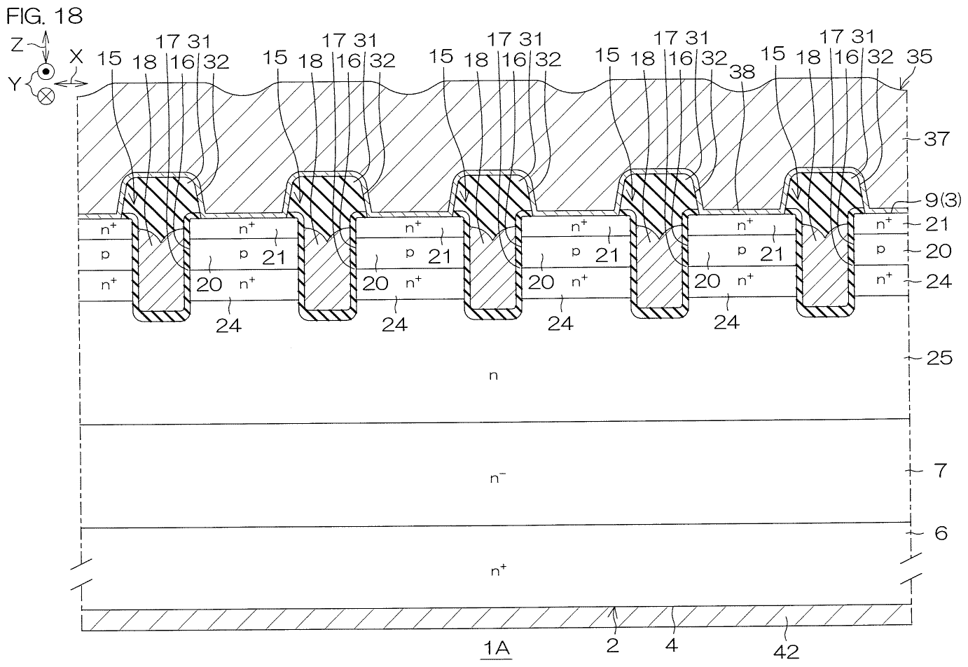

Hereinafter, first to eighth modification examples of the semiconductor devices 1A to 1D shall be described with reference to FIGS. 18 to 25. FIGS. 18 to 25 illustrate examples in which the first to eighth configuration examples are applied to the semiconductor device 1A, but the first to eighth configuration examples are also applicable to the semiconductor devices 1B to 1D.

Referring to FIG. 18, the semiconductor devices 1A to 1D according to the first modification example do not include the well region 22, the high concentration well region 23, the first contact region 27, and the second contact region 28. In this embodiment, the plurality of intermediate concentration regions 25 are integrated directly below the plurality of gate structures 15 and formed as the single intermediate concentration region 25 extending in the horizontal direction. The single intermediate concentration region 25 corresponds to the above-described base intermediate concentration region 52.

When the first modification example is applied to the semiconductor devices 1C and 1D, the second well region 72, the second high concentration well region 73, and the third contact region 78 are further removed. In this case, the plurality of intermediate concentration regions 25 are integrated directly below the plurality of gate structures 15 and directly below the plurality of source structures 65 and formed as the single intermediate concentration region 25 extending in the horizontal direction.

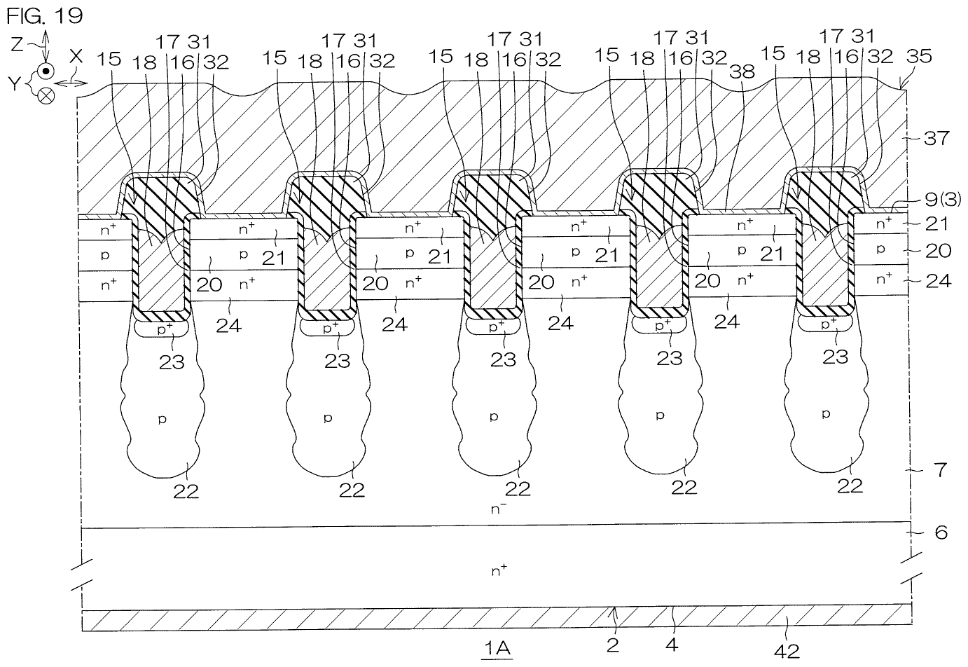

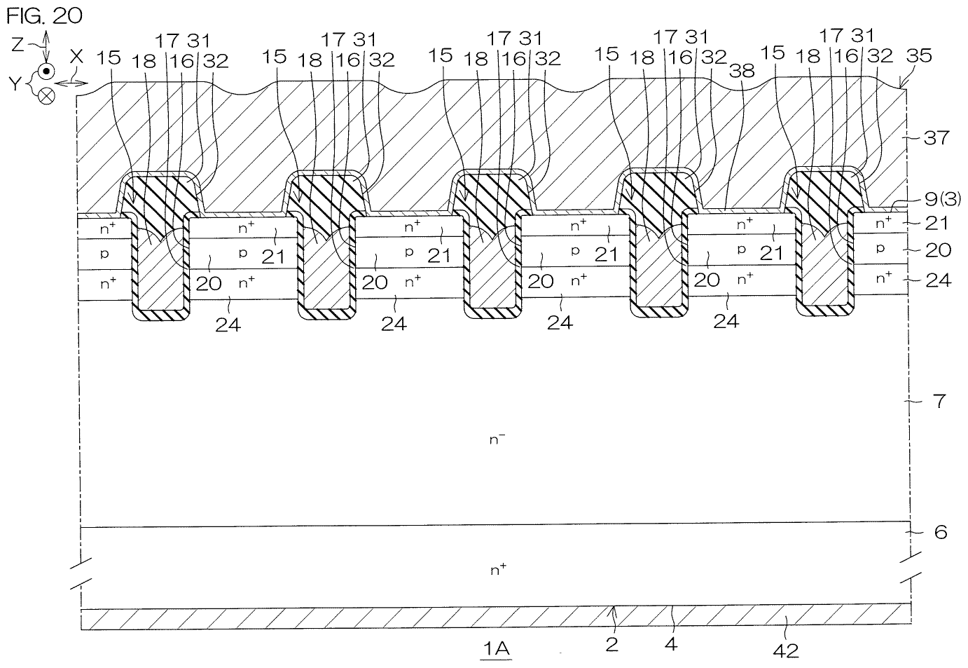

Referring to FIG. 19, the semiconductor devices 1A to 1D according to the second modification example do not have the intermediate concentration region 25. Referring to FIG. 20, the semiconductor devices 1A to 1D according to the third modification example have a configuration in which the well region 22 (the second well region 72), the high concentration well region 23 (the second high concentration well region 73), the first contact region 27, and the second contact region 28 (the third contact region 78) are removed from the configuration of the semiconductor devices 1A to 1D according to the second modification example.

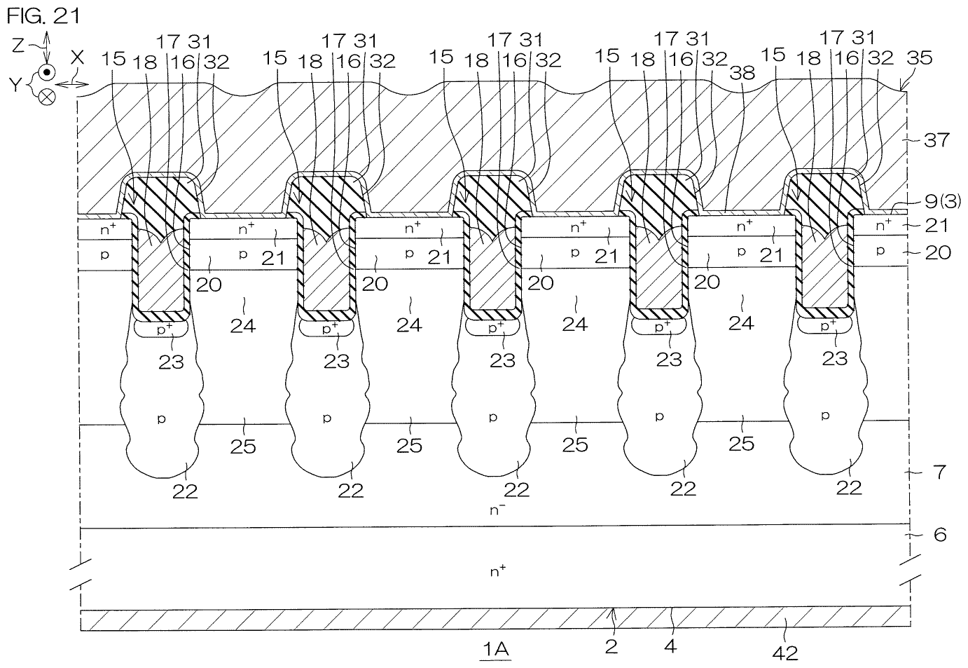

Referring to FIG. 21, the semiconductor devices 1A to 1D according to the fourth modification example do not have the high concentration region 24. In this embodiment, the intermediate concentration region 25 is formed in a region below the body region 20 as the high concentration region 24 having an n-type impurity concentration higher than the n-type impurity concentration of the second semiconductor region 7.

That is, in this embodiment, the intermediate concentration region 25 has a portion formed in the thickness range between the bottom wall 15c of the gate structure 15 (the source structure 65) and the bottom portion of the body region 20 in the second semiconductor region 7. With this configuration, the resistance value in the vicinity of the gate structure 15 is reduced by the intermediate concentration region 25 formed below the body region 20. Also, the intermediate concentration region 25 cancels out the undesirable p-type impurity introduced to the lateral side of the gate structure 15 due to a process error, etc.

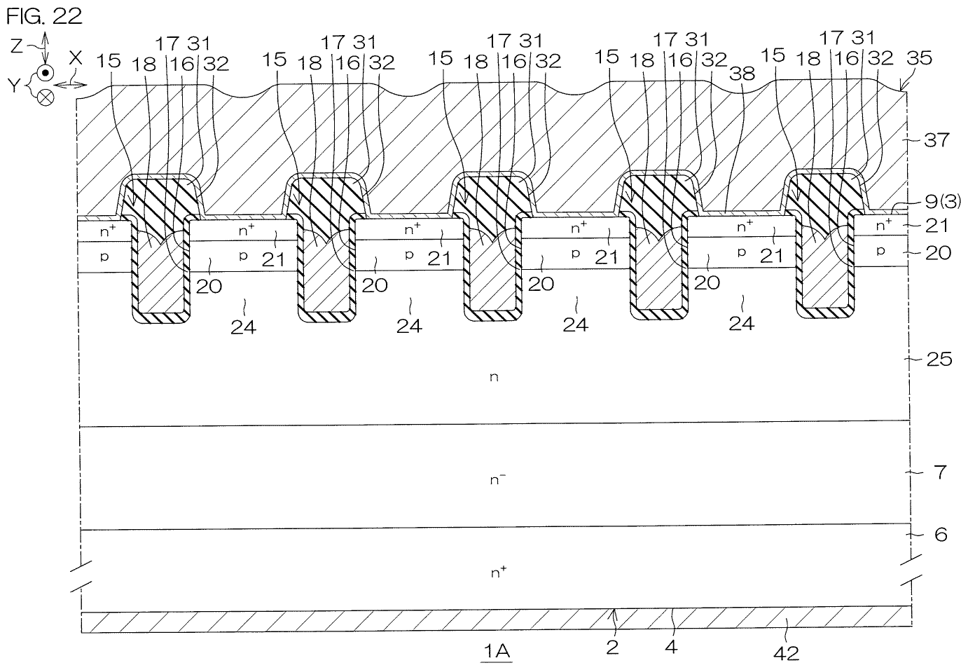

Referring to FIG. 22, the semiconductor devices 1A to 1D according to the fifth modification example have a configuration in which the well region 22 (the second well region 72), the high concentration well region 23 (the second high concentration well region 73), the first contact region 27, and the second contact region 28 (the third contact region 78) are removed from the configuration of the semiconductor devices 1A to 1D according to the fourth modification example.

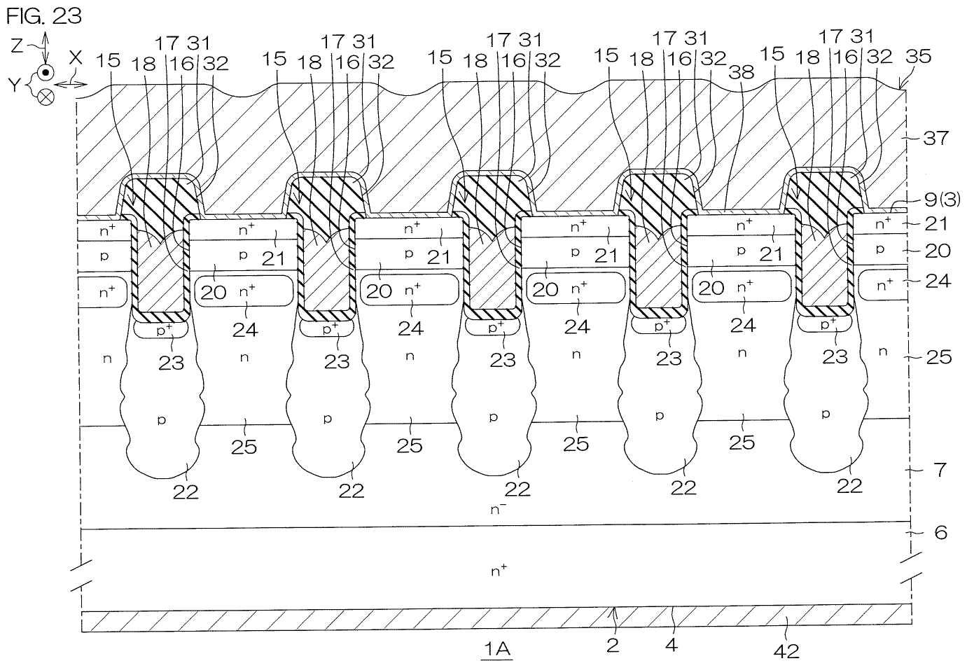

Referring to FIG. 23, the semiconductor devices 1A to 1D according to the sixth modification example include the plurality of high concentration regions 24 formed in the second semiconductor region 7 at intervals from the plurality of gate structures 15. That is, in this embodiment, the plurality of high concentration regions 24 face the side walls of the plurality of gate structures 15 with a portion of the intermediate concentration region 25 interposed therebetween.

When the intermediate concentration region 25 is not present, the plurality of high concentration regions 24 face the side walls of the plurality of gate structures 15 with a portion of the second semiconductor region 7 interposed therebetween. The plurality of high concentration regions 24 may have n-type impurity concentrations substantially equal to each other, or may have n-type impurity concentrations different from each other.

When the sixth modification example is applied to the semiconductor devices 1C and 1D, the plurality of high concentration regions 24 are formed at intervals to the plurality of source structures 65 side from the plurality of gate structures 15. In this case, the plurality of high concentration regions 24 may be connected to the plurality of source structures 65. As a matter of course, the plurality of high concentration regions 24 may be formed at intervals to the plurality of gate structures 15 side from the plurality of source structures 65.

The high concentration region 24 according to the sixth modification example is obtained by introducing an n-type impurity into the second semiconductor region 7 via a mask having a plurality of openings for exposing regions in which the plurality of high concentration regions 24 is to be formed in a forming step of the high concentration region 24.

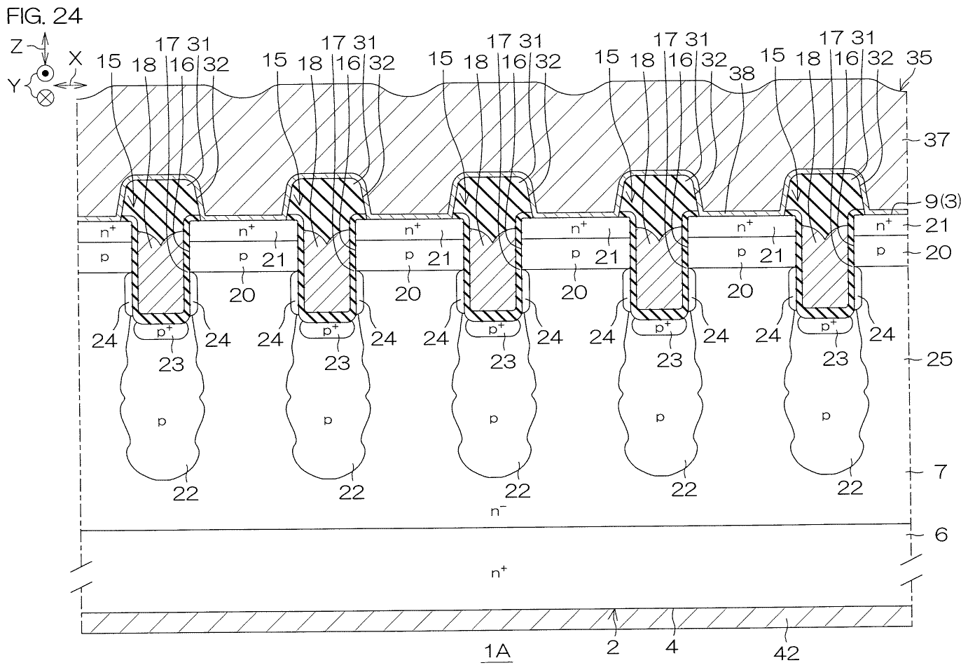

Referring to FIG. 24, the semiconductor devices 1A to 1D according to the seventh modification example include the plurality of high concentration regions 24 each formed in regions oriented along lower end portions of side walls (the first side wall 15a and the second side wall 15b) of the plurality of gate structures 15 in the second semiconductor region 7. The plurality of high concentration regions 24 are formed at intervals in the region between the plurality of gate structures 15 and face each other with a portion of the second semiconductor region 7 interposed therebetween.

The plurality of high concentration regions 24 may extend in the vertical direction Z along the side walls (the first side wall 15a and the second side wall 15b) of the plurality of gate structures 15. The plurality of high concentration regions 24 may be formed such as to bulge outward from the side walls (the first side wall 15a and the second side wall 15b) of the plurality of gate structures 15.

In this embodiment, the plurality of intermediate concentration regions 25 have a portion interposed in a region between the plurality of high concentration regions 24 in a region between the plurality of gate structures 15. The plurality of intermediate concentration regions 25 are electrically connected to the bottom portions of the plurality of body regions 20.

When the seventh modification example is applied to the semiconductor devices 1C and 1D, the plurality of high concentration regions 24 are formed in regions oriented along the lower end portions of the side walls (the first side wall 15a and the second side wall 15b) of the plurality of gate structures 15 at intervals from the plurality of source structures 65.

The high concentration region 24 according to the seventh modification example is obtained by introducing an n-type impurity into the second semiconductor region 7 via the side walls (the first side wall 15a and the second side wall 15b) of the trench 16 of the gate structure 15. The n-type impurity may be introduced into the second semiconductor region 7 by an oblique ion implantation method.

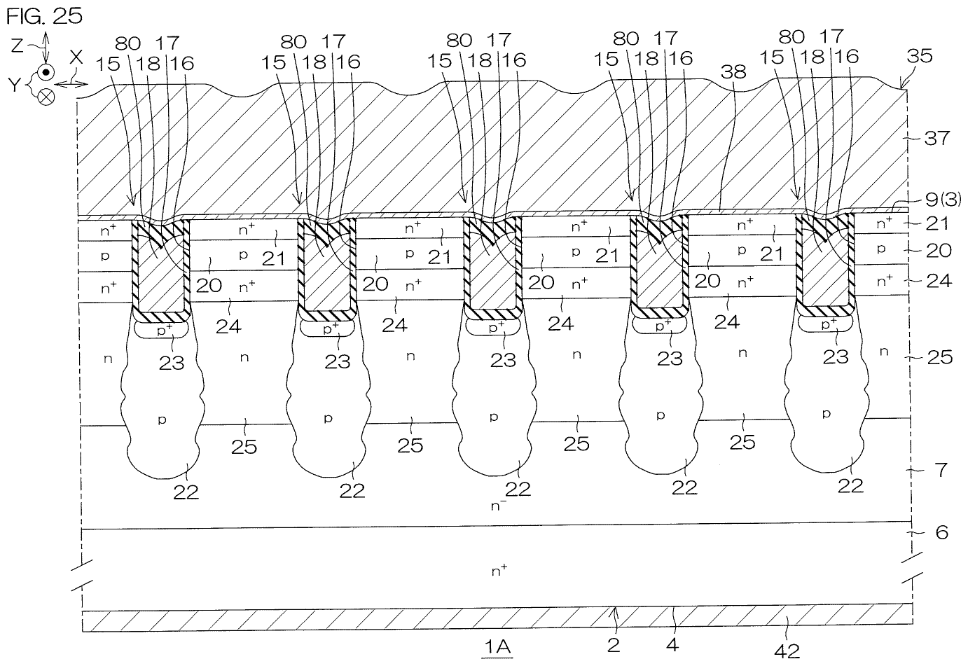

Referring to FIG. 25, the semiconductor devices 1A to 1D according to the eighth modification example include the gate structure 15 having the trench 16, the insulating film 17, the embedded electrode 18, and an embedded insulator 80. The embedded insulator 80 is embedded in the trench 16 such as to expose the first main surface 3 and covers the insulating film 17 and the embedded electrode 18 in the trench 16. The embedded insulator 80 may include at least one among a silicon oxide film, a silicon nitride film, and a silicon oxynitride film. The embedded insulator 80 preferably includes the silicon oxide film.

The source electrode 35 has a portion directly covering the first main surface 3 and a portion directly covering the embedded insulator 80. The source electrode 35 is electrically connected to the plurality of source regions 21 and the plurality of first contact regions 27 on the first main surface 3 and is electrically insulated from the plurality of embedded electrodes 18 by the embedded insulator 80. With such a configuration, the connection area of the source electrode 35 with respect to the plurality of source regions 21 and the plurality of first contact regions 27 is increased.

The embodiment (including the modification examples) described above can be implemented in yet other modes. For example, in each embodiment described above, a structure in which the conductivity type of a semiconductor region of the “n-type” is inverted to the “p-type” and the conductivity type of a semiconductor region of the “p-type” is inverted to the “n-type” may be adopted. The specific configuration in this case is obtained by replacing “n-type” with “p-type” and replacing “p-type” with “n-type” at the same time in the above description and attached drawings.

With the embodiment described above, the chip 2 including the SiC monocrystal is adopted. However, the chip 2 may include a wide bandgap semiconductor monocrystal other than the SiC monocrystal. The wide bandgap semiconductor is a semiconductor having a bandgap greater than a bandgap of silicon. For example, the chip 2 may contain gallium nitride, gallium oxide, diamond, etc. As a matter of course, the chip 2 may include a silicon monocrystal.

Similarly, the first semiconductor region 6 may include a wide bandgap semiconductor monocrystal other than the SiC monocrystal. For example, the first semiconductor region 6 may contain gallium nitride, gallium oxide, diamond, etc. As a matter of course, the first semiconductor region 6 may include a silicon monocrystal.

Similarly, the second semiconductor region 7 may include a wide bandgap semiconductor monocrystal other than the SiC monocrystal. For example, the second semiconductor region 7 may contain gallium nitride, gallium oxide, diamond, etc. As a matter of course, the second semiconductor region 7 may include a silicon monocrystal.

In each embodiment described above, a collector region of the p-type may be formed in a surface layer portion of the second main surface 4 of the chip 2. In this case, the chip 2 may have a single layer structure constituted of a semiconductor substrate of the n-type. In this case, the transistor structure Tr includes an IGBT (insulated gate bipolar transistor) structure in place of the MISFET structure. The specific configuration in this case is obtained by replacing the “source” of the MISFET structure with an “emitter” of the IGBT structure and replacing the “drain” of the MISFET structure with a “collector” of the IGBT structure in the above description.

Hereinafter, examples of features extracted from the present Description and the drawings shall be indicated below. Hereinafter, the alphanumeric characters, etc., in parentheses represent the corresponding components, etc., in the embodiments described above, but are not intended to limit the scope of each clause to the embodiments. The “semiconductor device” in the following clauses may be replaced with an “SiC semiconductor device,” a “wide bandgap semiconductor device,” “a semiconductor switching device,” a “MISFET device,” an “IGBT device,” etc., as needed.

[A1] A semiconductor device (1A to 1D) comprising: a chip (2) having a main surface (3); a semiconductor region (7) of a first conductivity type (n-type) formed in a surface layer portion of the main surface (3); a gate structure (15) of a trench type formed in the main surface (3) and positioned in the semiconductor region (7); a body region (20) of a second conductivity type (p-type) formed in a region at a side of the main surface (3) with respect to a depth position of a bottom wall (15c) of the gate structure (15) in the surface layer portion of the main surface (3); and a high concentration region (24) of the first conductivity type (n-type) formed in a thickness range between the bottom wall (15c) of the gate structure (15) and a bottom portion of the body region (20) in the chip (2) and having an impurity concentration higher than an impurity concentration of the semiconductor region (7).

[A2] The semiconductor device (1A to 1D) according to A1, wherein the chip (2) contains SiC.

[A3] The semiconductor device (1A to 1D) according to A1 or A2, wherein the high concentration region (24) has a bottom portion positioned at a side of the main surface (3) with respect to the depth position of the bottom wall (15c) of the gate structure (15).

[A4] The semiconductor device (1A to 1D) according to any one of A1 to A3, wherein the high concentration region (24) is connected to the gate structure (15).

[A5] The semiconductor device (1A to 1D) according to any one of A1 to A4, wherein the high concentration region (24) has a thickness less than a thickness of the body region (20).

[A6] The semiconductor device (1A to 1D) according to any one of A1 to A5, wherein the body region (20) has the bottom portion positioned further to the bottom wall (15c) side of the gate structure (15) than a depth position of an intermediate portion of the gate structure (15).

[A7] The semiconductor device (1A to 1D) according to any one of A1 to A6, wherein the gate structure (15) includes a side wall having an inclination angle of not less than 87° and not more than 93°.

[A8] The semiconductor device (1A to 1D) according to any one of A1 to A7, wherein the gate structures (15) are formed at an interval in the main surface (3), the body region (20) is formed in a region between the gate structures (15), and the high concentration region (24) is formed in the region between the gate structures (15) in a thickness range between the bottom wall (15c) of each of the gate structures (15) and the bottom portion of the body region (20).

[A9] The semiconductor device (1A to 1D) according to A8, wherein the high concentration region (24) is connected to the gate structures (15).

[A10] The semiconductor device (1A to 1D) according to any one of A1 to A9, further comprising: an impurity region (21) of the first conductivity type (n-type) formed in a region at a side of the main surface (3) with respect to the body region (20) such as to be oriented along the gate structure (15); the high concentration region (24) facing the impurity region (21) with a portion of the body region (20) interposed therebetween; and a channel (26) formed between the impurity region (21) and the high concentration region (24) in the body region (20).

[A11] The semiconductor device (1A to 1D) according to A10, wherein the high concentration region (24) has an impurity concentration less than an impurity concentration of the impurity region (21).

[A12] The semiconductor device (1A to 1D) according to any one of A1 to A11, further comprising: a well region (22) of the second conductivity type (p-type) formed in a region oriented along the bottom wall (15c) of the gate structure (15) in the chip (2).

[A13] The semiconductor device (1A to 1D) according to A12, wherein the well region (22) has an upper end portion oriented along a corner portion of the bottom wall (15c) of the gate structure (15), and the high concentration region (24) is formed in a thickness range between the bottom portion of the body region (20) and the upper end portion of the well region (22).

[A14] The semiconductor device (1A to 1D) according to A12 or A13, wherein the well region (22) has a thickness greater than a thickness of the body region (20).

[A15] The semiconductor device (1A to 1D) according to any one of A12 to A14, further comprising: a high concentration well region (23) of the second conductivity type (p-type) formed in the well region (22) at an interval to a side of the bottom wall (15c) of the gate structure (15) from a bottom portion of the well region (22) and having an impurity concentration higher than an impurity concentration of the well region (22).

[A16] The semiconductor device (1A to 1D) according to A15, wherein the high concentration well region (23) has a bottom portion positioned at a side of the bottom wall (15c) of the gate structure (15) with respect to a depth position of an intermediate portion of the well region (22).

[A17] The semiconductor device (1A to 1D) according to any one of A1 to A16, further comprising: a contact region (27) of the second conductivity type (p-type) formed in a region oriented along a side wall of the gate structure (15) in the chip (2) and having an impurity concentration higher than an impurity concentration of the body region (20).

[A18] The semiconductor device (1A to 1D) according to any one of A1 to A17, further comprising: a bottom-side contact region (28) of the second conductivity type (p-type) formed in a region oriented along the bottom wall (15c) of the gate structure (15) in the chip (2) and having an impurity concentration higher than an impurity concentration of the body region (20).

[A19] The semiconductor device (1A to 1D) according to any one of A1 to A18, further comprising: an intermediate concentration region (25) of the first conductivity type (n-type) formed in a region below the high concentration region (24) in the chip (2) and having an impurity concentration higher than an impurity concentration of the semiconductor region (7) and lower than an impurity concentration of the high concentration region (24).

[A20] The semiconductor device (1A to 1D) according to A19, wherein the intermediate concentration region (25) has a region positioned on an upper side with respect to the depth position of the bottom wall (15c) of the gate structure (15) and a region positioned on a lower side with respect to the depth position of the bottom wall (15c) of the gate structure (15).

While specific embodiments have been described in detail above, these are merely specific examples used to clarify the technical contents. The various technical ideas extracted from this description are not limited by the order of description, the order of configuration examples, etc., in the description and can be combined as appropriate with each other.

What is claimed is:

1. A semiconductor device comprising:
a chip having a main surface;
a semiconductor region of a first conductivity type formed in a surface layer portion of the main surface;
a gate structure of a trench type formed in the main surface and positioned in the semiconductor region;
a body region of a second conductivity type formed in a region at a side of the main surface with respect to a depth position of a bottom wall of the gate structure in the surface layer portion of the main surface; and
a high concentration region of the first conductivity type formed in a thickness range between the bottom wall of the gate structure and a bottom portion of the body region in the chip and having an impurity concentration higher than an impurity concentration of the semiconductor region.

2. The semiconductor device according to claim 1,
wherein the chip contains SiC.

3. The semiconductor device according to claim 1,
wherein the high concentration region has a bottom portion positioned at a side of the main surface with respect to the depth position of the bottom wall of the gate structure.

4. The semiconductor device according to claim 1,
wherein the high concentration region is connected to the gate structure.

5. The semiconductor device according to claim 1,
wherein the high concentration region has a thickness less than a thickness of the body region.

6. The semiconductor device according to claim 1,
wherein the body region has the bottom portion positioned further to the bottom wall side of the gate structure than a depth position of an intermediate portion of the gate structure.

7. The semiconductor device according to claim 1,
wherein the gate structure includes a side wall having an inclination angle of not less than 87° and not more than 93°.

8. The semiconductor device according to claim 1,
wherein the gate structures are formed at an interval in the main surface,
the body region is formed in a region between the gate structures, and
the high concentration region is formed in the region between the gate structures in a thickness range between the bottom wall of each of the gate structures and the bottom portion of the body region.

9. The semiconductor device according to claim 8,
wherein the high concentration region is connected to the gate structures.

10. The semiconductor device according to claim 1, further comprising:
an impurity region of the first conductivity type formed in a region at a side of the main surface with respect to the body region such as to be oriented along the gate structure;
the high concentration region facing the impurity region with a portion of the body region interposed therebetween; and
a channel formed between the impurity region and the high concentration region in the body region.

11. The semiconductor device according to claim 10,
wherein the high concentration region has an impurity concentration less than an impurity concentration of the impurity region.

12. The semiconductor device according to claim 1, further comprising:
a well region of the second conductivity type formed in a region oriented along the bottom wall of the gate structure in the chip.

13. The semiconductor device according to claim 12,
wherein the well region has an upper end portion oriented along a corner portion of the bottom wall of the gate structure, and
the high concentration region is formed in a thickness range between the bottom portion of the body region and the upper end portion of the well region.

14. The semiconductor device according to claim 12,
wherein the well region has a thickness greater than a thickness of the body region.

15. The semiconductor device according to claim 12, further comprising:
a high concentration well region of a second conductivity type formed in the well region at an interval to a side of the bottom wall of the gate structure from a bottom portion of the well region and having an impurity concentration higher than an impurity concentration of the well region.

16. The semiconductor device according to claim 15,
wherein the high concentration well region has a bottom portion positioned at a side of the bottom wall of the gate structure with respect to a depth position of an intermediate portion of the well region.

17. The semiconductor device according to claim 1, further comprising:
a contact region of a second conductivity type formed in a region oriented along a side wall of the gate structure in the chip and having an impurity concentration higher than an impurity concentration of the body region.

18. The semiconductor device according to claim 1, further comprising:
a bottom-side contact region of the second conductivity type formed in a region oriented along the bottom wall of the gate structure in the chip and having an impurity concentration higher than an impurity concentration of the body region.

19. The semiconductor device according to claim 1, further comprising:
an intermediate concentration region of the first conductivity type formed in a region below the high concentration region in the chip and having an impurity concentration higher than an impurity concentration of the semiconductor region and lower than an impurity concentration of the high concentration region.

20. The semiconductor device according to claim 19,
wherein the intermediate concentration region has a region positioned on an upper side with respect to the depth position of the bottom wall of the gate structure and a region positioned on a lower side with respect to the depth position of the bottom wall of the gate structure.
